(19) United States
(12) Patent Application Publication
(10) Pub. No.: US 2026/0096033 A1
(43) Pub. Date: Apr. 2, 2026

(54) COMPUTER IMPLEMENTED PORTABLE ELECTRONIC DEVICE CHARGING AND ACCESS MANAGEMENT METHOD

(71) Applicant: HomeWAV, LLC, St. Louis, MO (US)

(72) Inventors: Seyedmorteza Sahebkarkhorasani, St. Louis, MO (US); Andrew Lewis, St. Louis, MO (US); Dinko Karamfilov, St. Louis, MO (US); Alireza Khamesipour, St. Louis, MO (US); Steve McDaniel, St. Louis, MO (US)

(21) Appl. No.: 19/411,768

(22) Filed: Dec. 8, 2025

Related U.S. Application Data
(63) Continuation-in-part of application No. 17/201,918, filed on Mar. 15, 2021.
(60) Provisional application No. 62/990,113, filed on Mar. 16, 2020.

(51) Int. Cl. H05K 5/02; H01M 10/44

(52) U.S. Cl. CPC H05K 5/0208; H01M 10/441; H05K 5/0221; H05K 5/0286

(57) ABSTRACT

A mobile device management charging and access management method is implemented with a database, a controller, and at least one charging bay device including a locking mechanism. The method includes: accepting, by the at least one controller, a user login to verify an authorized user status according to information in the database; assessing a user privilege status after the authorized user status is verified according to the authorized user data and information in the database; and only when the privilege status is active, allowing one of the portable computing devices to be retrieved and used by the verified authorized user.

### CROSS REFERENCE TO RELATED APPLICATIONS

This application is a continuation-in-part application of U.S. application Ser. No. 17/201,918 filed Mar. 15, 2021, which claims the benefit of U.S. Provisional Application Ser. No. 62/990,113 filed Mar. 16, 2020, the complete disclosures of which are hereby incorporated by reference in its entirety.

This application also relates in part to U.S. application Ser. No. 19/228,421 filed Jun. 4, 2025, which is a continuation of U.S. application Ser. No. 18/453,724 filed Aug. 22, 2023 and now issued U.S. Pat. No. 12,395,368, the complete disclosures of which are hereby incorporated by reference in its entirety.

This application further relates in part to U.S. application Ser. No. 18/524,476 filed Nov. 30, 2023, the complete disclosure of which is hereby incorporate by reference in its entirety.

### BACKGROUND OF THE INVENTION

The field of the invention relates generally to automated charging and locking cabinet devices and systems capable of securing tablet computer devices in multi-compartment chargers in a controlled environment, and more specifically to improved modular bay charging devices and centralized mobile device management of configurable kiosk systems including monitoring of modular charging bay operation to address potential security issues.

The modern day proliferation of mobile computer technology and handheld computing devices has conventionally been avoided in controlled environments such as correctional facilities for a variety of reasons that are presently receding rapidly in view of technological advances. An availability of relatively powerful tablet computer devices now available at relatively low cost, coupled with the convenience that they provide, makes them an attractive option to conventional, non-mobile computer terminal devices conventionally used at correctional facilities for visitation purposes and other desirable applications that inmates may access when permitted by facility administrators for desired kiosk services.

Tablet device charger systems have been recently developed in order to securely store and charge groups of tablet computer devices so that they are ready for use with kiosk services offered in correctional facilities. Existing tablet device charger systems are disadvantaged in some aspects, however, and improvements are desired.

### BRIEF DESCRIPTION OF THE DRAWINGS

Non-limiting and non-exhaustive embodiments are described with reference to the following Figures, wherein like reference numerals refer to like parts throughout the various drawings unless otherwise specified.

FIG. 1 is a perspective view of an exemplary battery powered portable electronic device which may be used in a configurable kiosk system of the present invention.

FIG. 2 is a block diagram of a computer-implemented correctional facility services system offering secure interactions between resident users in a controlled environment such as a correctional facility housing incarcerated inmates and remotely located non-incarcerated visitors.

FIG. 3 is a block diagram of a portion of the system shown in FIG. 2.

FIG. 4 is a schematic diagram of an exemplary configurable kiosk device and system including expansion charging modules to accommodate varying numbers of tablet computer devices to meet the needs of different facilities and changing needs of the facilities over time.

FIG. 5 is a method flowchart of exemplary processes implemented by the computer kiosk device and system shown in FIG. 4.

FIG. 6 is a front view of an exemplary embodiment of an improved modular charging bay for the system shown in FIG. 4 and the method shown in FIG. 5.

FIG. 7 is perspective view of a wall mounting bracket for the modular charging bay shown in FIG. 6.

FIG. 8 is a first partial perspective front view of a portion of the modular charging bay shown in FIG. 6 and the mounting bracket shown in FIG. 7.

FIG. 9 is a second partial perspective front view of a portion of the modular charging bay shown in FIG. 6 and the mounting bracket shown in FIG. 7.

FIG. 10 is partial perspective rear view of a portion of the modular charging bay shown in FIG. 6 and the mounting bracket shown in FIG. 7.

FIG. 11 is a perspective front view of the modular charging bay showing lock actuators in a locked position with a manual key release.

FIG. 12 schematically illustrates an operation of a locking mechanism for the modular charging bay of FIG. 11.

FIG. 13 is a front schematic view of a configurable kiosk system including a plurality of modular charging bays.

FIG. 14 a method flowchart of exemplary processes implemented by the configurable kiosk system shown in FIG. 13.

FIG. 15 illustrates an exemplary administrator interface graphical screen display showing exemplary charging bay status and reporting in the processes illustrated in FIG. 14 for configurable kiosk systems such as those shown in FIG. 13.

FIG. 16 illustrates an exemplary administrator interface graphical screen display showing exemplary charging bay enrollment in the processes illustrated in FIG. 14 for configurable kiosk systems such as those shown in FIG. 13.

FIG. 17 illustrates an exemplary administrator interface graphical screen display showing exemplary charging bay lock history in the processes illustrated in FIG. 14 for configurable kiosk systems such as those shown in FIG. 13.

FIG. 18 illustrates an exemplary administrator interface graphical screen display showing exemplary firmware management in the processes illustrated in FIG. 14 for configurable kiosk systems such as those shown in FIG. 13.

FIG. 19 illustrates an exemplary administrator interface graphical screen display showing exemplary charging bay status and charging pocket status in the processes illustrated in FIG. 14 for configurable kiosk systems such as those shown in FIG. 13.

FIG. 20 illustrates an exemplary administrator interface graphical screen display showing exemplary charging bay lock scheduling in the processes illustrated in FIG. 14 for configurable kiosk systems such as those shown in FIG. 13.

FIG. 21 illustrates an exemplary administrator interface graphical screen display showing exemplary charging bay notification in the processes illustrated in FIG. 14 for configurable kiosk systems such as those shown in FIG. 13.

FIG. 22 illustrates an exemplary administrator interface graphical screen display showing exemplary charging bay reporting in the processes illustrated in FIG. 14 for configurable kiosk systems such as those shown in FIG. 13.

FIG. 23 illustrates an exemplary administrator interface graphical screen display showing exemplary charging bay model and version reporting in the processes illustrated in FIG. 14 for configurable kiosk systems such as those shown in FIG. 13.

FIG. 24 illustrates an exemplary administrator interface graphical screen display showing administrator user permission assignment and monitoring in the processes illustrated in FIG. 14 for configurable kiosk systems such as those shown in FIG. 13.

FIG. 25 illustrates an exemplary administrator interface graphical screen display showing correctional facility administrator user link generation and options in the processes illustrated in FIG. 14 for configurable kiosk systems such as those shown in FIG. 13.

FIG. 26 illustrates an exemplary administrator interface graphical screen display showing administrator user activity in the processes illustrated in FIG. 14 for configurable kiosk systems such as those shown in FIG. 13.

FIG. 27 illustrates an exemplary administrator interface graphical screen display showing charging bay enrollment options in the processes illustrated in FIG. 14 for configurable kiosk systems such as those shown in FIG. 13.

FIG. 28 is a method flowchart of exemplary user device check-out and check-in processes implemented in configurable kiosk systems and charging bays.

FIG. 29 is a method flowchart of exemplary processes for operating configurable kiosk systems and charging bays in different modes.

FIG. 30 is a method flowchart of exemplary user device identification and notification processes for operating configurable kiosk systems and charging bays implemented in configurable kiosk systems and charging bays.

FIG. 31 schematically illustrates charging pocket and user device identification features implemented in configurable kiosk systems and charging bays.

FIG. 32 schematically illustrates user device detection and interface features for charging pockets implemented in configurable kiosk systems and charging bays.

FIG. 33 is a method flowchart of exemplary assigned user device checkout processes implemented in configurable kiosk systems and charging bays.

FIG. 34 is a method flowchart of user device assignment processes implemented in configurable kiosk systems and charging bays.

FIG. 35 is a method flowchart of queued user device assignment processes implemented in configurable kiosk systems and charging bays.

FIG. 36 schematically illustrates electrical protection features for charging pockets implemented in configurable kiosk systems and charging bays.

FIG. 37 is a block diagram of a portion of a machine learning kiosk services system including a charging bay device.

FIG. 38 is a method flowchart of automated configuring, testing, upkeep and diagnostic processes for the machine learning system shown in FIG. 37.

FIG. 39 is a method flowchart of automated compliance, investigational and financial analytic processes for the machine learning system shown in FIG. 37.

### DETAILED DESCRIPTION OF THE INVENTION

The inventive concepts described herein beneficially address particular logistical issues presented by an adoption of portable computer devices made accessible to residents in a controlled environment (e.g., inmates) and offering desirable services in a controlled environment such as a correctional facility. Accordingly, the following discussion of the state of the art and particular problems presented for mobile device management and charging systems for mobile computer devices is appropriately set forth below for a better understanding of particular problems that now exist in the art, followed by exemplary embodiments of the invention that overcome such problems.

### I. State of the Art

Frequent visitation by family and loved ones for confined residents in a controlled environment such as a correctional facility is important but historically subject to logistical challenges for arranging physical interaction between residents and visitors while ensuring security interests of the facility are met. Video visitation systems now exist that beneficially avoid requirements of visitors having to travel to the correctional facility and related on-site security concerns and challenges to correctional facility personnel. HomeWAV® video visitation systems are disclosed in, for example, U.S. application Ser No. 18/254,476 and U.S. application Ser. No. 19/228,421 which are incorporated by reference above and which provide secure video visitation functionality appropriate for correctional facility use and which may operate on tablet computer devices.

More specifically, the HomeWAV® video visitation systems dramatically reduce, if not eliminate, burdens on correctional facility personnel in aspects of otherwise conventionally required logistical scheduling and/or manual approval of visitation requests, while nonetheless providing adequate security safeguards and oversight capabilities needed by correctional facility personnel. Numerous benefits of frequent visitation sessions with incarcerated inmates are beneficially realized via the HomeWAV® systems at relatively low cost, and sometimes at no cost, to correctional facilities. Further, video visitation services are only one of many services made available to inmates via the HomeWAV® systems to authorized inmates having current privilege status allowing them to access the system. Because of their convenience and versatility for offering valued services to inmate residents, tablet computer devices are desirably used in correctional facilities by inmates, but bring with them further logistical challenges in order to reliable serve the needs of residents while also meeting increased security requirements.

In one aspect, and especially for correctional facilities housing large populations of inmates, keeping track of relatively large numbers of tablet computer devices needed to accommodate a large inmate population presents administrative and logistical challenges to correctional facility administrators to maintain and track an inventory of computer devices in the correctional facility. Specifically, and as a rule of thumb, in a system such as the HomeWAV® video visitation system the ratio of tablet computers to inmates should preferably be about 1:1 or 1:2 to ensure that a sufficient number of tablet computer devices are available to inmates when needed.

As such, for a relatively small correctional facility housing 100 inmates, about 20 tablet computer devices may be optimal to serve the inmate population. While 20 tablet computer devices may raise serious logistical challenges to a small facility, the number of tablet computer devices for larger correctional facilities can quickly rise to daunting levels that require serious management solutions. Numerous correctional facilities exist today having relatively large populations of more than a thousand inmates, and some correctional facilities exist today having populations of more than ten thousand inmates. Considering also the sheer number of correctional facilities today, and the various different types of correctional facilities (e.g., state prisons, federal prisons, local jails, juvenile correctional facilities, Native American detention facilities, and military detention facilities) the industry challenges to widespread adoption of tablet computer devices for use by inmates in a secure manner are significant.

Electronic tools assisting correctional facility administrators to ensure secure access to specific tablet computers by specific inmates, restrict access to specific tablet computers by specific inmates, and to track, log, and record the time of use and nature of use of specific tablet computers on an inmate-by-inmate basis in a reliable manner have been developed and have succeeded to reduce the burdens on correctional facility administrators for managing inventories of tablet computer devices. An increasing use of tablet computer devices in a correctional facility introduces new and different burdens, however, that have yet to be completely resolved. Specifically, burdens associated with charging and recharging inventories of tablet computer devices, and securely managing inventories of tablet computer devices as inventory size increases have yet to be fully overcome.

Charging systems have been recently developed which are capable of charging an inventory of checked-in tablet computer devices without burdening correctional facility administrators and while flexibly meeting the needs of different correctional facilities having different inventory sizes or evolving inventory sizes in any given correctional facility. For example, U.S. Patent Application Publication No. Serial No. 2021/0287197 of HomeWAV (which corresponds to U.S. application Ser. No. 17/201,918 that is incorporated by reference above) discloses an intelligent, secure and configurable correctional facility computer kiosk system and method for portable electronic device access and management including but not limited to tablet computer devices in a correctional facility. The configurable kiosk system is specifically geared toward the security needs of correctional facilities with beneficial flexibility to accommodate varying numbers of tablet computer devices to meet the needs of different correctional facilities. Unlike conventional charger systems that only accommodate a fixed number of tablet computer devices via a fixed number of tablet charging slots, the number of tablet computer charging slots may be varied in the configurable kiosk system and therefore more completely meet the needs of the correctional facility application wherein population size of inmates may vary considerably from one another and wherein population size of inmates is subject to change over time in the correctional facilities.

The configurable correctional facility computer kiosk system of U.S. Patent Application Publication No. 2021/0287197 includes a kiosk controller which controls secure tablet access for inmates based on preregistered authorized user data as compared to inmate user supplied data, and also an assessment of inmate privileges to access kiosk services. The kiosk system also includes separately provided and distinct modular add-on charging bays each having a number of lockable charging slots and charging circuitry for the tablet devices which are intelligently controlled by the kiosk controller for secure tablet device check-in, check-out, device charging, and tablet device tracking and oversight functionality. Tablet device content management and monitoring and oversight of inmate use of the tablet devices is also advantageously provided with detection and notification features for security-related concerns in the correctional facility.

Such modular charging bays of U.S. Patent Application Publication No. 2021/0287197 allow the kiosk system to be configured to initially include a first number of tablet device charging slots deemed to be sufficient for a given correctional facility. The first number of tablet device charging slots is the sum of any charging slots provided in a first or main unit and secondarily in the number of charging slots in each of a selected modular charging bays, such that the system is scalable via the selected number of charging bays to reach an optimal number of device charging slots to meet the particular needs of any given correctional facility for desired kiosk services running through the tablet devices. Likewise, kiosk systems may be initially configured for different facilities with different numbers of modular charging bays to initially meet the different charging needs of varying desired tablet inventory sizes of each correctional facility for the desired kiosk services.

The kiosk system of U.S. Patent Application No. 2021/0287197 may be advantageously reconfigured at a point in time after its initial configuration to include a second number of tablet device charging slots which is different from the first number for the initially configured kiosk. Such reconfiguration may be made in a retrofit manner by adding or subtracting and therefore changing the number of modular charging bays provided to realize a different number of charging slots that matches a desired change in tablet device inventory size. The kiosk system may automatically detect changes in the number of modular bays and intelligently account for the expanded or reduced number of tablet devices made available in the correctional facility, and is therefore flexible to accommodate different numbers of tablet devices in an inventory of tablet devices made available in each correctional facility at different points in time.

Because the charging bays of U.S. Patent Application Publication No. 2021/0287197 are provided in a modular, plug and play form, customized kiosk fabrication at higher cost to include kiosks having a specifically desired but fixed number of charging slots for different correctional facilities is avoided, especially so as the number of desired charging slots grows to become prohibitively expensive. Likewise, an obsolescence of a kiosk system is avoided when changes in inmate population size require different numbers of tablet devices to be made available to inmate users in the correctional facility, especially so when the tablet device inventory grows and exceeds the fixed number of tablet charger slots provided. Ability to remove modular charging bays that are no longer needed eliminates security issues posed by overcapacity of the kiosk system relative to actual needs.

While the configurable correctional facility computer kiosk system of U.S. Patent Application Publication No. 2021/0287197 overcomes numerous challenges in providing secure access to an inventory of tablet devices in correctional facilities with appropriate tablet device management and controls with reduced burden on correctional facility administrators, further improvements are desired. For example, electronically controlled charging bays are sometimes prone to reliability issues that are not easily detected over a number of charging bays. Monitoring and overseeing an optimal operation of a number of charging bays is needed, including detection of certain conditions or states of the charging bays that may negatively impact security objectives or render the operation of the kiosk system to be sub-optimal.

Known locking mechanisms for charging bays tend to be overly complicated and require precise positioning of a tablet computer device relative to a locking mechanism to activate the locking mechanism. Furthermore, certain types of locking mechanisms, including but not limited to mechanisms involving solenoids and locking pins, are subject to reliability issues in use and may sometimes be forced open or fail if power is lost. Likewise, simple manual locking features are vulnerable to being forced open by malicious actors. If any of the locking mechanisms in the tablet charging slots are not fully engaged, if any lock mechanism experiences a fault condition or an error condition, or of the locking features can be forced open, tablet devices may be freely removed from the charging bays in a manner that circumvents applicable access restrictions. Over a large number of modular charging bays, unreliable locking of tablet devices in the charging bays, or vulnerabilities in the locking mechanisms, present security concerns in a correctional facility that may lead to objection of an adoption of modular charging bays.

Especially when faulty locking mechanisms may not be apparent to correctional facility administrators or otherwise easy to detect over a large number of modular charging bays, false impressions that tablet devices are securely stored may persist for indefinite periods of time that could be exploited by bad actors. Considering that known modular charging bays include a number of individually lockable charging slots that are unlockable on demand by a kiosk controller, any of the locks for the charging slots may fail to engage or disengage in a relatively unpredictable manner. Correctional facility administrators lack desirable electronic tools to track locking operations and take proper steps to ensure compliance with security needs in response.

Certain error conditions for electronically controlled locking mechanisms may prevent use of tablet devices altogether if they cannot be removed from the charging slots due to a failed lock mechanism that is stuck in a locked position. In this case, tablet devices may be unusable until professional repairs to the charging bays, or replacement of the affected charging bays, can be made. As a result, inmate access to desired kiosk services offered through tablet devices may be undesirably limited. Manual operability of otherwise electronically controlled locks is accordingly desired for emergency situations or intervention by correctional facility personnel when needed to ensure access to tablet devices.

On the other hand, error conditions for electronically controlled locking mechanisms may result in unlocked tablet devices for lock mechanisms that become stuck in an unlocked position. Failsafe locking mechanisms and detection of locking status (e.g., successful or unsuccessful) are therefore needed. Notification of faulty locks or error conditions is likewise desired, and so are simpler and more reliable alternatives to existing locking and unlocking features acting upon individual charging slots. Effective locking mechanisms are desired that act on more than one charging slot with a degree of programmability to automatically lock and unlock at specific times instead of on demand.

Potential user error in failing to insert tablet devices in the proper orientation to ensure that charging connectors are aligned and charging connections are established in the charging bays can also be an issue in certain types of charging bays where the tablet device can be inadvertently inserted in more than one orientation by a user. User error in failing to insert tablet devices in the proper orientation also tends to prevent a proper engagement of locking features. Damage to charging connectors and locking mechanisms may result when tablet devices are incorrectly inserted into a modular charging bay. Detection and notification features for such circumstances, or alternatively features that can prevent the device from being inserted in the wrong orientation are accordingly needed.

Additionally, desired operability of electronically controlled modular charging bays in configurable kiosk systems depends on software/firmware compatibility and ability to update software/firmware over time. Over a large number of charging bays, however, and especially as modular charging bays are added to kiosk systems over time, management capability and oversight is needed to assess and compare software/firmware versions or track software/firmware updates and ensure that all the modular charging bays are operating with compatible software/firmware. Incompatibility in software/firmware amongst various modular charging bays can lead to unexpected results and performance issues of the kiosk system, which may not be apparent to anyone in the correctional facility for indefinite periods of time.

Likewise, user error in introducing charging bays, and selecting charger bay settings in the kiosk configuration is possible, again leading to unexpected results and performance issues of the kiosk system, which may not be apparent to anyone in the correctional facility for an indefinite period of time. Unrestricted access to introduce charging bays, editing charging bay information, and to change lock status can also present vulnerability to exploitation by bad actors to circumvent security safeguards. Remote monitoring of enrolled charging bay devices, remote access to control settings and preferences, status report capability and historical event report capability for the charging bays, restricting access to the system with secure links and restricting access to certain system functionality, and detection and notification capability for events of interest would ensure the proper operation of the charging bays or prompt resolution of error conditions but are presently lacking.

### II. Improved Charging Bay Devices, Configurable Kiosk System and Mobile Device Management of the Invention

Exemplary embodiments of correctional facility computer kiosk devices, systems and methods are described below that overcome the above and other difficulties via improved charging bay devices and improved administrator interfaces allowing effective oversight and control in a centralized manner for large numbers (e.g., thousands) of modular bay charging bay devices in different configurable kiosk systems in a number of correctional facilities. Superior safety, durability, and effective centralized mobile device management is beneficially provided.

More specifically, improved locking mechanisms are provided in waterproof and tamper proof charging bay devices with state detection features for intelligent control and oversight of the charging bay devices individually and collectively through the improved administrator user interfaces. The improved locking mechanism acts on multiple slots of the charging bay at once instead of individually, and also incorporates a spring biased failsafe feature ensuring that the locking position is maintained in the event of a locking mechanism failure in the charging bay. In contemplated examples, the locking mechanism may include a motor driven actuator link that collectively moves locking (or blocking) elements that prevent removal of tablet devices, sensors such as limit switches that provided locking or unlocking state feedback to a control board or control device which may electronically control the motor with a Power Over Ethernet (POE) power supply. The locking mechanism and controls may be protected in a sealed waterproof enclosure to ensure long-term durability.

An emergency barrel-key override feature is also provided which realizes manual operability of the locking mechanism when desired or as needed, with a spring biased locking force avoiding user error which could otherwise inadvertently leave the locking mechanism unlocked after key operation. Conspicuous and tamper proof locking features are visible from an exterior of the device for simple visual confirmation of locked and unlocked tablet status for peace of mind to correctional facility administrators. Modular chassis assemblies including charging pockets, supports, and electronic control features may be provided which can be swapped out when needed instead of being repaired on site. Removable cabinet housing faces allow access to the modular chassis assemblies, which may be hung and fastened to a wall mountable bracket, ensuring environmental protection and serviceability.

The charging bay devices may include angled pockets which reduce the depth of the assembly when mounted on a wall as well as simplify engagement of charging connections with tablet computer devices. Shaped charging pockets and protective cases for the tablet devices ensure that tablet devices may only be inserted in one-way where the charging connections and the locking mechanisms are reliably engaged. In the one-way insertion, the tablet devices within the cases are inserted upside-down in the charging slots and the charging pockets. The entire protective case and the protected tablet device are inserted completely into the shaped pockets, and access openings for the pockets include additional clearance for a user's hand to be inserted into the pocket when inserting and removing a tablet device via a grip portion or grip handle of the protective case.

The electronic controls of the charging bay devices communicate with another device such as a kiosk controller for the configurable kiosk system or with a remotely located kiosk services device operating as a centralized data collection system associated with kiosk services offered through the tablet devices. Configurable kiosk systems may be provided having any number of charging bay devices. Network scalability across multiple charger bay devices is advantageously realized.

Detailed reporting and event history for events of interest in the operation of the improved charging bay devices in the configurable kiosk systems is available via improved administrator interfaces, and notifications and alerts are generated to ensure that appropriate steps can be taken to address detected concerns and optimize the use and operation of the kiosk system. Enrolled charging bay devices may be known to the system for mobile device management, including their specific pod locations in a facility, and administrators may manage the charging bay devices as well as the tablet devices to ensure optimal operation of the monitored kiosk system(s). Administrator permissions are required to access the charging bay device data and information and the tablet device data and information such that mobile device management remains secure, and logs are kept of administrator actions for later review to assess system operation and administrator activity for potential further improvements based on the comprehensive amount of data being collected that may illuminate hardware, firmware and software changes to improve mobile device management system reliability even further.

Charging bay notifications generated by the system may concern physical failure of a lock mechanism, unsuccessful locking events, unsuccessful charging of a tablet device, incompatible software/firmware issues, unsuccessful software/firmware updates, offline charging bays and other events of interest that require a response to ensure that access controls are not circumvented and that security compliance is maintained. Administrators at the correctional facilities and remote from the correctional facilities can see and verify in real time the status and condition of charging devices being monitored, and administrators also may interact with the charging bay devices to correct detected issues.

User-friendly and intuitive graphical screen displays are generated for authorized administrative users at locations remote from the correctional facilities to assess the performance of the charging bays and the tablet devices and overall utilization of the kiosk systems in the same and different facilities. Diagnostics and troubleshooting of the charging bays is possible from remote locations, and administrative burdens on correctional facility administrators are lessened. Summary dashboards displays and easily accessed options are provided to enroll charging bay devices and assess operation thereafter as they are installed and replaced in modular kiosk systems. Event history may be easily accessed for modular charging bay devices in multiple correctional facilities. Status, reports, and histories for all modular bay devices being monitored may be generated, and specific subgroups of certain modular bay devices being monitored may be searched to generate status, reports and histories for only selected ones of the modular bay devices being monitored.

While described in the context of correctional facilities such as jails and prisons, and also while described specifically in the context of the patented HomeWAV® video visitation services, the inventive concepts described herein are not necessarily limited to correctional facilities such as jails or prisons, and further are not necessarily limited to video visitation system services. Rather, the inventive concepts described herein may more generally accrue to a broad variety of facilities that present similar issues concerning desirable controlled access and secure device management in a controlled environment, and also tracking of tablet devices access and use in facilities and environments in which the benefits of the inventive concepts described equally apply in whole or in part to control access to and charging of a plurality of mobile devices. Some of the features described, including modular charging assemblies accommodating different numbers of portable electronic devices (including but not limited to tablet computer devices), may be desirable for educational settings, as well as for general commercial or residential use to manage a plurality of mobile computer devices in an environments that are not necessarily “controlled” to protect security interests and concerns applicable to certain types of users in specific security-minded environments. Method aspects will be in part explicit and in part apparent in the description below.

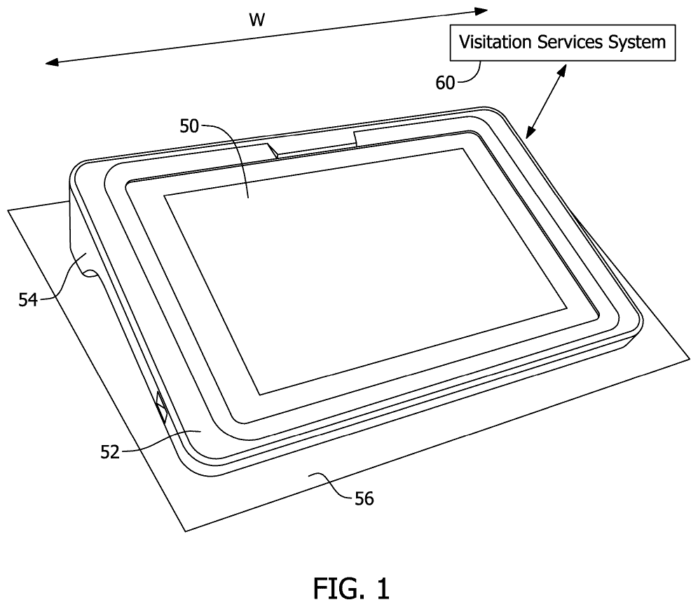

FIG. 1 is a perspective view of an exemplary battery powered portable electronic device in the form of a tablet computer device 50 according to an exemplary embodiment of the present invention which may be used in a configurable kiosk system further described below for inmate access to kiosk services in a correctional facility. In contemplated embodiments, the tablet computer device 50 may be a battery powered, processor-based device such an Android device or an IOS device including an 8 inch touchscreen. In contemplated examples, the tablet computer device 50 may include a 3200 mAh or greater battery offering extended use and long life, front and rear cameras having a desired resolution (e.g., 5 MP), and a speaker/microphone. The tablet computer device 50 may also include a case 52 with integral stand 54 on one side of the case 52. The stand 54 elevates the far side of the tablet computer device 50 relative to a tabletop or desktop surface 56 as shown in FIG. 1, while the near side of the case is not elevated. By virtue of the stand 54, the touch screen of the tablet computer device 50 is oriented at an angle relative to a tabletop or desktop surface 56, and is therefore oriented at a better viewing angle for optimal use of the tablet computer device 50 by an inmate.

The tablet computer device 50 may optionally also include an audio port such as a headphone jack, and a conventional charging port such as a micro-USB port, a lightning port, or a pin dock connector of conventional portable electronic devices. Asset tag location features, RFID features, and Wi-Fi or cellular connection features may also be provided, although in contemplated embodiments the tablet computer device 50 is configured to communicate exclusively with a visitation services computer system 60 and/or with other correctional facility systems. The tablet computer device 50 in contemplated embodiments further includes a central processing unit including one or more processors, 16 GB of memory, 2 GB DDR+ memory, an accelerometer, and a light Sensor. The tablet computer device may also include power buttons, volume buttons, etc. implemented on the touch screen or as physical buttons.

The tablet computer device 50 may in some embodiments be constructed from heavy duty materials such as steel and includes structural assembly techniques to define a so-called “jail-hardened” device that meets specific requirements of correctional facility installation to meet security needs.

While an exemplary embodiment of a tablet computer device is shown and described, variations are possible with different sizes and form factors, different communication ports, different degree of memory storage, different processors, etc. The inventive concepts described herein are generally extendable to the entire market of tablet computer devices at various price points with varying performance capabilities and features.

In use, the tablet computer device 50 may wirelessly communicate with a video visitation services system 60 such as the HomeWAV® video visitation system and may be utilized by an inmate of a correctional facility to conduct video visitations sessions or to participate in other services made available to inmate users. The inmate user may log-in into the tablet computer device 50 to connect with the visitation services system 60, and the tablet computer device 50 may run an inmate user interface with predetermined selection menus and options for the inmate to access different services that are pre-approved for use in the controlled environment of the correctional facility. As such, web content and access to external devices and systems may be tightly controlled, and inmates are generally precluded from using the tablet computer devices 100 apart from the preapproved services.

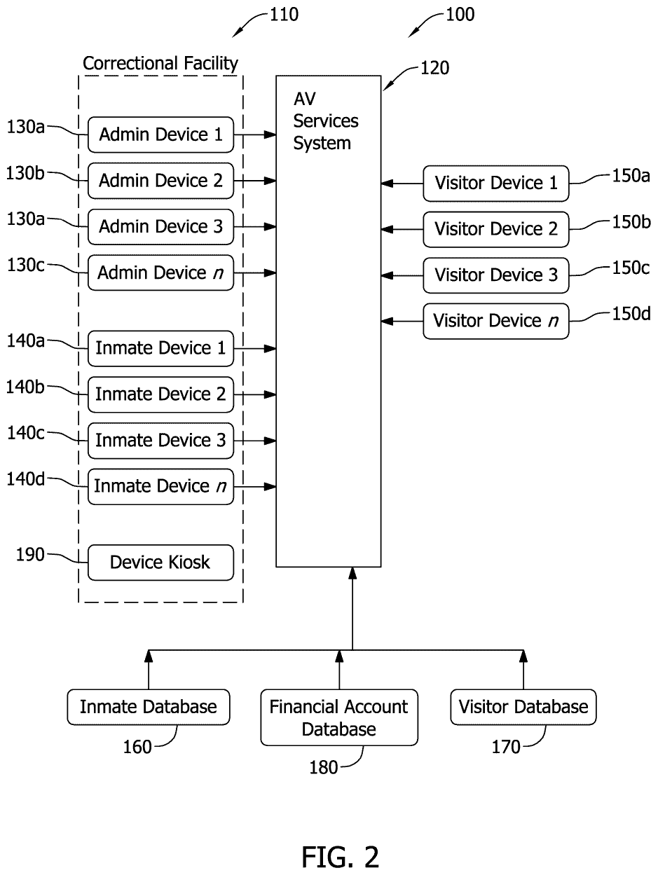

FIG. 2 is a is a block diagram of a computer-implemented correctional facility services system 100 offering secure interactions between resident users in a controlled environment such as a correctional facility 110 housing incarcerated inmates and remotely located non-incarcerated visitors. As non-limiting examples, such correctional facilities may include state prisons, federal prisons, local jails, juvenile correctional facilities, Native American detention facilities, and military detention facilities. The controlled environment of such facilities includes strict security measures, oversight, monitoring, and controls to securely manage populations of inmates for the safety of the inmates, correctional facility officers and staff attending to the inmates, and also for visitors. The controlled environment of the correctional facility also includes access controls and restrictions applicable to the use of computer devices made available in the correctional facility 110.

As shown in FIG. 1, the system 100 includes an audio/video (“AV”) communication services system 120 that is in communication with computer devices 130 and 140 in the correctional facility 110 for respective use by correctional facility administrators and incarcerated inmates. In the example of FIG. 2, administrator computer devices 130a, 130b, 130c and 130d are shown, although the system 100 is scalable to include any number n of administrator computer devices 130. Likewise in the example of FIG. 2, inmate computer devices 140a, 140b, 140c and 140d are shown, although the system 100 is scalable to include any number n of inmate computer devices 140. The inmate computer devices 140 may be tablet computer devices such as the device 50 shown in FIG. 1.

In the typical case, the number of correctional facility administrators in a given correctional facility 110 is far fewer than the number of inmates. As mentioned above, correctional facilities exist today having populations of more than a thousand inmates, and some correctional facilities exist today having populations of more than ten thousand inmates. Ideally, and as rule of thumb, the ratio of inmate computer devices 140 to inmates should be about 1:5 to ensure that a sufficient number of inmate computer devices are available to inmates when needed, although this is by no means required in all cases and such ratio of inmates to inmate computer devices may vary considerably amongst different correctional facilities 110. Typically, however, the number of inmate computer devices 140 well exceeds the number of correctional facility administrators and raises practical challenges to correctional facility administrators to oversee them.

The AV communication services system 120 is further in communication with computer devices 150 for respective use by non-incarcerated friends and family of incarcerated inmates (collectively referred to herein as “visitors”) at respective locations remote from the correctional facility 110 where an inmate is housed. In the example of FIG. 2, visitor computer devices 150a, 150b, 150c and 150d are shown, although the system 100 is scalable to include any number n of visitor computer devices 150. The AV communication services system 120 beneficially interconnects respective ones of the inmate devices 140 and visitor devices 150 to conduct live electronic audio/video exchanges and other features described herein while applying correctional facility administrator preferences and monitoring capability via the administrator devices 130.

In the system 100, and by virtue of the AV communication services system 120, inmate users may spontaneously initiate (i.e., without prior scheduling and without required action by correctional facility personnel at the time of initiation by the inmate) to use the services of the AV services system to conduct, for example, a video call. The video call may likewise proceed, from beginning to end, without requiring any action of correctional facility personnel. The video call is conducted via one of the inmate devices 140 that is interfaced through the AV services system 120 with selected visitor devices 150 of respective visitors that are approved in advance. As such, the number of approved visitors and therefore visitor devices 150 will typically exceed the number of inmates in a given inmate population for a particular correctional facility 110. The AV communication services system 120 may simultaneously operate to provide services for inmate devices 140, according to preferences and controls realized by the administrator devices 130 of multiple correctional facilities 110, to realize electronic audio/video exchanges with visitors via visitor devices 150. The electronic audio/video exchanges and services established through the system 100 may include singular video calls (i.e., calls involving only one inmate and only one visitor), group video calls (i.e., calls involving an inmate and multiple visitors), group messaging services and other services described in U.S. application Ser. No. 19/228,421 which is incorporated by reference above.

With respect to each correctional facility 110, the AV communication services system 120 is operative in reference to an inmate database 160 which includes correctional facility data and information, authorized inmate information and data, inmate privilege information and data. The AV communication services system 120 is further operative in reference to a database 170 including non-inmate user data such as pre-authorized remote visitor data, and a database 180 including financial account data for the services made available through the AV services system 120. The databases 160, 170, 180 may in some cases be combined and/or additional databases may be included to contain some of the same data and information as well as other data and information needed to perform the system functionality described herein.

In contemplated embodiments the AV communication services system 120 may be a web-based, hosted services system in which the respective administrator, inmate and visitor uses may login via web portals with stationary computer terminal devices and/or via specific interface apps running on mobile computer devices. The computer devices 130, 140, 150 may therefore be a combination of stationary computer devices and mobile computer devices, although the enhancements of the inventive system 100 are aimed toward issues posed by mobile computer devices and as such in a contemplated embodiment of the system 100 the number of mobile computer devices used in the system 100 would vastly exceed the number of stationary computer terminals. The system 100 is particularly convenient for remotely located visitors and visitor devices 150 by eliminating any need to travel to the correctional facility 110, but it is recognized that in some cases a visitor may travel to a correctional facility and conduct a video visitation system with an inmate while there via a stationary computer terminal or a mobile device made accessible to the visitor in the facility.

The reader is referred to U.S. application Ser. No. 18/524,476 which is incorporated by reference above for more specific detail regarding system architecture and server-based video conferencing and video messaging functionality that may be included in the system 100. It is recognized, however, that a web-based, hosted AV communication services system 120 system is only one of a number of ways that the system 100 could be implemented while otherwise meeting the security requirements of correctional facilities with respect to adoption of mobile computer devices. In particular, networked, server-based systems may be provided that do not necessarily require web access to operate, and the AV communication services system 120 could in some cases be located in a correctional facility, as opposed to being remotely located. Numerous system architectures, distributed or undistributed, may be employed in the AV communication services system 120 in various embodiments with otherwise similar functionality from the inmate and visitor user perspective. In certain embodiments for smaller inmate populations, the AV communication services system 120 need not be a server-based system at all, and could instead be run on single computer devices or combinations of computer devices that do not include computer servers.

In certain contemplated embodiment, the AV communication services system 120 may further operate in combination with a configurable computer kiosk device and system 190 that provides secure check-out and check-in of an optimal number of mobile computer devices for use by inmates in a correctional facility, as well as intelligent charging of mobile computing devices, coordinated content management for the mobile computer devices, and intelligent security monitoring and controls of devices being used by inmates at any given point in time.

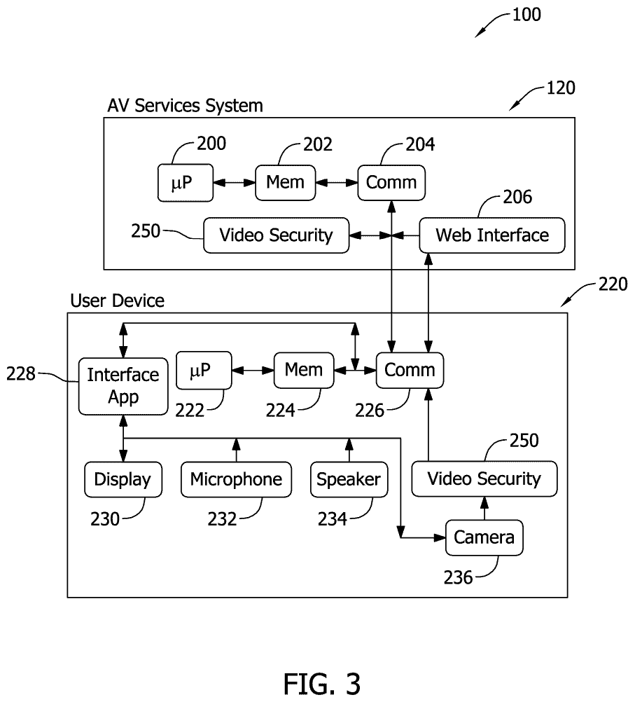

FIG. 3 is a block diagram of a portion of the system 100 shown in FIG. 2 wherein the AV communication services system 120 is shown to include a central processor unit (CPU) including one or more processors or microprocessors 200, a memory 202, a communication element 204 and a web interface 206. The AV communication services system 120 is in communication with a user device 220 that may be utilized a computer device 130, 140 or 150 in the operation of the system 100.

The user device 220 includes a CPU including one or more processors or microprocessors 222, a memory 224, and a communication element 226. The communication element 226 is a known element communicating with the web interface 206 of the AV system 120 in a known manner using a wired or wireless communication path to establish an Internet connection between the devices using known communication protocols and techniques. When the user device 220 is configured as a mobile computer device, it may also include a user interface app 228 that establishes communication with the AV service system 120 as shown.

When the user device 220 is configured as an administrator device, it runs an administrator interface application 228 presenting graphical screen displays to an administrative user in order to present options and accept selection inputs to enable and disable selected features or selected services in the operation of the AV system 120, to optimize system settings in view of the needs and preferences of the particular correctional facility 110 (FIG. 1) in which AV services are being offered through devices 220 of inmates and visitors, and to monitor and oversee services in use. The graphical screen displays are presented in interactive form that is responsive to administrator selections using navigational home pages and sub-pages each including organized buttons, menus and sub-menus, drop-down selection fields, fill-in data entry fields, pop-up dialog boxes, check boxes and other known features familiar to app developers and users.

When the user device 220 is configured as an inmate device, it runs an inmate interface application 228 presenting graphical screen displays to an inmate user in order to securely login and identify authorized inmates to use services offered through the AV system 120, present options to inmates and accept selection inputs for available services and to present output screen displays and functionality for selected services. The graphical screen displays are presented in interactive form that is responsive to inmate selections using navigational home pages and sub-pages each including organized buttons, menus and sub-menus, drop-down selection fields, fill-in data entry fields, pop-up dialog boxes, check boxes and other known features familiar to app developers and users.

When the user device 220 is configured as a visitor device, it runs a visitor interface application 228 presenting graphical screen displays to a visitor user in order to present options and accept selection inputs for available choices and to present output screen displays and functionality for selected services. The graphical screen displays are presented in interactive form that is responsive to visitor selections using navigational home pages and sub-pages each including organized buttons, menus and sub-menus, drop-down selection fields, fill-in data entry fields, pop-up dialog boxes, check boxes and other known features familiar to app developers and users.

Examples of screen displays generated by administrator, user and visitor interface applications 228 are set forth in U.S. application Ser. No. 18/524,476 which is incorporated by reference above and which may be included in the operation of the system 100. Further examples of screen displays generated by administrator, user and visitor interface applications 228 are also set forth in U.S. application Ser. No. 19/228,421 which is incorporated by reference above for certain aspects of operation of the system 100. Still further examples of screen displays generated by the administrator user application 228 are described below regarding aspects of modular charging bay device management and oversight. The interface applications 228 may be designed to run in an iOS or Android operating system of the device 220 which may be configured as a handheld tablet computer device or a smartphone device, while still communicating seamlessly with the AV services system 120 running on still another known operating system.

The user device 220 may as shown also include a display 230 that is configured to be a touch sensitive display that is fully operative as a known input/output device, a microphone 232, a speaker 234 and at least one camera 236. The display 230, speaker 234 and camera 236 may be provided as built-in elements of the computer device 220 when configured as mobile device such as a tablet computer, a smartphone or a notebook or laptop computer. The computer device 220 may alternatively be provided at least in part as separate components usable together in a desktop, workstation or computer terminal set up. Additional input/output components such as a mouse, stylus and keyboard may be provided when desired. In the context of the present discussion, the speaker 234 includes a built-in speaker, a separately provided speaker, an audio jack providing an audio signal output from the device, and any connected headphone or headset arrangement and wireless ear bud components that a user may enjoy when using the device 220. External microphones may also be employed in connection with the device 220 via wired arrangements in known types of headphones, wired and wireless headsets, or wired and wireless handheld microphones that may be hand-held, tabletop devices, or secured in desired locations relative to computer monitors and the like in a correctional facility, home, or office environment.

The camera 236 may include a forward facing camera and a rear facing camera in some embodiments of user devices 220. In other embodiments, the user device 220 (such as an inmate device) may only include a forward facing camera. Video security components 250 are included in the user device 220, and may in some cases be implemented through the user interface application 228, to perform image processing on the video feeds generated by the camera 236 to provide enhanced video security features to address the issues discussed above with respect to security issues posed by the mobile nature of user devices 220 to conduct video visitation services in the correctional facility context. In further and/or alternative embodiments, video security components 250 may also be included in the AV services system 120 instead of or in addition to the user devices 220 which are operative on the video feeds of the camera 236 in each user device 220 wherein the enhanced security video processing options described further in U.S. application Ser. No. 19/228,421 may be selectively enabled according to correctional facility preferences. The security video processing options automatically process images of a video feed from an inmate user device 140 or a visitor user device 150 in order to prevent a video transmission of unsecure video content during the video call. The image processing employs, for example, human face detection for transmitting images of a user's face in combination with different degrees of blurring of background content or removal of background content in the images of the video feed, or blurring of the entirety of images in the video feed to address security concerns or privacy concerns in the course of a video visitation session conducted with one or more portable tablet computer devices.

In each of the system 120 and the user device 220, the processors and memory storage operate in tandem to execute instructions, commands, and control algorithms, as well as other data and information required to satisfactorily operate the system 100 as described herein. The memory storage may be, for example, a random access memory (RAM), and other forms of memory used in conjunction with RAM memory, including but not limited to flash memory (FLASH), programmable read only memory (PROM), and electronically erasable programmable read only memory (EEPROM) may likewise be included.

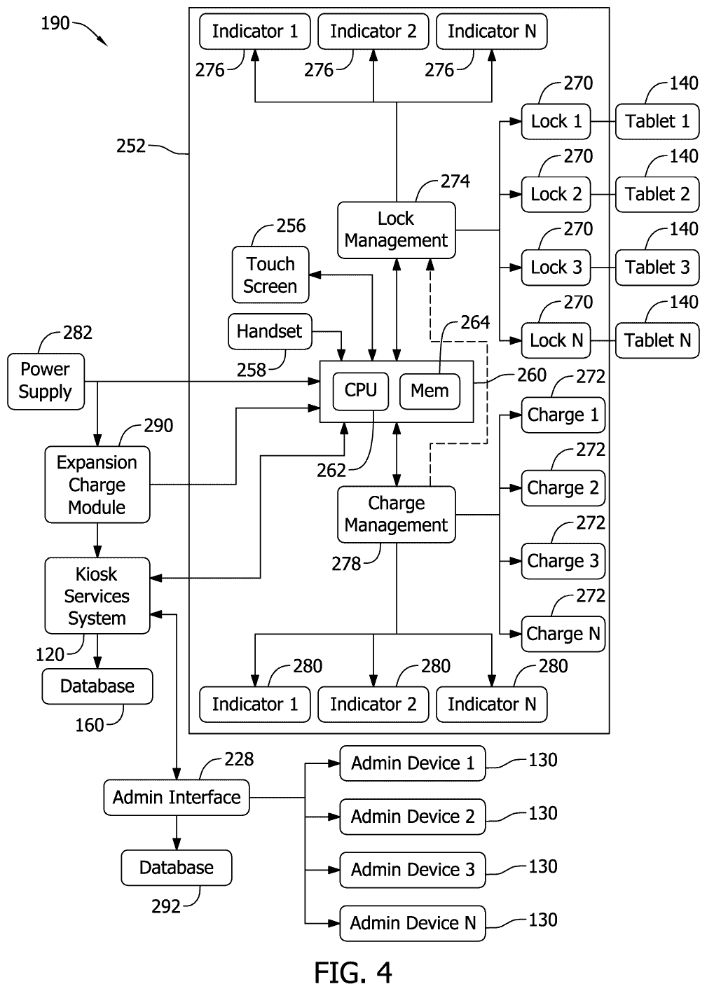

FIG. 4 schematically illustrates the configurable kiosk device 190 for the system 100 shown in FIG. 2. The kiosk device 190 may be provided as a system including modular add-on charging bays as further described herein.

The kiosk device 190 may include a rugged housing, casing or cabinet 252 such as that described further below that may be securely mounted to a wall in a correctional facility using known fasteners, anchors, or techniques to fixedly mount the kiosk device in a desired location. Alternatively, instead of mounting to a vertically-oriented support such as a wall, the kiosk device 190 could be mounted instead to a horizontally-oriented support structure such as a tabletop, desktop, countertop, floor or other support structure as desired. In some cases, the kiosk device 190 could likewise be obliquely mounted to a support and therefore be presented to a user at any angle desired relative to vertical or horizontal planes in a correctional facility.

Likewise, in other contemplated embodiments the kiosk device 190 may also be provided in a freestanding or self-supporting cabinet or housing to be placed on a tabletop, desktop, countertop, floor, or shelf as desired, whether or not actually being secured in place. Portable and non-portable embodiments of the kiosk device 190 are therefore contemplated. In some cases, the kiosk system including a number of devices 190 is provided in relatively small and lightweight package sizes that can be carried by hand, while in other embodiments larger and heavier kiosk systems may incorporate wheels or casters provided on one or more freestanding or self-supporting cabinets, housings or carts allowing the system to be easily moved from place to place or positioned and re-positioned in a desired location as needed.

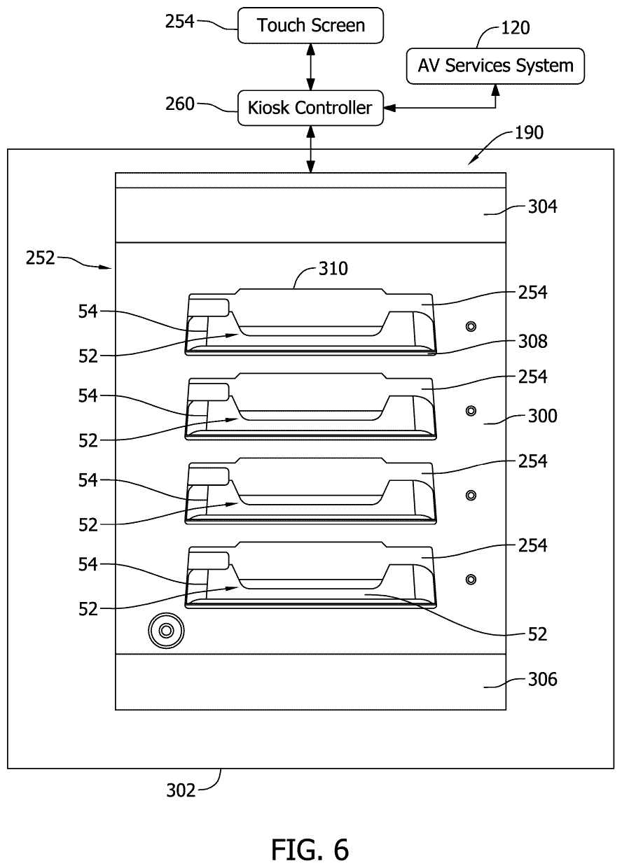

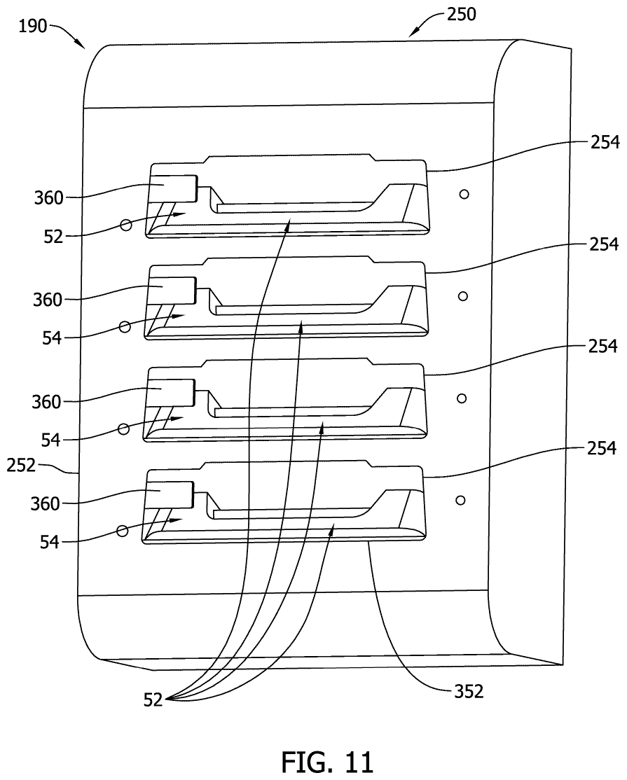

In a contemplated embodiment, the cabinet housing 252 of the kiosk device 190 may be constructed from heavy duty materials such as steel and may include structural assembly and fabrication techniques to provide a so-called “jail-hardened” device meeting applicable and specific requirements of correctional facility installation to ensure that the kiosk device 190 cannot be tampered with and therefore meet security needs in a controlled environment. The cabinet housing 252 further defines a number n of tablet computer slots 254 (FIGS. 6, 11) that extend through a front face of the cabinet housing 252. Each tablet computer slot 254 is sized and dimensioned to respectively receive a single tablet computer 50 (FIG. 1) within the case 52. The tablet device 50 may serve as an inmate device 140 (FIG. 2) and user device 220 (FIG. 3) in the system 100.

A touch screen monitor 256 may be mounted to or near the cabinet housing 252 in contemplated embodiments for use by a user such as an inmate, and a telephone handset 258 is also provided for use by an inmate user. In some cases, the telephone handset 258 may be considered optional and need not be provided, and input elements other than a touch screen element 256 or handset 258 (e.g., keypads or a keyboard) may be provided to accept user inputs.

The kiosk device 190 device includes a controller 260 including a processor 262 and a memory storage 264 wherein executable instructions, commands, and control algorithms, as well as other data and information required to satisfactorily operate the kiosk device 190 as described herein are stored. The memory 264 of the processor-based controller may be, for example, a random access memory (RAM), and other forms of memory used in conjunction with RAM memory, including but not limited to flash memory (FLASH), programmable read only memory (PROM), and electronically erasable programmable read only memory (EEPROM) may likewise be included. The controller 260 may be contained within the cabinet housing 252, may be external to the cabinet housing 252 but near the cabinet housing 252, or may be remotely located from the cabinet housing 252 and/or remotely located from the correctional facility in various contemplated embodiments.

Via the touchscreen monitor 256, an inmate user may login to the kiosk device 190 as a pre-registered inmate user in order to use kiosk services offered via through the mobile tablet computer devices or via the touchscreen 256 and handset 258. Such services may include audio/video visitation services, email services, web browsing or web content services, phone call services, appointment or scheduling services, financial account services, educational services, commissary services, or other services offered to inmates as revocable privileges across an inmate population in a correctional facility. Such inmate privileges are revocable in the sense that they may be granted, revoked or suspended for a definite period of time or an indefinite period of time in view of inmate status and behavioral considerations over time. As such, the same inmate user over a period have time may have privileges (or may not have privileges) to access some or all of the features available via the computer kiosk device 190. Likewise, the same inmate user may over a period of time be subject to more or less limitation or restriction on certain types of privileges due to inmate status and behavioral considerations.

Accordingly, the computer kiosk device 190, via the controller 260, accepts unique login information from an inmate via the touch screen monitor 256 and/or the telephone handset 258 so that each inmate accessing the kiosk device 190 can be uniquely identified and privilege status of the inmate as identified can be verified or confirmed on demand at each time of access by respective inmate users. Aside from username and password/PIN number log-in, the computer kiosk device 190 may include and incorporate biometric identification hardware and software elements to perform fingerprint analysis/comparison, voice analysis/comparisons, facial recognition, retinal scan/comparison, etc. to achieve varying additional degrees of security and/or user convenience.

In contemplated embodiments, video-based voice biometric identifications are employed as an added security feature for video visitation sessions or alternative purposes as desired. In such video-based voice biometric identification, the audio is extracted from the video feed and is analyzed to identify the person(s) participating in the video conference. Alarms or alerts can be generated if unauthorized persons are detected in a video visitation session.

The touchscreen monitor 256 and the telephone handset 258 may be utilized by an inmate user as desired to complete activities that do not require a tablet computer device to accomplish. When a tablet computer device 140 is desired, however, the kiosk system can be utilized to automate a check-in, check-out process and ensure that a plurality of tablet computer devices 140 are adequately charged for use and re-charged in periods of non-use when in the tablet charging slots 254 of the cabinet housing 252.

When a tablet computer device 140 is received in one of the slots of the cabinet housing 252, the tablet computer device may further be locked in place by a locking mechanism including a lock actuator 270, operable by the kiosk controller 260. An inserted tablet computer device 140 may therefore be directly engaged and locked to the slot in which it has been inserted, preventing removal from the kiosk device 190 until the locking mechanism is operated by the controller 260 to unlock it. Additionally, in contemplated embodiments the tablet computer devices 140 may be supplied with protective cases such as that shown and described in FIG. 1 above that are compatible with the kiosk device 190. The lock actuators 270 may operate with respect to the protective cases to prevent removal of the tablet computer devices 140 when the lock actuators 270 are in lock positions.

Once the tablet computer device 140 is received and locked in place in one of the slots of the kiosk device 190, the tablet computer device 140 may be charged via charging circuitry 272 provided in the kiosk device for the devices 140 in each slot. Any number n of tablet computer devices 140 can be simultaneously locked in place in the respective slots and charged at once via the charging circuitry 272. In contemplated embodiments, the device charging occur wirelessly via inductive charging circuitry and the like, or may occur via engagement of charging contacts in the kiosk device and charging contacts of the tablet computer devices 140 via engagement, for example of a dock and pin connection or plug and socket type of engagement that results in a non-wireless charging connection. The respective tablet computer devices 140 in each respective slot may be individually lockable or unlockable via lock management hardware/software 274 operating the lock actuators 270 or may be lockable or unlockable as a group. Indicators 276 may be provided to indicate the status of each lock in any manner desired for the n number of tablet devices 140 accommodated.

In the example shown, battery charge management hardware/software 178 may also be provided in the kiosk housing cabinet 252 and may also be associated with slots to selectively operate charging sensors and/or charging circuitry 272. Charging indicators 280 may be provided to visually indicate the state of charge in each of the n number of tablet computer devices 140. The charging circuitry 272 includes any AC/DC or voltage/current conversion circuitry required to convert electrical power from a main power supply 182 to charge the tablet devices 140 in the slots provided.

In contemplated embodiments, the kiosk device 190 is configurable to include different numbers of slots 254 in modular form via modular component assemblies that can be combined in any number at an initial time, and thereafter additional modular component assemblies may be added or existing modular component assemblies may be removed to increase or decrease the number of charging slots 254 in the kiosk system and flexibly meet the needs of different correctional facilities that require different numbers of tablet computer devices 140. For example, the computer kiosk device 190 could be fabricated in a first component sub-assembly, and a second sub-assembly including additional tablet computer slots is separately fabricated and provided as an expansion charge module 290 which has similar locking, charging and indication features that may be managed by the kiosk controller 260. In the context of the present disclosure the first sub-assembly is sometimes referred to as a main kiosk device assembly and the second sub-assembly is an add-on modular assembly including additional tablet computer slots wherein additional tablet computer devices 140 may be lockably received and charged when not in use. Such an add-on assembly including additional tablet computer slots is sometimes also referred to herein as a modular charging bay.

The first and second sub-assemblies 190, 290 may be provided in modular, plug and play form that can be easily coupled together mechanically and electrically in a daisy chain arrangement or another arrangement including compatible mechanical and electrical connectors. When desired, a third component sub-assembly 290 could be provided that, similar to the second sub-assembly described above, includes another set of additional tablet computer slots 254 so that the kiosk can easily be configured to have an expanded number of charging slots 254. Any number n of modular sub-assemblies 290 can be mixed and matched with a main kiosk assembly to provide the optimal number of charging slots 254 in the assembled computer kiosk system in an optimal manner for any given correctional facility. The number n of modular sub-assemblies or modular charging bays can be increased or decreased over time to accommodate changing needs and circumstances of correctional facilities over time. In some cases, the main kiosk assembly need not itself include any charging slots at all so long as the desired number of charging slots 254 are provided in an add-on modular sub-assembly or in a combination of add-on modular sub-assemblies. As such, the add on charging bays 190, 290 could be operated by a controller in a device that does itself including charging slots 254. Also, more than one controller 260 could be provided in the configurable kiosk system provided that the controllers are coordinated with one another for the management purposes described below.

The modular component sub-assemblies 190, 290 may be removed and replaced to ensure full operation of the computer kiosk system in the event that one of the modular sub-assemblies needs maintenance or service for the locking assemblies, charging circuitry, etc. Spillproof drainage features may also be implemented in cabinet housing 252 (and in cabinet housings of the modular charging bays 290) for reliable operation thereof.

The electronically controlled lock management hardware 274 may be programmed to implement a managed locking system to lock and unlock tablet computer devices 140 as desired, as well as to log and record inmate information relative to each tablet device 140 accessed, which may in turn be remotely viewed by a correctional facility administrator who wishes to see which of the tablet computer devices 140 has been checked out and specifically to whom and for how long. The electronically controlled charge management hardware 278 may likewise be programmed to implement a managed charging system wherein charging power would only be provided in a given tablet computer slot when actually needed for charging a tablet computer device 140. When charging power is not needed, either because a tablet computer device 140 is not present in a tablet computer slot or because the tablet computer device 140 is fully charged, the charger circuitry 272 may be disconnected from the main power supply 282, thereby reducing energy consumption by the computer kiosk system. Individual charging of the tablet computer slots can also be activated and deactivated on a set schedule for charging, or manually activated by a correctional facility administrator when needed.

As an aspect of the lock management, apart from the computer kiosk system itself and the interface provided where an authorized inmate present at the location of the kiosk system may login to access a tablet computer device 140, remote actuation of the physical locks 270 is also possible. For example, an administrator via an administrator interface may click on an unlock button provided on the interface to unlock a specific tablet device 140 or a group of tablet computer devices 140 from a remote location. An administrator therefore need not physically access the computer kiosk system at its particular location to unlock a tablet device 140 for retrieval and use. Lock and unlock commands may therefore be generated through the administrator interface and communicated to the physical locks 270 to provide a degree of redundancy or improved convenience if an authorized inmate user has difficulty checking out a locked tablet computer device 140.

The tablet computer devices 140 may also be configured with Factory Reset/Safe Mode Protection. In contemplated embodiments, safe mode and factory reset may be enabled or disabled either locally on the tablet computer device 140 or from a remote location to provide the necessary security (or not) for certain users such as inmates, or for certain types of inmates, to make sure that the user cannot breach the tablet computer device 140 for improper use or access to unauthorized services, apps web content, etc.

In general, a factory reset of the tablet computer device 140 would revert the settings of the tablet computer device 140 to default factory settings that could potentially circumvent any security measures or security safeguards for certain types of end users (e.g., inmate users). While perhaps a factory reset may be advisable and unobjectionable for use by certain users and/or to address certain issues that the tablet computer device 140 may experience, access to the factory reset should be carefully controlled and preferably not be made available to other types of users. As such, in certain embodiments the factory reset option may not be accessible on the device 140 itself but instead may be accessed only by a system administrator, who may be a correctional facility administrator, to individually authorize a factory reset of a tablet computer device 140 or a group of tablet devices as desired.

Likewise, activation of a “safe mode” of the tablet computer device 140 has potential to bypass any network/security measures that have been put in place and therefore provide a user of the device 140 unrestricted access to web content that would be inherently undesirable in certain environments such as correctional facility use by an inmate. While perhaps “safe mode” operation may be advisable and unobjectionable for use by certain users, access to safe mode should be carefully controlled and preferably not be made available to other types of users. As such, in certain embodiments the safe mode option is not made accessible on the device 140 itself, and instead may be accessed only by a system administrator, who may be a correctional facility administrator, to individually authorize safe mode operation of a tablet computer device 140 or a group of tablet computer devices as desired and as further illustrated in the administrative interfaces described further below.

The kiosk system communicates with the kiosk services system 120 that is operative in reference to database 160 which includes correctional facility data and information, authorized inmate information and data, inmate privilege information and data, and non-inmate user data such as pre-authorized remote visitor data, financial account data and other data and information needed to perform the functions described.

The tablet computer devices 140, once removed from the kiosk system may wirelessly communicate with the kiosk services system 120 and may be utilized by the inmate to conduct visitations sessions or to participate in other services made available via the kiosk services system to inmate users. Depending on system setup, the inmate user may or may not need to log-in into a tablet computer device 140 to connect with the kiosk services system 120 after successfully obtaining access to one of the tablet computer devices 140. In contemplated embodiments, a tablet computer device 140 may be checked-out by an inmate user for a predetermined amount of time which may depend on availability of funds to cover any charges for use of the tablet computer device 140. In some cases wherein no financial funds are available, an inmate may not be able to check-out one of the tablet computer devices 140 at all, despite being an authorized user having active privilege status that would otherwise permit the inmate to use one of the tablet computer devices 140.

For monitoring and oversight, the kiosk services system may include an administrator interface 228 and database 292 including similar or different information to the database 160. Authorized, correctional facility administrators may log-in and access the administrator interface 228 via respective administrator computer devices 130 and select or adjust system settings and preferences, as well as oversee inmate use of the tablet computer devices 140. Any number n of administrators and administrator computing devices of any kind (e.g., dedicated computer terminal or workstation, desktop computer, laptop or notebook computer, tablet computer, smartphone, etc.) may be accommodated.

Correctional facility administrators, via the computer devices 130 and the administrator interface 228 can locally or remotely view a state of charge (e.g., charge %) of individual tablet computer devices 140 in the computer kiosk system or individual tablet computer devices 140 that are removed from the computer kiosk system for use, and facility administrators can enable or disable privileges of individual inmates to use the kiosk system to access one of the tablet computers 140. Administrators can also locally and remotely monitor specifically which one of the tablets 140 is checked out and which one of the inmates checked it out. Administrators can likewise locally and remotely monitor which of the respective tablet computer devices 140 has been returned and checked in, and whether each tablet computer device 140 was turned in on time and slotted properly by an individual inmate in the kiosk system. Administrators may also locally or remotely view and monitor a detailed audit trail of each tablet computer device 140 as it is used over time. Real-time monitoring of specific use of a tablet computer device 140 is possible, such as a monitoring of an online visitation session in progress with a remote visitor, or activity can be recorded and saved for subsequent recording and security monitoring. Privileged communications with legal counsel or clergy may be excepted from security monitoring or recording as needed. Detailed archives may be obtained and reports may be generated for use by administrators for investigative purposes or to assess overall use and performance of the computer kiosk system as it is used by inmates. Different levels of access may be provided to different administrators to oversee the status, use and operation of the various different devices utilized in the system 100 as further described below.

Alarms and notifications may be provided to administrators via the computer devices 130 and the administrator interface 228 to alert them of failed log-in attempts by inmates, improper attempts to obtain a tablet computer device by inmates, error conditions of the computer kiosk system or error conditions of the respective tablet computer devices 140, improper use of a tablet computer device 140, tablet computer devices 140 that are not timely checked-in or returned to one of the tablet computer slots, or other events of interest to the security needs of the facility that may require the attention of and possible intervention by an administrator.

The controller 260 may intelligently detect an addition or removal of expansion modules 290, and may cause notifications or alerts to administrators of a change in configuration of the computer kiosk system as an appropriate security safeguard.

While FIG. 4 illustrates an exemplary architecture of the computer kiosk device 190 according to an exemplary embodiment of the invention having certain benefits described, alternative system architectures are possible to realize at least some of the benefits described to the same or different degree.

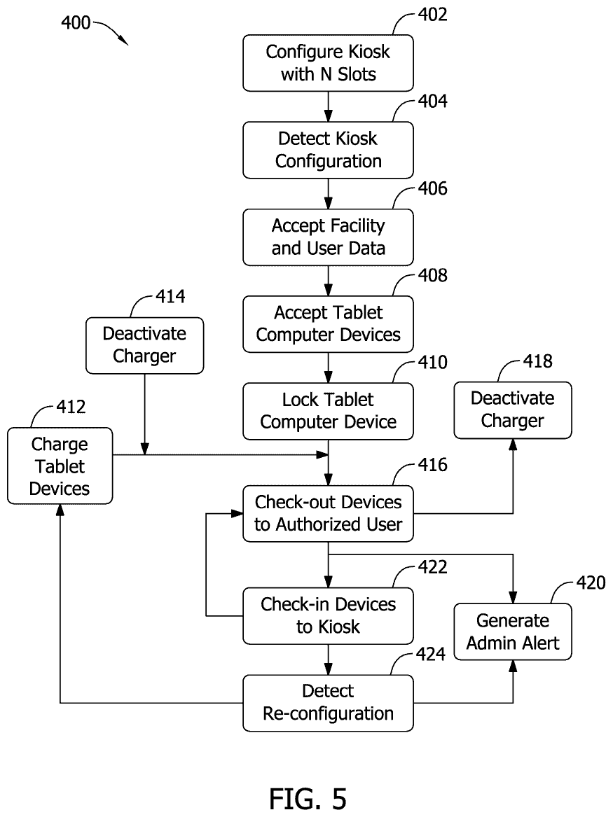

FIG. 5 is a method flowchart of processes 400 implemented by the computer kiosk system shown in FIG. 4. The processes may be implemented as algorithms in the programming of the kiosk controller 260.

At step 402, the computer kiosk system is configured with a number n of tablet computer slots as described above in a combination of a first sub-assembly and at least one second sub-assembly of units having tablet charging slots, tablet locking features and the other functionality described. The configuration at step 402 may be performed by the manufacturer of the kiosk as an initial preparatory step of the method 400, or may be completed on-site by a kiosk system installer at a correctional facility by assembling modular component sub-assemblies to realize the desired number n of tablet slots 114 at a point in time subsequent to initial installation. The configuration step 402 may also optionally include fastening the kiosk to a wall or support as described, although embodiments are contemplated wherein the configured system is portable or freestanding and therefore not fixed in place to a wall or support in certain installations.

At step 404, the kiosk system is fully assembled and installed and powered on, and the controller 260 then detects its configuration to determine the number n of tablet slots in the system as configured. Step 404 may include uniquely identifying each of the number n of tablet slots for subsequent use and tracking of tablet computer devices 140.

At step 406, facility and user data is accepted. The facility and user data may include information unique to each correctional facility that connects to the kiosk services system 120 and inmate user data such as identification data and biometric data used to securely identify inmates logging into the computer kiosk system or a tablet computer device 140 that is successfully checked-out and removed from the computer kiosk system. The user data may also include financial account information which may be applied as a restriction to whether an inmate may check out a tablet computer device 140 or as restriction for how long the tablet computer device 140 may be checked out. The user data may also include administrator data including administrator identification and login data and administrator preference data. Data and information accepted at step 406 may be directly or indirectly received, and may include access to the kiosk service database 160 or the administrator database 292. The technical effect of the processes and systems described herein is achieved when such data and information is entered, transmitted, downloaded or otherwise accepted by the computer kiosk system or made available to the processor-based kiosk system via the aforementioned databases.

At step 408, tablet computer devices 140 are accepted into the number n of tablet slots. The tablet computer devices 140 may be self-identifying to the kiosk system as they are inserted into the respective slots using, for example, a machine readable bar code or another machine readable element recognized by the system. Near Field Communication (NFC) using a known protocol, short-range communication via known Bluetooth standards and protocol, or Wi-Fi communicating via a Local Area Networking (LAN) according to known protocols may also facilitate automatic identification of tablet computer devices 140 to the kiosk system. Alternatively, each tablet computer device may be assigned a unique identity as it is inserted into the respective tablet computer slots of the kiosk system. Likewise, the computer kiosk system may include dual in-line package (DIP) switches and the like to enable the functionality described. Regardless of how the tablet computer devices are identified, the computer kiosk system can then know specifically which tablet computer device has been checked-out to which inmate for monitoring and oversight purposes in the correctional facility. The tablet computer device identification data for each tablet computer device being managed through the system may be stored in one of the system databases and retrieved when needed.

At step 410, the tablet computer devices 140 are locked in the number n of tablet computer slots via the locking mechanisms and actuators 270 provided. Charger circuitry 272 may then be activated at step 412 to charge the tablet computer devices 140 individually or as a group by connecting the charger circuitry 272 to the power supply 282. The battery charge on each tablet computer device 140 can then be monitored, and when each device 140 is fully charged the respective charger circuitry 272 can be disconnected at step 414 from the power supply 282 to reduce power consumption. In contemplated embodiments, priority charging is executed, wherein tablet computer devices 140 having the lowest battery charge are charged first before a charging of tablet computer devices having a higher charge. In the priority charging scenario, charging circuitry outputs may be shared in the various different tablet computer slots and thus a one-to-one relation of charging circuits and tablet slots is not necessarily required and more energy efficient charging of a plurality of tablet computer devices is possible.

At step 416, the controller 260 of the computer kiosk system allows check-out of a tablet device 140 to an authorized user. Step 416 includes accepting login data and any biometric data to uniquely identify an inmate user, and comparing such login and biometric input received to the user information in the system database(s) to confirm that the inmate user is authorized to access a tablet computer device 140 and has an active and current privilege status that does not revoke or suspend the authorized access at the time the inmate logs in to the kiosk computer system. If the inmate user is not identified as an authorized inmate user, or if an identified and otherwise authorized inmate user is subject to privilege revocation or suspension of privilege that bars access to a tablet computer devices, access to a tablet computer device 140 is denied by the system. Otherwise, access to a tablet device 140 is granted to an identified and authorized user, and one of the tablet devices 140 is unlocked for retrieval and use by the identified, authorized user. An indicator may be lit to show the inmate user which of the tablet computer devices 140 to retrieve, and the inmate user may simply pull the unlocked tablet computer device 140 from the tablet computer slot 1 for use. Optionally, an unlocked computer device 140 may in some embodiments be partially ejected from one of the tablet computer slots as a visual cue for the user to retrieve the unlocked tablet computer device 140.

When a tablet computer device 140 is removed by the inmate user, at step 418 the charger circuitry 272 for the slot from which the tablet computer device 140 has been removed is optionally disabled. Timers and the like may be set for the removed tablet computer device 140 to be returned, which may be displayed to the inmate user on the screen of the tablet computer device 140. After removal from the tablet computer slot, the inmate user may re-enter login information to the tablet device 140 when needed to connect to the kiosk services system 120. Otherwise, the tablet computer device 140 may automatically connect to the kiosk services system 120 when removed from the tablet computer slot. Regardless, once the tablet computer device 140 is connected to the kiosk services system 120, the inmate user may proceed to use any service provided and made accessible to the inmate user, including but not limited to video visitation services.

If the inmate user does not timely return the tablet computer device 140 at the expiration of the timer, a notice or alert may be generated to administrators. Notices or alerts may likewise be generated for any detected misuse or error condition of the tablet computer device 140 or the computer kiosk system. Such notices or alerts may be generated and delivered to administrators in any form via any medium desired in an active or passive alert (e.g., email, SMS text notification, voice message, push notification, etc.).

While the tablet computer devices 140 are checked-out, administrators may locally or remotely monitor inmate use of the tablet devices 140 as described above. The extent and nature of the inmate's use of the tablet computer device may be recorded and archived in system databases and detailed reports may be generated on an inmate-by-inmate basis or a group basis, as well as on a device-by-basis basis or based on a group of devices.

At step 422, the tablet devices 140 are checked-in as inmate users return them to one of the tablet computer slots. The tablet computer slot for return of the tablet computer device may or may not be the same slot from which the tablet computer device 140 was removed at check-out. The inmate user may log back into the computer kiosk system as part of the check-in process so that the system 100 knows which inmate is checking-in the tablet computer device 140. In embodiments wherein the tablet computer devices 140 are self-identifying to the computer kiosk system, the kiosk system can also confirm that the inmate user is returning the same tablet computer device 140 that was checked out. The check-in time and any details are recorded by the system as a reportable event that is archived for subsequent retrieval when needed. The checked-in tablet computer device 140 is automatically locked and re-charged by activating the charger circuitry for subsequent use when checked out again. In some embodiments, only fully-charged tablet devices 140 are made available for check-out.

At step 424, the kiosk controller 260 detects a reconfiguration of the computer kiosk system when tablet charging slots of modular charging bays 290 are added or subtracted. At step 420, an active or passive notice or alert is generated to administrators that the kiosk system has been reconfigured so that the administrators may act accordingly to oversee the use of the reconfigured number of tablet computer slots and associated change in tablet computer devices usable with the kiosk system. In the event of system maintenance wherein a modular component sub-assembly is swapped out because of a maintenance or service procedure, the kiosk controller 260 can detect the change and notify administrators accordingly. Attempts to tamper with the system can therefore readily be detected.

FIG. 6 is a front view of an exemplary embodiment of the kiosk device 190 for the system 100 shown in FIG. 4 and the method 400 shown in FIG. 5. The kiosk device 190 may be duplicated as an expansion charge module 290 (FIG. 4) to realize a configurable and scalable kiosk system in modular form to flexibly accommodate different inventory sizes of portable computer devices such as the tablet computer devices 50 (FIG. 1) in a correctional facility and avoid more expensive custom fabrication of kiosk devices to serve different inventory sizes and/or to avoid an obsolescence of kiosk devices when inventory sizes change due to fluctuation in inmate populations over time. The kiosk device 190 is sometimes referred to as a modular charging bay device which can be used in a stand-alone manner or in combination with similar charging bay devices to vary the number of tablet devices that can be accommodated and charged in the kiosk system.

As shown in FIG. 6 the kiosk device 190 includes a cabinet housing 252 which defines a generally flat and vertically extending front face 300 which extends parallel to a vertical wall 302 upon which the device 190 is mounted. The front face 300 is generally elongated and rectangular, and the cabinet housing 252 includes upper and lower portions 304, 306 each including a generally rounded portion adjacent the front face 300 and angled sections extending from the rounded portion toward the wall as shown. The cabinet housing 252 may be fabricated from cold-rolled steel that is powder-coated for corrosion resistance. The cabinet housing 252 is generally tamper proof and resistant to environmental conditions. The front face 300 and portions 304, 306 may be removable for service of interior components and may sealingly engage with a gasket and baffle arrangement to realize a waterproof housing. Front-mounted curved screws may allow service without breaking the seal.

Access openings are provided through the front face 300 for insertion and removal of a tablet computer device 50 (inside the case 52) from a number of charging slots 254 located just behind the access openings. In the illustrated example, four access openings and four charging slots 254 are provided in the device 190 which extend generally horizontally across the front face 300 in a spaced apart, aligned and generally parallel orientation to one another along a longitudinal height dimension of the front face 300 and also generally centered in the lateral width dimension of the front face 300. In another embodiment, however, greater or fewer than four access openings and greater or fewer than four charger slots 254 may be included, and the orientation of the charging slots 254 and access openings may be varied as desired.

In the example shown, the access openings each include a linear, continuously extending lower edge 308 extending horizontally across the front face 300 and an upper edge 310 extending opposite the lower edge 308. Unlike the lower edge 308, the upper edge 310 is discontinuous and includes a pair of lower linear portions on each side of an upper linear portion that is centrally located in the upper edge 310. Angled sections connect the lower linear portions and the ends of the upper linear portion in the upper edge 310. The lower linear portions of the upper edge 310 extend generally parallel to the lower edge 308 at a first distance therefrom, and the upper linear portion extends generally parallel to the lower edge 308 at a second distance therefrom which is greater than the first distance.

The upper linear portion of the upper edge 310 beneficially provides an additional amount of space or an additional amount of clearance for a user's hand to insert or retrieve a device 50 by grasping a rear portion or bottom portion of the case 52 which defines a grip portion for the user's hand. Comparing FIGS. 1 and 6, it is seen that the devices 50 are inserted through the access openings and into the charging slots 254 in an upside-down orientation where the legs of the integral stand portion 54 extend upwardly as shown in FIG. 6 instead of downwardly in FIG. 1 for normal use of the device 50 with the legs of the integral stand portion 54 extending beneath the device 50.

In contemplated use of the device 190, users may partially insert one hand into one of the access openings of a charging slot 254 with the palm of their hand extending over the rear of the case 52 and wrap their fingers around a portion of the case 52 to grasp or grip the case 52 and the associated device 50 in the case. The additional clearance of the access opening in the upper edge 310 provides space for a portion of the back of the user's hand (the dorsal side of the user's hand) and the user's top knuckles when grasping the case 52 of the device 50 while still inside the slot 254, and also provides space for the user's hand to be removed from the access opening while holding the case 52 and device 50 without the user's hand or knuckles scraping or otherwise contacting the upper edge 310 of the access opening.

Likewise, in contemplated use of the device 190, users may hold the case 52 of the device 50 in an upside-down orientation with one hand and then insert the case 52 and a portion of their hand into an unoccupied one of the access openings before releasing the case 52 in the charging slot 254. After letting go of the case 52 for the device 50, the additional clearance of the access opening in the upper edge 310 provides space for the user to remove the back of the user's hand (the dorsal side of the user's hand) and the user's fingers without the user's hand or knuckles scraping the upper edge 310 of the access opening.

In the illustrated example, the lower edges 308 of the access openings extend horizontally end-to-end for a distance about equal to the longitudinal width dimension W of the upper side of the case 52 (FIG. 1) of the device 50. The upper edges 310 of the access openings have a slightly reduced end-to-end length than the lower edges 308, such that the lateral end edges of the access openings interconnecting the edges 310, 308 are angled rather than vertical. The shape of the access openings in the angled end edges follows a tapered shape of the case 52 on the lateral side edges of the of the device as shown in FIG. 6. The access opening shape and the shape of the case may be varied in further and/or alternative embodiments as desired. So long as the access openings and the cases 52 have complementary shapes, the devices 50 may be safely inserted and secured to the charging slots 254

The device 190 includes or is in communication with the kiosk controller 260 which may address the charging slots 254 of the unit to activate and deactivate charging circuitry, manage device content, and activate locking features to secure the devices 50 when in the slots 254. The touch screen 256 (or the handset 258 (FIG. 4)) may be provided on or in the device 190 or may be separately provided for purposes of accepting user login information from inmate users. The kiosk controller 260 may likewise be provided in the device 190 or separately provided in different contemplated embodiments.

In a contemplated embodiment, when an inmate user enters login information with the touch screen 256 (or the handset 258 (FIG. 4)), the kiosk controller 260 may verify the user as an authorized user and also assess inmate privileges for access to one of the device 50 in the charging slots 254 by the authorized user. If the authorized user is verified with active privileges, the locking mechanism may be unlocked for the user to retrieve one of the devices 50. A user may also enter log-in information to return a device 50 to the kiosk device 190, and once the login information is verified the locking mechanism may be unlocked to allow the user to insert the device 50 into an unoccupied charging slot 254.

In another contemplated embodiment, the locking mechanism of the kiosk device 190 may be programmable to unlock all of the tablet devices 50 for retrieval and return within a predetermined window of time. In such an embodiment, and during the predetermined window of time, all of the tablet devices 50 are unlocked, and any of the available devices 50 may therefore be retrieved from the slots 254 without prior identification of the user (e.g., an inmate). The user therefore needs to complete log-in to the device 50 with user id, password, and any biometric verification required. Once successfully logged in to the device 50, the AV services system 120 can confirm inmate privilege status and apply any related user restrictions and also match the inmate user with a specific device 50 for monitoring and oversight purposes in the use of the device 50 for kiosk service functionality. The device 50 may automatically cease kiosk service functionality and logout from the kiosk services system at the expiration of a time limit, or the user may alternatively logout from the device 50 in a voluntary manner prior to expiration of the time limit. Once logged out, the user may return the device 50 via re-insertion into an unoccupied one of the charging slots 254 during the predetermined amount of time while the locking mechanism remains unlocked. When the predetermined window of time expires for the charging bay, the locking mechanism is engaged and all of the devices 50 in each charging bay are securely stored until the next scheduled unlocking event where they may again be retrieved and removed from the charging bay.

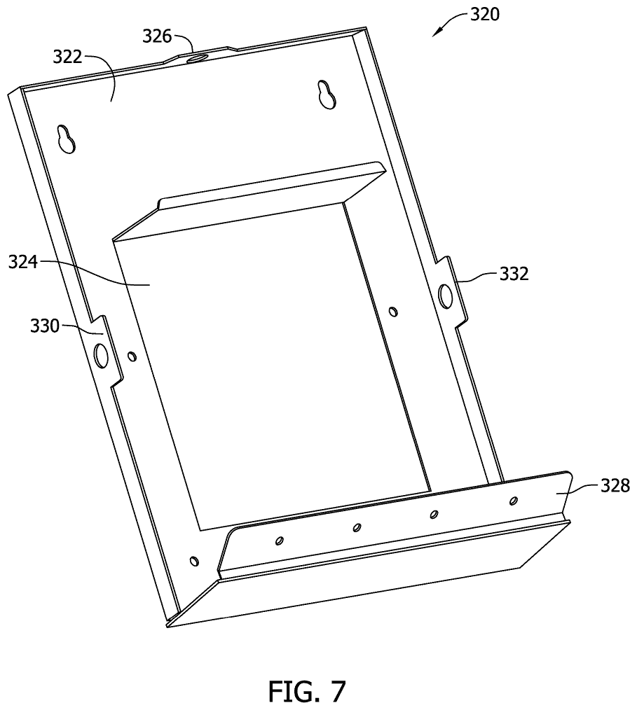

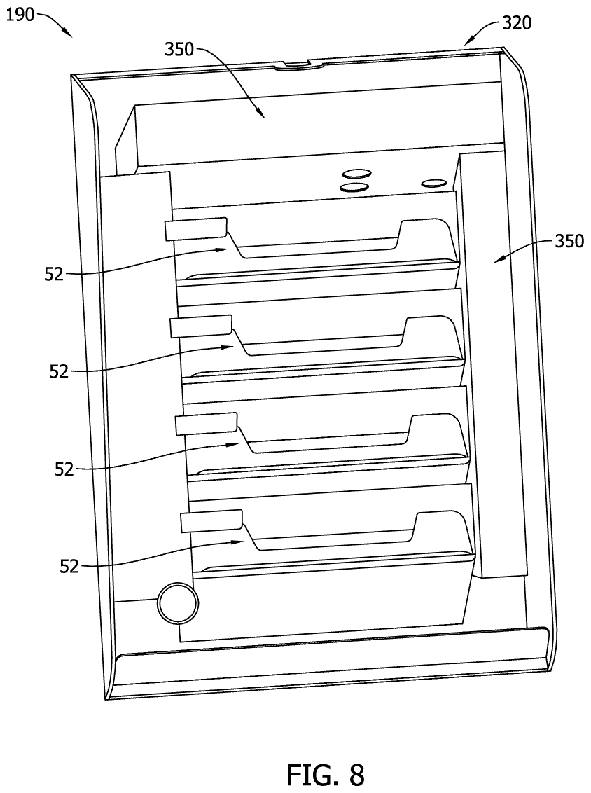

FIG. 7 is perspective view of a wall mounting bracket 320 for the kiosk device/modular charging bay 190 shown in FIG. 6. The bracket 320 includes a flat back plate 322 that extends generally flush with the wall 302 and may be fastened thereto with fasteners extended through the keyhole openings or the other apertures provided in the back plate as shown. The bracket 320 also includes a space between overhanging portions of the bracket in which the tablet charging slots 254 extend in the assembled device 190, and a number of attachment flanges 326, 328, 330 and 332 for securing portions of the cabinet housing 252 to the bracket 320 with fasteners as shown in FIGS. 8-10 in a secure manner suitable for correctional facility use.

In the installation of the device 190, the mounting bracket 320 is first attached to the wall 302 and the remainder of the device 190 may be provided as a reinforced chassis including the charging pockets, locking mechanisms and electronic controls which may be hung on the bracket 320 and attached to the bracket 320 in a secure manner. When so assembled, the weight of the device 190 is carried by the vertical wall 302 with the top and bottom of the kiosk device 190 being separated from the floor and ceiling of the correctional facility. That is, the device 190 is neither supported by the floor or ceiling when installed to the wall 302 with the bracket 320. In some cases, however, the mounting bracket 320 could be considered optional and the device 190 could be otherwise supported by a floor, a table or other horizontally extending support structure instead of vertically oriented support structure of the wall 302.

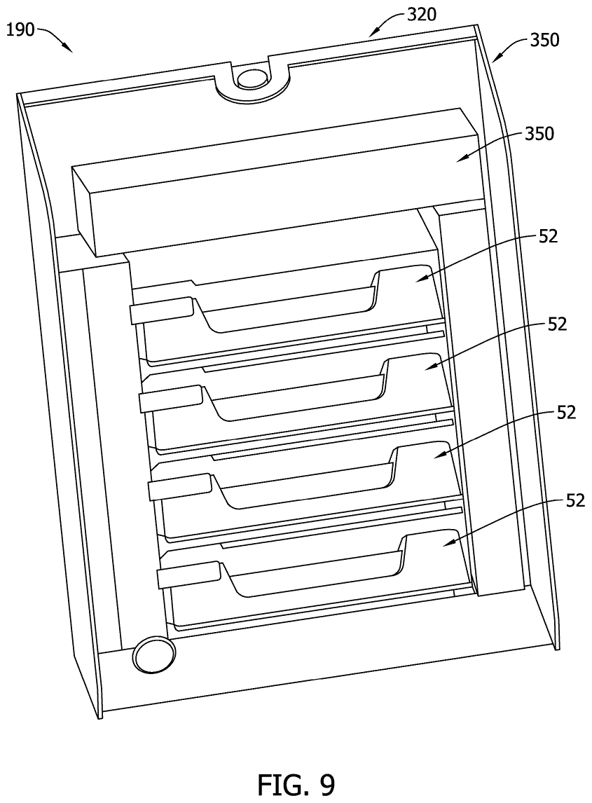

FIGS. 8-10 are various perspective views of the kiosk device/modular charging bay 190 and the mounting bracket shown in FIG. 7. The front face 300 and portions 304, 306 of the cabinet housing 252 are removed in FIGS. 8 and 9 to reveal a module assembly including opposed and parallel side supports and side panel sections with charging pockets 352 located therebetween which respectively define the charging slots 254 and receive the cases 52 of devices 50. A protected power supply and control board assembly 350 is located at the top of the device 190 above the charging pockets as shown in FIGS. 8 and 9. The power supply and control board assembly 350 and the charging pockets 352 are provided as modules which can be removed from one another and therefore be independently replaced as desired in the service of the kiosk device/modular charging bay 190.

The bottom of the control board assembly 350 includes drainage openings as shown in FIG. 8 to shed any fluids or moisture that may negatively impact the operability of the power supply or the control board. In a contemplated embodiment, the power supply is a Power-Over-Ethernet (POE) power supply which simplifies the installation of the device 190 in many facilities. Alternative power supplies are known and may be utilized, however, in lieu of or in combination with the POE power supply. Communications by the control board with other devices may be established via Ethernet as a default, and optionally via Wi-Fi/4G connections in contemplated embodiments.

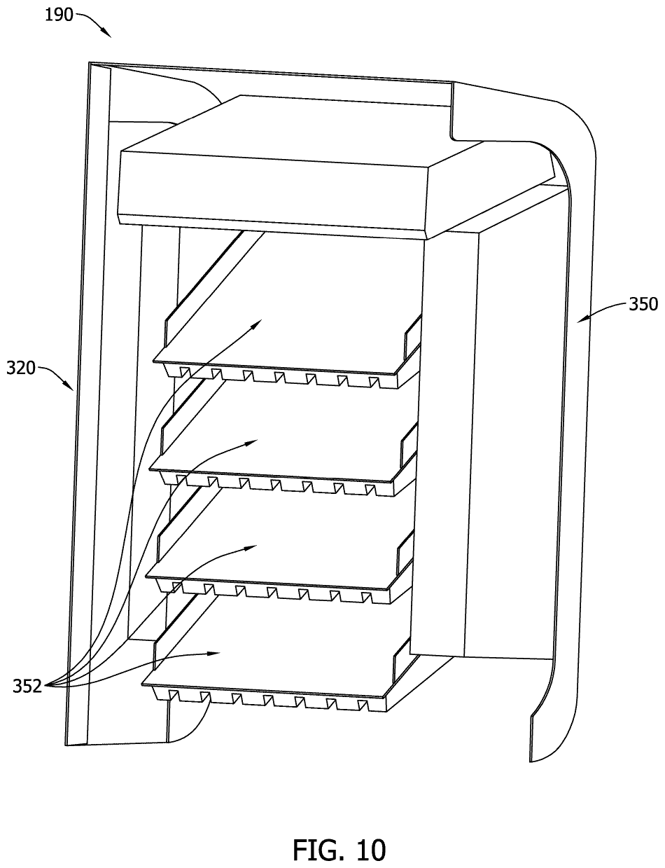

The charging pockets are shown in FIGS. 8-10 and extend downwardly at an angle relative to the front face 300, the wall 302 and the back plate 322 such that the depth of the assembly measured perpendicularly relative to the wall 302 is reduced while the cases 52 and devices 50 are entirely inserted into the charging slots 254. As shown in FIG. 10, the charging pockets are also tapered with a wedge shape such that the front side of the pockets adjacent the front face 300 defines a greater area than the rear side of the pockets adjacent to the back plate 322 and the wall 302. Because the device cases 52 include the stand portions 54 on one side of the case 52, the side of the case 52 including the stands 54 is deeper than the side of the case opposite the legs of the integral stand portion 54. The shallower area of the case (opposite the stand portions 54) can be inserted into the wedge-shaped pocket 352 in a one-way orientation only. If a user attempts to insert the cases 52 in a backwards orientation with the stand portions 54 first entering the access openings, the deeper stand portions 54 occupying a larger area will interfere with the wedge-shaped pockets 352 and prevent the case 52 and device 50 from being accepted in the slot 254 which the pocket 352 defines. As such, user error in inserting the case 52 and device 50 in a backward orientation which would preclude charging connections from being established in the pocket 352 on the shallower side of the case 52 is eliminated.

The downward angle of the pockets 352 also provides a gravity-assisted insertion of the cases 52 and devices 50 which avoids an incompletely inserted case 52 and device 50 in one of the pockets 352. Such gravity assistance also reliably completes charging connections between the ports of the device 50 and the connecting pins and connectors in the charging pockets 352. The alignment of charging pins and ports is enhanced by the wedge-shape of the pockets 352 which guides the path of the case 52 and device 50 and ensures alignment of the charging connectors in the charging pockets 352 and the charging port of the device 50. As such, any problematic misalignment or incomplete engagement of the charging connectors is beneficially avoided. Data connectors may also be provided in the charging pockets and may establish connection with data connectors in the device 50. In some cases, power and data connections may be established through a single connector in the charging pocket 352 and a single port of the device 50 via power pins and data pins and other known power and data connections to charge and exchange data in portable electronic devices. Spring-loaded pin connections and the like may be provided in the changing pockets to reliably establish power and data connections to devices 50.

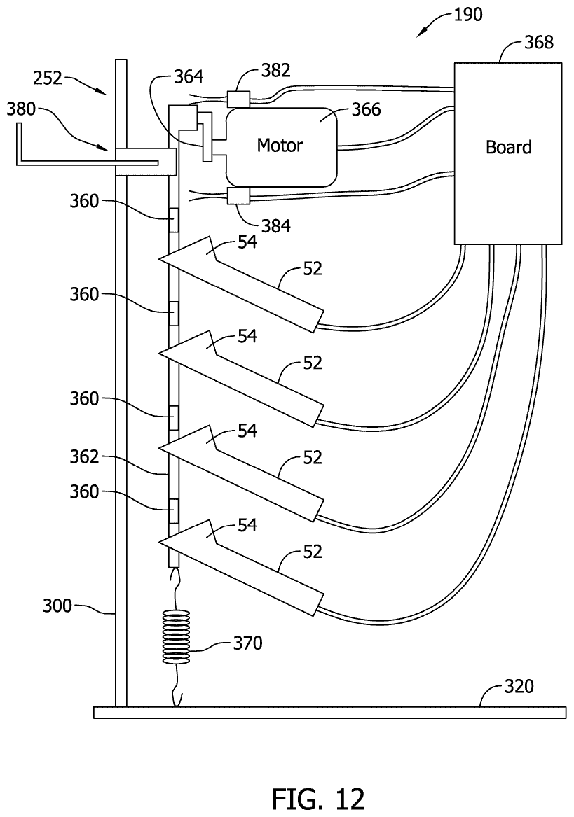

FIGS. 11 and 12 illustrate an exemplary locking mechanism for the kiosk device/modular charging bay 190. As shown in FIG. 11, generally rectangular and planar locking tabs 360 extend just behind the access openings and extend partly across the access openings for the charging slots 254. In the example illustrated the locking tabs 360 extend horizontally across about 20% of the of the width of the case 52. The locking tabs 360 extend in front of one of the stand portions 54 of the cases 52 for the devices 50 in a spaced relation from the upper edge 310 and lower edge 308 of the access openings. In the locked position shown in FIG. 11, the cases 52 and devices 50 cannot be removed from the charging slots because the locking tabs 360 block a passage of the stand portion 54 in each case 52.

In contemplated embodiments, the locking tabs 360 are automatically movable as a group between the locked position shown in FIG. 11 and an unlocked position wherein the locking tabs 360 are moved upwardly to clear the stand portions 54 and allow removal (or reinsertion) of the case 52 and device 50. The locking tabs 360 are also manually movable as a group between the locked position shown in FIG. 11 and an unlocked position. The locking tabs 360 may also be reinforced by a structural crease or fold making strengthening the tab to resist any tampering attempt to bend or deflect the tab. The locking tabs 360 may also be fabricated with an increased material thickness to provide structural reinforcement to resist any tampering attempt. The locking tabs 360 may be integrally formed and fabricated with the actuator link 362 from high strength materials such as metal for durability and resistance to being forced open or broken to improperly obtain access to the portable computer devices.

FIG. 12 schematically illustrates an operation of a locking mechanism for the locking tabs 360. The horizontal locking tabs 360 extend from a continuous and vertically extending actuator link 362. As shown in FIG. 12, the locking tabs 360 extend just behind the end of the case 52 of each device 50 when inserted into the charging pocket. The locking tabs 360 in the locking position obstruct the removal of the case 52 and device 50, without physically engaging the case 52 to realize a locking arrangement. This is sometimes referred to as a blocking mechanism that prevents removal of a case 52 and device 50 without positively engaging the case 52 and device 50. In this aspect, the locking mechanism is simplified relative to known locking mechanisms as it does not require an alignment of a locking projection and a locking aperture securing the case 52 or device 50 in position.

As further shown in FIG. 12, the actuator link 362 is interfaced at is top end with an eccentric wheel 364 driven by an output shaft of an electric motor 366. The eccentric wheel 364 converts a rotation of the motor output shaft to a linear movement of the actuator link 362. The actuator link 362 may be engaged to the wheel 364 in a known manner including an interlocking tooth or gear-like arrangement, with a known fastener, with a known bonding element (e.g., glue) or via another connector. Pulley arrangements and other known features may likewise by employed to realize linear movement of the actuator link 362 when the motor is energized to rotate the motor output shaft.

The motor 366 is responsive to a control board 368 which operates the motor 366 to reposition the actuator link 362 and to connect or disconnect (or energize and de-energize) charging circuity in the charging pockets 352 for the devices 50 in the cases 52. Wired connections are shown between the control board 368 to provide charging power and data connections to devices 50 which are fully received in the charging pockets 352 to establish charging connections and data connections as described above. The control board 368 may also operate charging indicators such as LEDs visible on the front face 300 adjacent each pocket with for example, multi-color functionality such as red, yellow and green functionality to indicate a battery charge of each tablet as unacceptably low (red), intermediate but not yet ready for use (yellow), or sufficiently charged (green) for full use and enjoyment of the tablet device for an expected time period of use.

The control board 368 is operable to power the motor 366 on demand or at a preprogrammed time to rotate the output shaft and the connected eccentric wheel 364, causing the vertical actuator link 362 to move upwardly in FIG. 12 to an unlocked position wherein the locking tabs 360 no longer obstruct the stand portions of the cases 52 of the devices 50. The motor 366 acts against stored energy in a coil spring 370 that tends to pull the link 362 downward to maintain the locked position of the tabs 360. As such, if the locking mechanism were to fail to provide a sufficient amount of opening force, the mechanism reverts to or otherwise maintains a failsafe locked position via the stored force in the spring 370. Beneficially, a failure in the locking mechanism at the top end of the link 362 cannot result in an unlocking of the cases 52 and devices 50 which defeats access controls and safeguards for the correctional facility.

To ensure that devices 50 may be made available when needed, the device 190 further includes an emergency key and barrel assembly 380 that a correctional facility administrator may manually use to unlock the cases 52 of devices 50 in the kiosk device 190. By inserting the key into the barrel and manually rotating the key, the actuator link 362 is moved upwardly by the barrel to the unlocked position against the stored energy of the spring 370. The spring 370 again returns the link 362 to the locked position as a failsafe measure when the user stops exerting force to rotate the key. Again, unintentional unlocking of the cases 52 and device 50 is avoided which would defeat security access controls and safeguards for the devices 50.

Lock state detection by the control board 368 is realized through an upper limit switch 382 which detects a state of the actuator link 362 in the raised unlocked position, and a lower limit switch 384 which detects a state of the actuator link 362 in the lowered locked position. The dual limit switches 382 eliminate ambiguity that a single limit switch would otherwise present in the actual state of the lock mechanism. For example, the upper limit switch in the example above can detect that the mechanism has fully unlocked but it cannot detect that it has fully locked. Likewise, the lower limit switch can detect that the lock mechanism has completely locked but it cannot detect that the locking mechanism has fully unlocked. By providing both of the limit switches, however, the lock state can be verified as fully locked or fully unlocked, and if neither of the sensors register a locked or unlocked state the mechanism has failed somewhere between the locked state and the unlocked state. As such, the dual limit switches 382 can detect a successful change of lock state between the locked and unlocked state, a successful change of lock state between the unlocked and locked state, and an unsuccessful change of lock state in either direction (i.e., from locked to unlocked or from unlocked to locked). An unsuccessful change in lock state, as detected by the limit switches 382, can be the result of a change in progress (i.e., the actuator is moving from one state to the other but has yet to arrive in its final position to effect the change of state) or can be the result of a malfunction, error, or failure condition somewhere in the mechanism which presents the lock or unlock state from being established.

The control board 368 communicates with the limit switches 382, 384 to intelligently sense the change in position of the actuator link 362 which carries the locking tabs 360, and as such the control board 368 may confirm the locked and unlocked position of the locking mechanism and record each locking event and unlocking event (i.e., a successful change in state from locked to unlocked and from unlocked to lock), whether made manually or automatically through the control board 368 and the motor 366. In the event that the locking mechanism malfunctions or fails and does not fully lock or unlock (as determined by the limit switches 382, 384) a notification can be generated by the control board 368 of an successful change in state or an error condition in which the desired lock state or unlock state has not been accomplished. Notification of the unsuccessful change in lock state or error condition can be communicated to a kiosk controller which generates a notification for attention of an administrator using an administrator device 130. Steps can be taken in response to the notification to investigate the affected lock mechanism, attend to any reset or repair of the lock mechanism or swap out the affected device 190 with another device 190 having a properly operating locking mechanism to restore full operation of the kiosk system. In some cases, another lock command to change the lock state may be issued from the administrator device 130 may cause the lock mechanism to restore itself without having to locally inspect the affected device 190. Such restoration of the locking mechanism may be confirmed (or not) with the limit switches 382, 384 and provide a degree of remote trouble shooting and diagnostic capability for the locking mechanism.

While the above-described kiosk device 190 with a combination of manual and automatic locking features is beneficial for the reasons stated, in another embodiment the kiosk device 190 may alternatively include manual unlocking with the key and barrel assembly 380 without the automatic unlocking operation of the motor 366 and wheel 364 to move the actuator link 362. The limit switches 382, 384 may still be provided with the control board 368, however, to perform state detection of the manual locking mechanism to record locking and unlocking events, and to communicate locking mechanism error conditions and generate desired notifications. Likewise, in still another embodiment the automatic unlocking operation of the motor 366 and wheel 364 to move the actuator link 362 may be provided without the barrel and key assembly 380 and the related manual unlocking capability, with the control board 368 detecting and recording locking and unlocking events and to communicate locking mechanism error conditions and generate notifications.

While specific automatic and manual locking mechanisms and features have been described, variations are possible and may be implemented in further and/or alternative embodiments of the kiosk device 190 with similar benefits and advantages. For example, in the arrangement of FIG. 12, the motor 366 and wheel 364 are interfaced at an upper end of the actuator link 362, whereas in another embodiment the motor 366 and wheel 364 may be interfaced with the actuator link 362 at another location such as a lower end of the actuator link 362. As another example, the key and barrel assembly 380 is located in an upper portion of the front face 300 in the cabinet housing 252 in the arrangement of FIG. 12, whereas in another embodiment the key and barrel assembly 380 may be located in a mid-portion or lower portion of the front face 300. Also, the spring 370 is located beneath the charging pockets in the arrangement of FIG. 12 and is biased to pull the actuator link 362 downward to the locked position, whereas in another embodiment the spring 370 may be located elsewhere such as above the charging pockets and be biased to push the actuator link 362 downward to the locked position. The operation of the mechanism described above in the arrangement of FIG. 12 may also be reversed such that the actuator link 362 moves upwardly to a locked position and downwardly to an unlocked position with the spring 370 biasing the actuator toward the upward locked position. Motor interfaces other than an eccentric wheel 364 to move the actuator link 362 are possible to move the link 362 between locked and unlocked positions, and sensor elements other than limit switches 382, 384 may be utilized to detect locked and unlocked positions of the mechanism. Variations in the location and geometry of the locking tabs 360, the actuator links 362 and the cases 52 of devices 50 are possible while still realizing secure locking and unlocking of tablet devices. More than one locking mechanism may be provided, and additional sensors may be provided to detect a position of more than one actuator link or additional gradations of movement for a single actuator link.

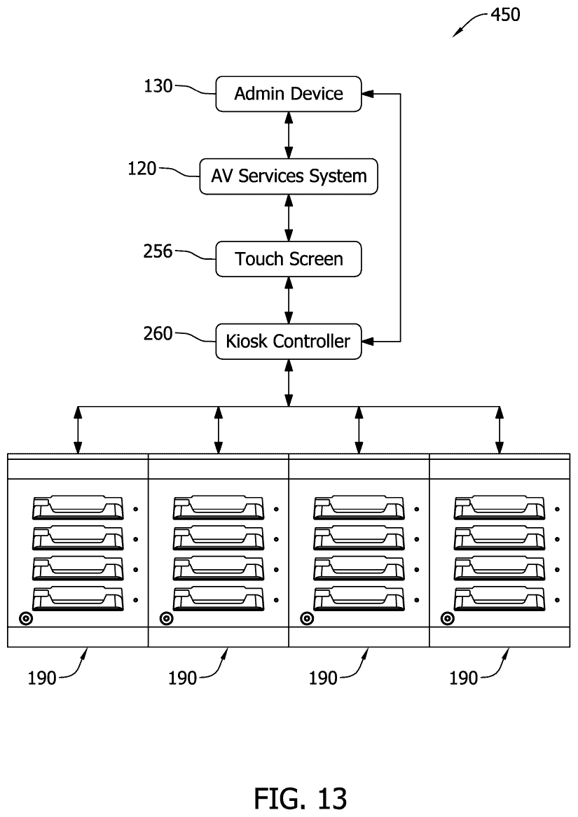

FIG. 13 is a front schematic view of a configurable kiosk system 450 including a plurality of kiosk devices/modular charging bay devices 190. Four devices 190 are shown side-by-side and are mounted to a wall in a correctional facility. Each device 190 communicates with a kiosk controller 260 which may address the charging slots in each device 190 and ascertain a status of charging of devices 50 and communicate with specific ones of the devices to perform any monitoring oversight and content management functionality. Data and information from the devices 190 may be communicated to the kiosk controller 260 and/or to the AV Services System 120 and stored in one of the aforementioned databases or in an additional database for purposes of the charging bay monitoring and oversight functionality described below.

The kiosk controller 260 may process user inputs made with the touch screen 256 (or the handset 258) to unlock one of the devices 190 for retrieval of a tablet device 50, which may then be used with the AV Services System 120 and overseen with an administrator device 130. Also, the controller 260 and or the local controller of each kiosk device 190 may cause the tablet devices to become unlocked automatically on a predetermined schedule and automatically locked again on a predetermined schedule, with users logging into the tablet devices 50 to assess kiosk services subject to user authorization authentication and assessment of inmate privilege status. While four devices 190 are illustrated in FIG. 13, the system 450 is scalable to include any number n of devices 190 and to accommodate and manage a tablet inventory of different sizes. Since the devices 190 are provided in a modular plug and play form, the kiosk controller 260 can automatically detect changes in the number of devices 190 provided and reconfigure itself accordingly. Devices 190 may be beneficially added and removed as tablet inventory sizes change over time in a correctional facility. The system 450 may universally meet the needs of correctional facilities using lower cost modular units that avoids a more expensive custom kiosk solution and obsolescence of kiosk units having a fixed number of charging slots.

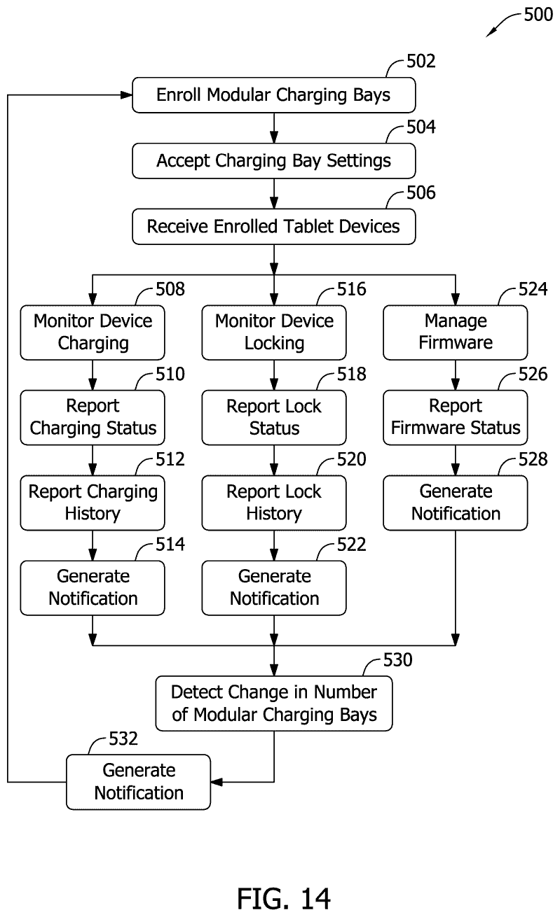

FIG. 14 a method flowchart of exemplary processes 500 implemented by and through configurable kiosk systems such as the system 450 shown in FIG. 13. The processes 500 may be implemented with one or more of the control boards or controller devices described above for the benefit of charging bay oversight via one or more of the administrator computer devices 130 running administrator interfaces and having access to a system database wherein charging bay device data is stored. The administrator devices 130 may communicate with a web-based, hosted services system including a centralized server system which, in turn, communicates with different configurable kiosk systems 450 and charging bays 190 thereof across a number of different correctional facilities offering kiosk services, including but not limited to the AV Services System 120. The kiosk controllers 260 of the configurable kiosk systems 450 communicate with the centralized server for centralized data collection, which is then accessible on the administrator devices 130 for authorized administrators of kiosk services. It is recognized, however, that at least some of the beneficial functionality described below, may be realized with alternative system architectures, and as such the processes 500 do not necessarily require a web-based, hosted services system and instead may incorporate other networked configurations such as those described above.

At step 502, modular charging bay devices such as the devices 190 are enrolled on the system for oversight purposes. For purposes of step 502, enrollment of the modular bay charging devices may include, for example, entering or accepting a unique device ID for each charging bay 190 provided in a configurable kiosk 450, the number of charging slots 254 and/or charging pockets 352 in each charging bay 190, identification data for each charging slot 254 or charging pocket 652 provided, identification data for the manufacturer or vendor of the charging bay 190, a model number or version number for the charging bay 190, firmware version data, and other data of interest for operation of the monitoring and oversight described herein. Also, enrollment at step 502 includes a facility identifier and a location identifier or each charging bay device 190 in the correctional facility. Entering and acceptance of the enrollment data and information may be made manually in part or in whole at the point of installation via a connected touch screen of the kiosk device or via a connected computing device, or may be performed at a remote location via an administrator device 130. Also, at least some of the enrollment data may be self-identifying to the system once the modular charging bays 190 are connected to the configurable kiosk systems being monitored, either via machine readable elements such as those described above or via data stored on the control boards of each charging bay 190 which can be communicated once the charging bay is placed online. Step 502 is repeated for each charging bay device 190 being utilized in a scalable number n number of configurable kiosks 450.

At step 504, charging bay settings are accepted for use in their respective kiosk systems 450. For example, lock preferences such as on-demand locking or unlocking may be selected, or the charging bays 190 may be programmed to lock and unlock at desired times for the correctional facility in which they are located. Notification preferences and other preferences may also be selected for purposes of step 504. Notices or alerts may be generated and delivered to administrators in any form via any medium desired in an active or passive alert (e.g., email, SMS text notification, voice message, push notification, graphical screen displays for logged in administrator users), and as such settings and preferences may include preferred forms of notifications, identification and contact information for persons to be notified, etc.

Steps 502 and 504 may be considered setup steps for charging bays 190 and kiosk systems 450 and may in some embodiments be effectively combined. For example, device setting selection and acceptance may be part of device enrollment. Once the data and information is accepted at steps 502, 504 the technical effects of the invention is realized in relation to stored charging bay information in a system database to oversee large numbers of charging bay devices 190 in operation. Enrolled tablet devices 506 may then be received in the modular charging bays 190, and any charging or content management for the devices 50 may occur as final initialization of each configurable kiosk system 450.

At step 508, battery charging is monitored for devices 50 in the charging bays 190 for each of the configurable kiosk systems 450 being monitored. The device monitoring may include assessment of red, yellow and green charging states and operation of charging indicators for the charging bays as described above, and activation and deactivation of charging circuity to manage power consumption when devices 50 are removed from charging bays or when batteries of the devices 50 are fully charged.

At step 510, charging status is reported for each device 50 in each charging bay 190 for each of the configurable kiosk systems 450 being monitored. The charging status is therefore available at a remote location for all systems 450 as well as locally in each system 450 via the charging indicators provided on the charging bays 190.

At step 512, charging history is recorded for each device 50 in each charging bay 190 for each of the configurable kiosk systems 450 being monitored. Comprehensive review and oversight of charging history is therefore possible at a local level of each system 450 and at a remote level for multiple systems 450. Diagnostics and troubleshooting is possible via analysis of the charging history of different charging bays 190 as compared to one another. Performance issues can be flagged and corrected for sub-optimal operation of some charging bays 190 relative to other charging bays 190, and battery charging issues can be identified for certain tablets 50 that are not charging comparably to other tablet devices 50. Recommendations can be made by the system to replace underperforming tablet devices 50 or otherwise taken into account for determining which tablet devices 50 are made available first to inmate users. For example, poorer performing tablet devices can be placed in one or more of the charging bays 190 which is the last to be unlocked, while better performing tablet devices 50 can be unlocked earlier.

At step 514, charging notifications are generated. The notifications may concern, for example, a power loss or other charging failure in one or more of the charging bays 190, sub-optimal charging performance of one or more of the charging bays 190, or a poor preforming tablet device 50 that is not charging adequately.

At step 516, device locking is monitored. As described above, the locked and unlocked positions of locking mechanisms can be sensed and confirmed by the control boards and kiosk controllers. Positive detection of locked and unlocked states of the locking mechanism is beneficially provided in real time via the control boards. Detection of manual unlocking events and return to the locked state after manual unlocking can also be monitored. Therefore, at any given point in time, a current status of each device 190 as locked or unlocked is known. Lock monitoring also includes the ability to cause the state of the lock to change in an unscheduled manner by an administrator who may be remotely located from the device.

At step 518, a change in lock status is reported for the locking mechanisms of the charging bay devices 190. For example, when the lock mechanism is caused to move from the locked position to the unlocked position, the change in state is reported. Likewise, when the lock mechanism is caused to move from the unlocked position to the locked position, the change in state is also reported. The change in state is detected by the sensors provided in the locking mechanism. As described above, the change in state may be effected manually, automatically or with a combination or manual and automatic features. The lock mechanisms may operate to simultaneously lock and unlock tablet devices 50 as a group, or may operate to lock and unlock individual tablet devices 50 which are stored in the charging bays 190.

At step 520, lock history is reported. The lock history can be used to assess usage of the charging bays and the tablets to optimize system performance, and can also be analyzed to diagnose and troubleshoot issues in the configurable kiosk systems which are not locking and unlocking as expected. For instance, if a charging bay 190 is scheduled to unlock at a predetermined time and day, but the history shows that it did not actually unlock at the predetermined time and day, an error condition can be flagged for investigation. Also, if a charging bay is determined to have unlocked at a time that is inconsistent with lock scheduling or permitted access time to tablet devices at the local facility level, a flag can be set for investigation of a suspicious event that may have circumvented security safeguards.

At step 522, lock notifications may be generated for detected error conditions, suspicious events, or other events of interest.

At step 524, firmware management options are assessed. Current firmware status may be detected or identified for the monitored charging bays 190. Firmware selection options are also possible at step 524. Particularly for firmware updates, selections can be made which are then executed on all of the charging bays 190 being monitored or for selected ones of the charging bays being monitored.

At step 526, firmware status is reported, allowing it to be compared to firmware status of other charging bays 190 to identify issues. Notifications may be generated at step 528, and firmware updates or firmware selections may completed to avoid any undesirable effects. The notifications at step 528 may also concern unexpected or unauthorized firmware changes which could compromise access controls and security in the correctional facility.

In addition to firmware management described above, the processes 500 may include additional similar steps to those described above to provide software management options, reports, and notifications.

At step 530, detections are made in the number of charging bays 90 in the kiosk systems 450 being monitored. The detected change may concern the addition of a charging bay 190 or the removal of a charging bay 190 in any of the kiosk systems being monitored. A notification may be generated at step 532 of the detected change, and the system may revert to step 502 to enroll an additional charging bay or to delete and unenroll a charging bay that has been removed. The process then repeats at step 504 to accept any settings for a newly added charging bay and the system effectively resets to oversee the changed number of charging bays 190. The changed number of charging bays may be noted in the pertinent history at steps 512, 520 and 526. Since many configurable kiosk systems 450 in many correctional facilities are overseen simultaneously a real time detection of changes at step 530 and an automatic reconfiguration of the monitoring system to accommodate the changes avoids otherwise severe logistical challenges to accurately tracking and overseeing the charging bays 190 as their number fluctuates over time. If any change in number of charging bays 190 is determined to be unauthorized, quick action can be taken to address any suspicious modification of the system or to ensure that access control and safeguards are not circumvented.

Monitoring at steps 508, 516, 524 may be updated every 1-2 minutes in contemplated examples, with the histories at step 512, 520 and any firmware history likewise be updated, and reports at steps 512, 520, 528 being sent at about 1-2 minute intervals. Periodic updating and reporting efficiently realizes interactive decision making and responsive actions to be taken by administrators while reducing data collection and data communication issues relative to real-time reporting and updates.

Exemplary administrator interface graphical screen displays will now be described that illustrate the flexibility and versatility of the mobile device management afforded by the processes 500 illustrated in FIG. 14 for configurable kiosk systems 450 such as those shown in FIG. 13. The description below assumes that the administrators have credentials and permissions to view the graphical screen displays, make selections from the graphical screen displays, enter information, conduct searches, and to take certain actions. To the extent that a user does not have credentials and permissions, certain selection options may be hidden and not be available. Each administrator user may log-in to the mobile device management interface with, for example, unique identification and password login that may be tied to administrator permissions to grant access or deny access to certain selections and display or certain information. The administrators may include local correctional facility administrators and remotely located administrators for the kiosk services system such as HomeWAV® system administrators, with each type of administrator having access to different levels of information and different ability (or non-ability) to take certain actions in the management of charging bay devices.

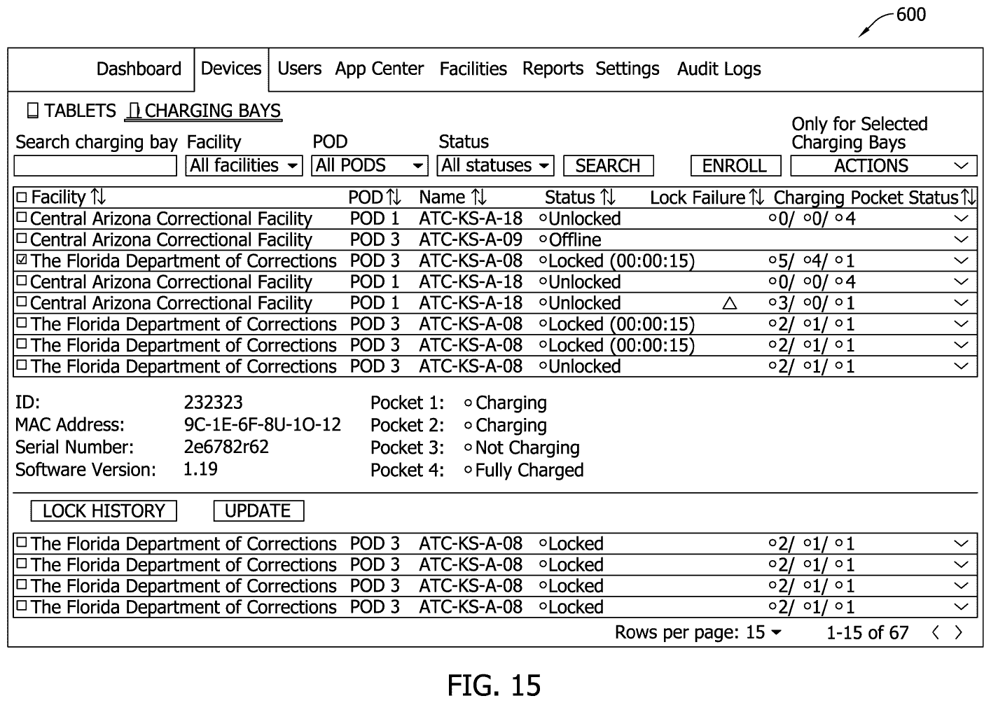

FIG. 15 illustrates an exemplary administrator interface graphical screen display 600 showing exemplary charging bay status and reporting. As shown in FIG. 15, a user has selected a “Devices” option in the main navigation bar at the top of the graphical screen display and has also chosen a “CHARGING BAYS” tab just below the main navigation bar. A “TABLETS” tab is also provided which when selected presents options and reports such as those described in U.S. application Ser. No. 17/201,918 which is incorporated by reference above. A sophisticated monitoring and oversight of tablet devices via graphical screen displays is provided through the TABLETS tab to meet the security concerns of the correctional facility. It is noted in this example that depending on the permissions of an administrator, the administrator may have access to, for example, the TABLETS tab but not to the CHARGING BAYS tab.

With the “CHARGING BAYS” tab being selected, the graphical screen display 600 includes a “Search charging bay” box, a drop-down menu “Facility” field box, a drop-down menu “POD” box, and a drop-down menu “Status” box with Search button for the user to search for desired ones of the charging bays in a filtered manner or as shown by default to see “All” charging bays being monitored. A list of charging bay devices is presented in tabular form by facility, pod, name, status, lock failure and charging pocket status. A selection box is presented for each listed device which when selected causes a display of ID, MAC Address, Serial No. Software Version, and number of pockets with charging status for each. In this example, a local correctional facility administrator may see and search for desired charging bays in the correctional facility, but may not access charging bay information for different facilities. Accordingly, the drop-down menu Facility field box would not be presented to the local correctional facility administrator. An administrator for the kiosk services system, however, may see any all of the devices in different facilities via the drop-down menu Facility field box.

The graphical screen display 600 is also shown to include an ENROLL button and an ACTIONS button for selected charging bay devices. The ACTIONS button causes an Actions drop-down list to be displayed which includes a Lock Charging Bay selection or Unlock Charging Bay selection. As such, administrators can cause selected charging bays to be lock or unlock through the graphical screen display 600 on demand at a time that has not been previously scheduled. Confirmatory prompts may be issued by the system before actually unlocking or unlocking selected charging bay device, and the administrator can select a term for the action taken (e.g., 1 hour, 1 day, indefinitely, etc.) in the case of unlock event or a term such as a selected day and hour, a selected number of hours and minutes, and a selected number of minutes and seconds in the case of a lock event, all of which are recorded on the system. The administrators can therefore respond locally and remotely to unique events such as lockdown events of different duration in one or more the facilities or other special circumstances or occasions as warranted. Before the selected terms are expired, administrators may change the lock status as desired via appropriate selections being made to maximize flexibility to meet changing conditions and exercise secure control or relax controls when appropriate.

A LOCK HISTORY button and an UPDATE button are also shown in the graphical screen display 600 with another table of devices, and an EXIT button is also shown for user navigation. The administrator user may see the number of rows per pages and the number of pages of monitored devices, and may navigate back and forth between the pages of the CHARGING BAYS tab which are reported through the system. An EDIT button is further included so that the information for selected devices can be changed. Editing options include a Remove button for a charging bay that is no longer in use. When the Remove button is activated, the system may send a confirmatory response to the use asking for confirmation before actually removing the selected device and information from the mobile device management and displays. Upon removal of a charging bay, the charging base is automatically unenrolled from the system.

Because of the large number of charging bays being monitored in contemplated embodiments, actions that are more than a year old are automatically deleted and are therefore not included in the Lock History.

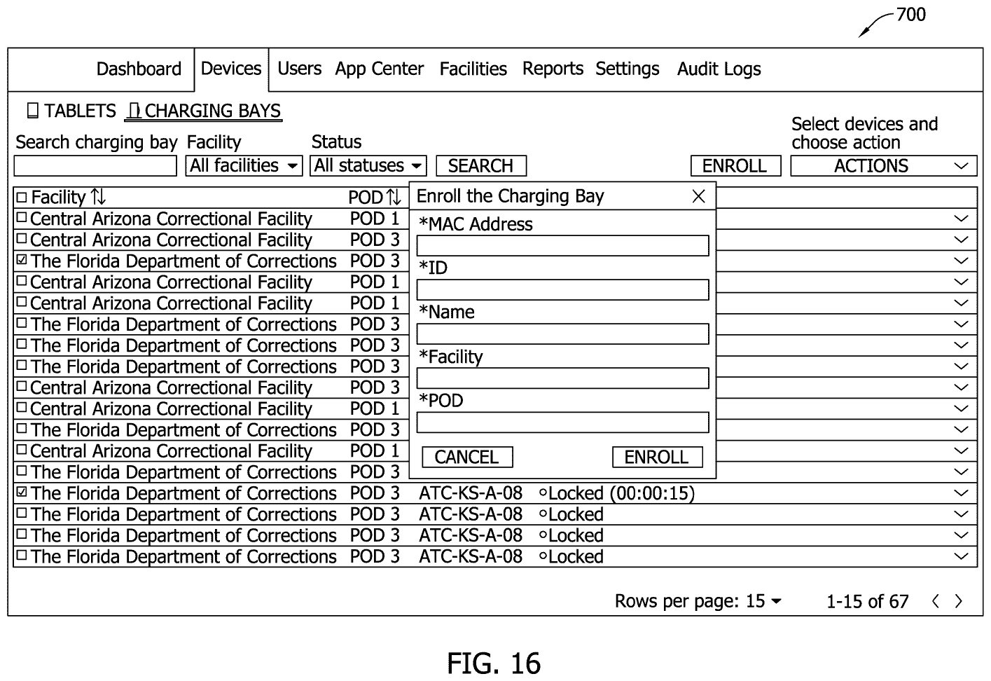

FIG. 16 illustrates an exemplary administrator interface graphical screen display 700 showing exemplary charging bay enrollment in the processes 500 illustrated in FIG. 14 for configurable kiosk systems 450 such as those shown in FIG. 13. In the graphical screen display 700, the user has selected the ENROLL button which causes a pop-up window to be displayed for entry of enrollment data using text entry boxes and drop-down menus in the example shown. The enrollment data and information shown in the example of FIG. 16 for each charging bay includes MAC Address, device ID, device name, facility identifier selection and location data (e.g., POD) in the correctional facility where the charging bay is located in the correctional facility. When the enrollment information has been entered and selected, the administrator can select the ENROLL button, or otherwise select the CANCEL button to return to the graphical screen display 600 (FIG. 15).

In response to the ENROLL button being activated, the system may verify that there actually is a connected charging bay with the accepted enrollment information. If the charging bay is verified it is added to the mobile device management and to the interface with assigned facility and pod data. If the charging bay cannot be verified, the system may prompt the user to check the enrollment information and try again.

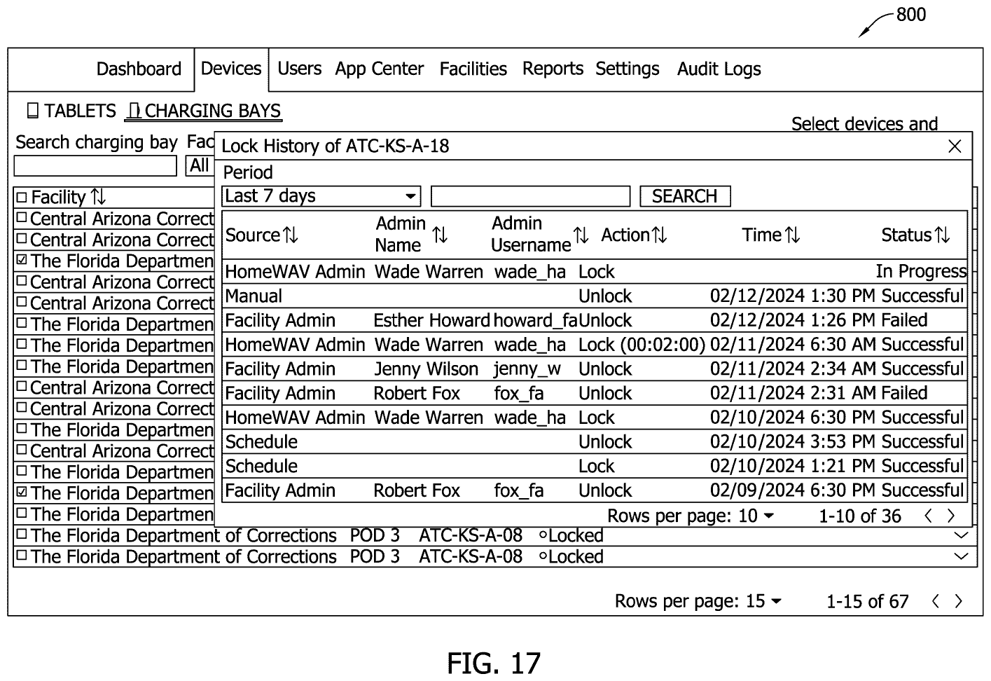

FIG. 17 illustrates an exemplary administrator interface graphical screen display 800 showing exemplary charging bay lock history in the processes 500 illustrated in FIG. 14 for configurable kiosk systems 450 such as those shown in FIG. 13. In the graphical screen display 800 the administrator has made a lock history selection from the graphical screen display 600 (FIG. 15) and a pop-up window is now presented showing lock history for selected charging bay devices.

The pop-up window includes a Period drop-down menu in which the administrator may select a longer or shorter time window, and in the example shown the “Last 7 days” has been selected. Alternative selections may include Last 24 hours, Last 30 days, Last 6 months, Last year or a custom search timeframe. A box to search history by admin name or username is also provided in the graphical screen display 800 with a SEARCH button. An exemplary list is shown in graphical screen display 800 for history in the last 7 days which is unrestricted by admin name or username. The list is provided in tabular form including a Source column for a lock change event, an admin name (if applicable), an admin username (if applicable), an Action (e.g., lock or unlock), a time of the Action, and a Status for the Action.

The Source column the graphical screen display 800 may indicate that a charging bay was locked or unlocked by a kiosk system administrator via the mobile device management system and interface, that a charging bay was locked or unlocked by a correctional facility administrator via the mobile device management system and interface, that a charging bay was automatically locked or unlocked due to scheduled action, or that charging bay was manually locked or unlocked at its location with a key.

The status is shown in the graphical screen display 800 of “Successful”. “In progress” or “Failed”. The administrator is therefore notified of positive and negative lock status for the selected device(s). The Failed status may prompt a separate notification for investigation, although in the examples shown in the graphical screen display 800 each Failed event was followed by a Successful event within a few minutes. As such, short duration Failed locking events may not require notification and related intervention for investigation and repair. Of course, the number and frequency of Failed events over time may result in a recommendation for repair or replacement of the module to avoid an excessive number of failed events.

The administrator user may see the number of rows per page and the number of pages for the complete history of the selected charging bays in the graphical screen display 800, and the administrator user may navigate back and forth between the pages of the Lock History reported through the system.

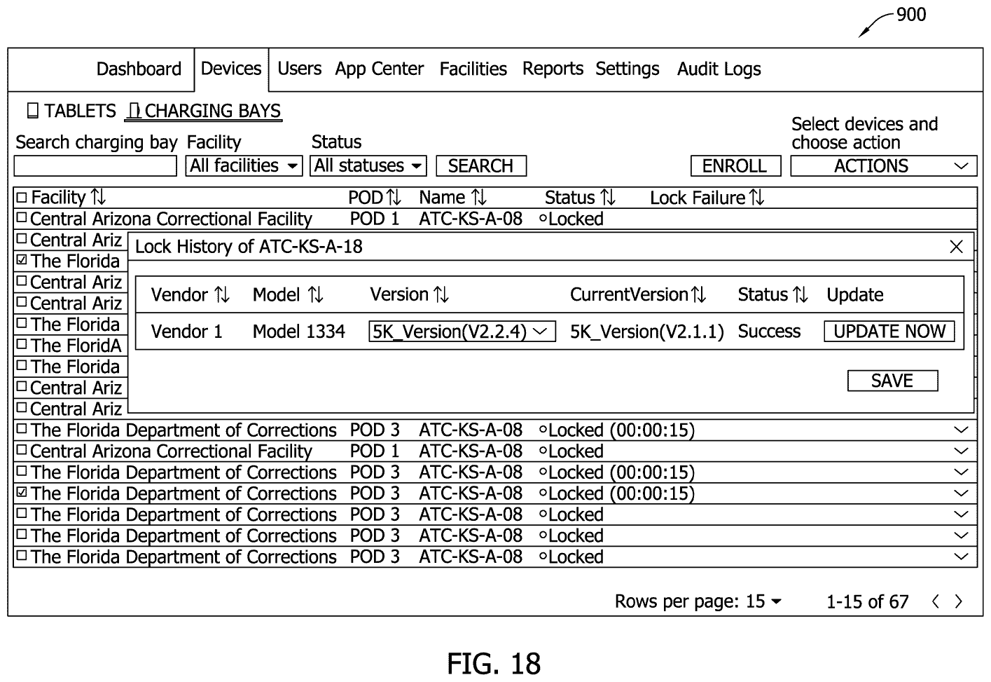

FIG. 18 illustrates an exemplary administrator interface graphical screen display 900 showing exemplary firmware management in the processes 500 illustrated in FIG. 14 for configurable kiosk systems 450 such as those shown in FIG. 13. The graphical screen display 900 includes an Update pop-up window for a selected charging bay which identifies the device vendor, the device model, a software/firmware version drop-down menu selection, current version, status and an UPDATE NOW button. The “status” shown in the graphical screen display 800 includes any change which is a result of the UPDATE NOW button selection. A SAVE button is also presented for the update made. A history of updates may be recorded and also be viewable on the system.

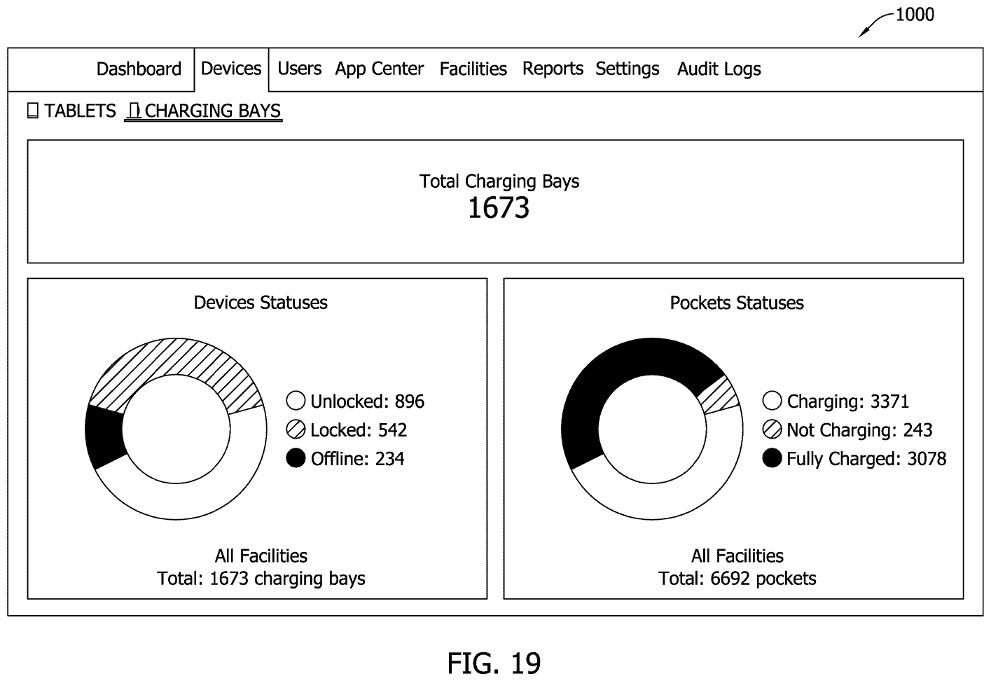

FIG. 19 illustrates an exemplary administrator interface graphical screen display 1000 showing exemplary charging bay status and charging pocket status in the processes 500 illustrated in FIG. 14 for configurable kiosk systems 450 such as those shown in FIG. 13. In the graphical screen display 1000, the Dashboard selection is made in the upper navigation bar and the CHARGING BAY tab is still selected. The graphical screen display 1000 shows the total number of charging bays being monitored, a device status doughnut chart, and a pocket status doughnut chart collectively showing summary aspects of monitored devices as a group. For a correctional facility administrator, the administrator will see the total number of charging bays monitored in the correctional facility.

The device status doughnut chart indicates the charging bay devices as Unlocked, Locked, or Offline in the example graphical screen display 1000, while the pocket status doughnut chart shows the pocket status as Charging, Not Charging, or Fully Charged. The doughnut charts in each case show percentages of the total number of charging bays displayed above the doughnut charges with the particular status indicated. In the example of the graphical screen display 1000, the total number and doughnut charts correspond to All Facilities being monitored. Similar graphical screen displays may be provided for charging bays of subsets of All Facilities or for individual facilities if desired. Likewise, variations in the dashboard to include different types of charts of different aspects for the summary may be implemented with similar benefit. In a contemplated embodiment, the dashboard is updated about every two minutes with current data.

It is noted that the example graphical screen display 1000 shows thousands of charging bays being monitored, and the corresponding significant capability of the system and method to reduce administrative burdens to monitor and oversee such a vast number of charging bays to ensure that correctional facility needs are being adequately served. The logistical problems of numerous persons having to physically inspect the modular kiosk systems in various different locations and keep corresponding records are avoided. The real time status report of the example graphical screen display 1000 for such a vast number of charging bays is generally not possible to quickly or accurately provide via human inspection and human reporting. The example graphical screen display 1000 removes any ambiguity regarding the status and current operation of a host of charging bay devices in a simple to digest manner for administrator users to understand and devote resources to device and areas that need attention.

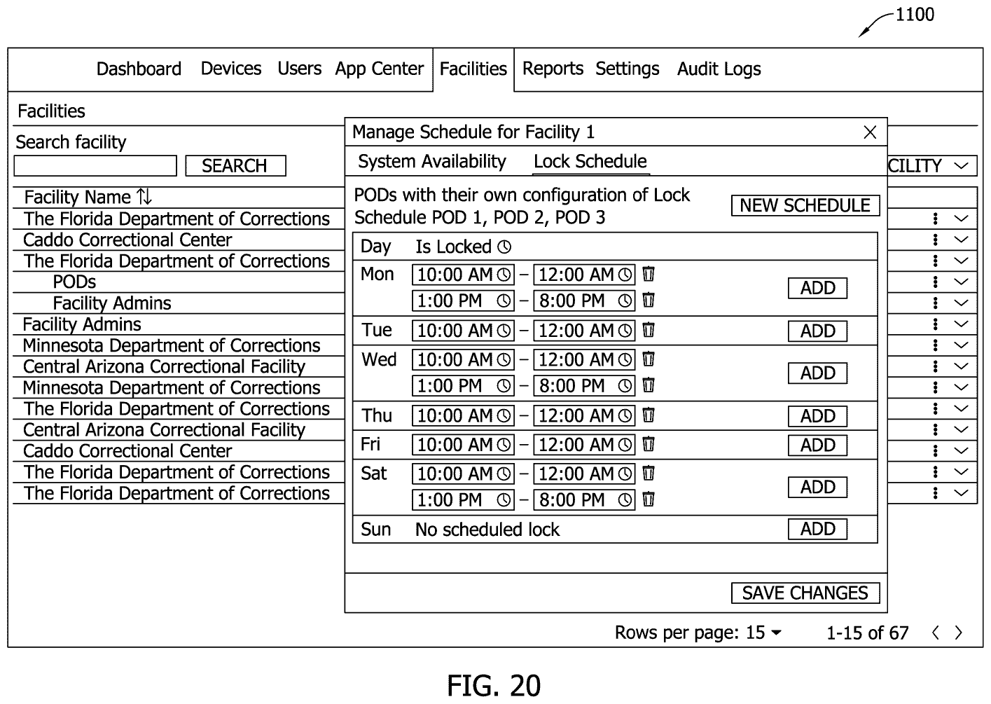

FIG. 20 illustrates an exemplary administrator interface graphical screen display 1100 showing exemplary charging bay lock scheduling in the processes 500 illustrated in FIG. 14 for configurable kiosk systems 450 such as those shown in FIG. 13. In the graphical screen display 1100 one of the facilities has been selected in the list and a sub-menu has been accessed with a Content Settings having been selected. As a result, a pop-up window appears including a Lock Schedule Tab as shown. The user may select desired timed lock schedules for each day of the week. In the example shown, lock times for each day Monday through Saturday may be individually added via respective ADD buttons, and a No Scheduled Lock option may be added on Sunday. A SAVE CHANGES button is provided for scheduled selections made and a NEW SCHEDULE button is provided to make new locked scheduling selections. As seen in the example graphical screen display 1100, the three PODS in the correctional facility all operate with the same lock schedule, although in further embodiments they schedules for the different PODS could be individually scheduled and may be different from one another if desired.

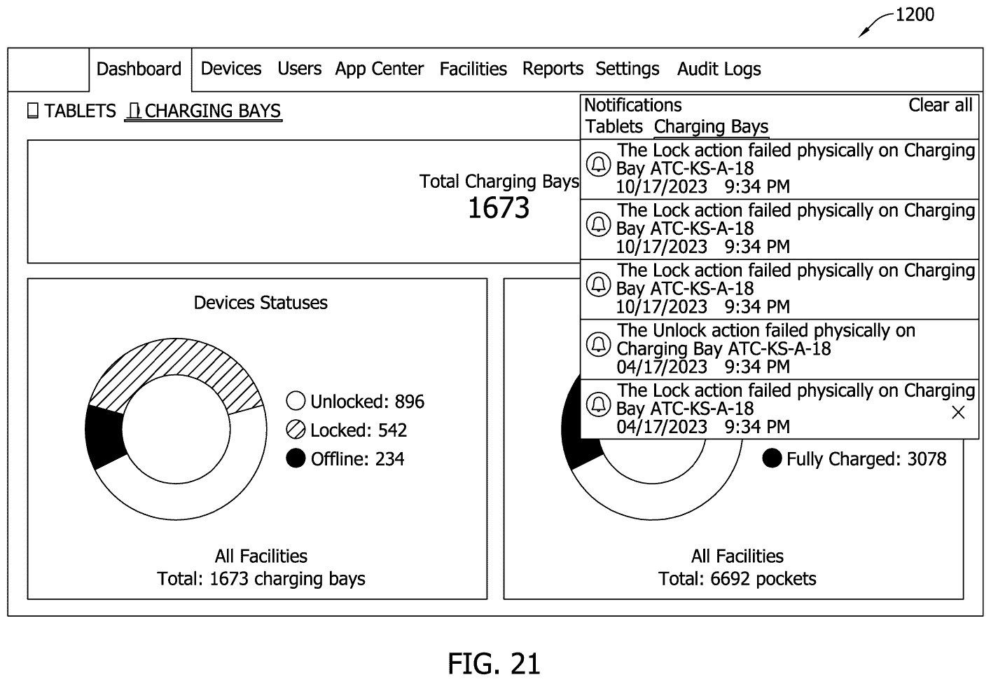

FIG. 21 illustrates an exemplary administrator interface graphical screen display 1200 showing exemplary charging bay notification in the processes 500 illustrated in FIG. 14 for configurable kiosk systems 450 such as those shown in FIG. 13. In the graphical screen display 1200, the notification bell icon in the navigation bar has been selected and a pop-up window has appeared including a Tablets tab and Charging Bays tab. The Charging Bays tab has been selected in the graphical screen display 1200 and notifications are listed concerning physical failures of lock actions for identified charging bays. The notifications may be reviewed and individually closed, while a Close All option is also provided. The Failures of the lock actions may cause a separate notification for investigation and intervention in another form to a designated person or persons, or the administrator may take appropriate steps to have the failures investigated as a response to the notifications shown. Options may be presented in the graphical screen display 1200 to direct the notifications to other persons or to take follow up actions before closing the notifications.

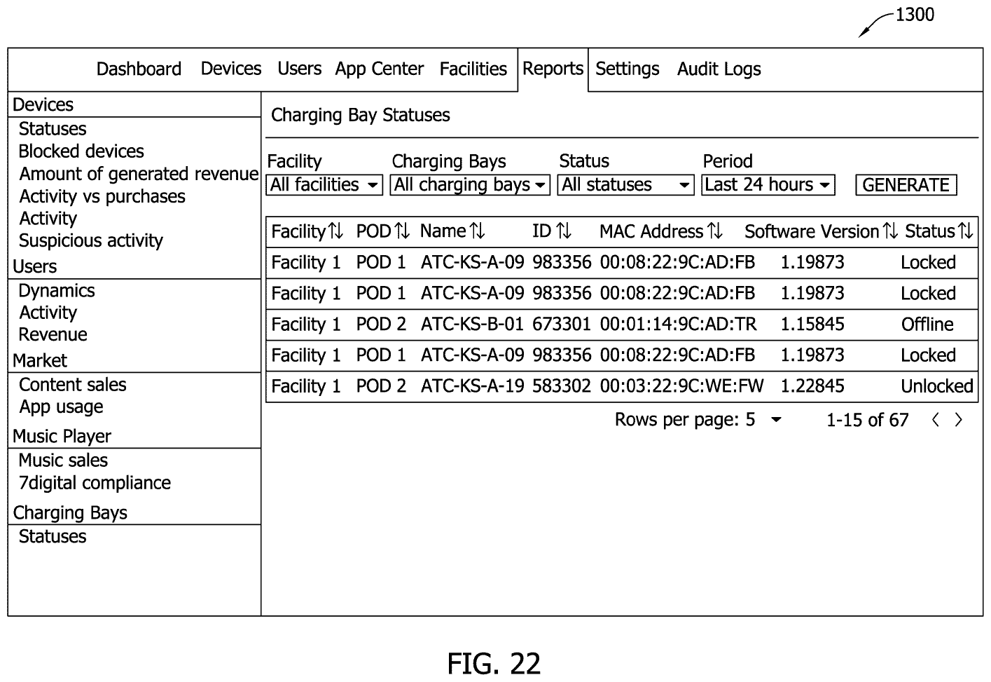

FIG. 22 illustrates an exemplary administrator interface graphical screen display 1300 showing exemplary charging bay status reporting in the processes 500 illustrated in FIG. 14 for configurable kiosk systems 450 such as those shown in FIG. 13. In the graphical screen display 1300, Reports has been selected in the upper navigation bar which results in the Charging Bay Statuses screen.

The graphical screen display 1300 in the example shown includes a Facility drop-down menu selector, a Charging Bays group drop-down menu selector, a Status type drop-down menu selector, and a time Period drop-down menu selector accompanied by GENERATE and EXPORT AS buttons.

A generated list is shown in the graphical screen display 1300 in tabular form including Facility, POD, Name, ID, Mac Address, Software Version status, and general Status including for example, Locked, Unlocked, and Offline status for the generated report. The administrator user may see the number of rows per page and the number of pages for the complete list of charging bays in the generated report, and the administrator user may navigate back and forth between the pages of the status report.

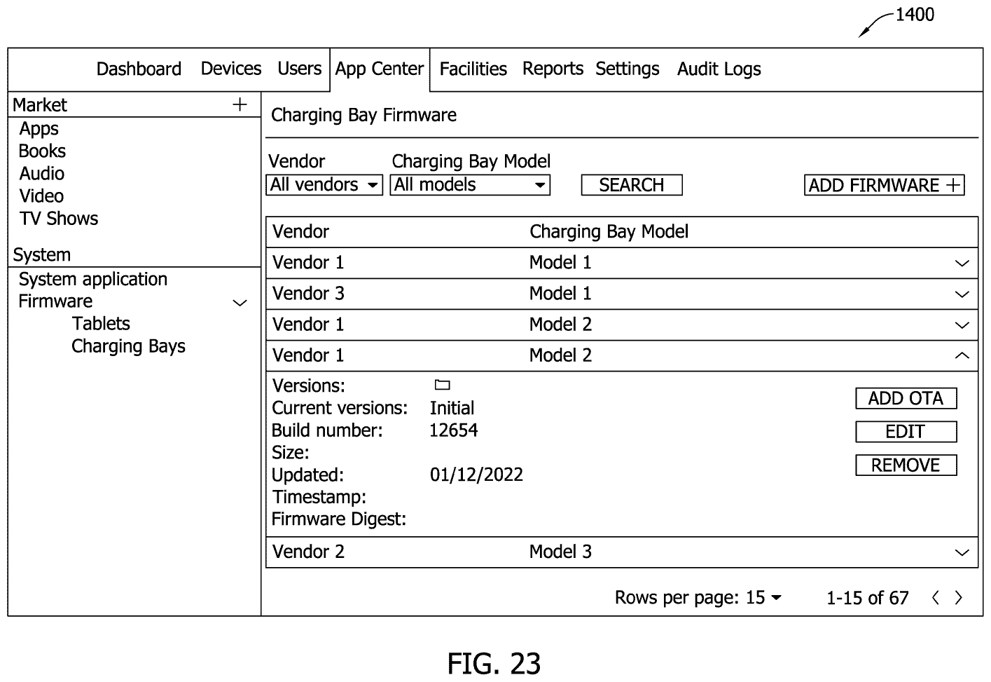

FIG. 23 illustrates an exemplary administrator interface graphical screen display 1400 showing exemplary charging bay model and version reporting in the processes 500 illustrated in FIG. 14 for configurable kiosk systems 450 such as those shown in FIG. 13.

In the graphical screen display 1400, App Center has been selected in the upper navigation bar and a Charging Bay Firmware screen is caused to be displayed to the administrator user. The screen includes a Vendor drop-down menu selector and a Charging Bay Model drop-down menu selector with a Search button for the selections made. Charging bay devices are listed which correspond to the search with Vendor information and model information with a down arrow pointer to see further information. When the down arrow pointer is selected more detailed information is shown as illustrated and accompanied by ADD OTA, EDIT and REMOVE button options. Software updates may made over the air to the respective devices. An ADD FIRMWARE button is also provided for administrator review and update of firmware in a similar manner to the software.

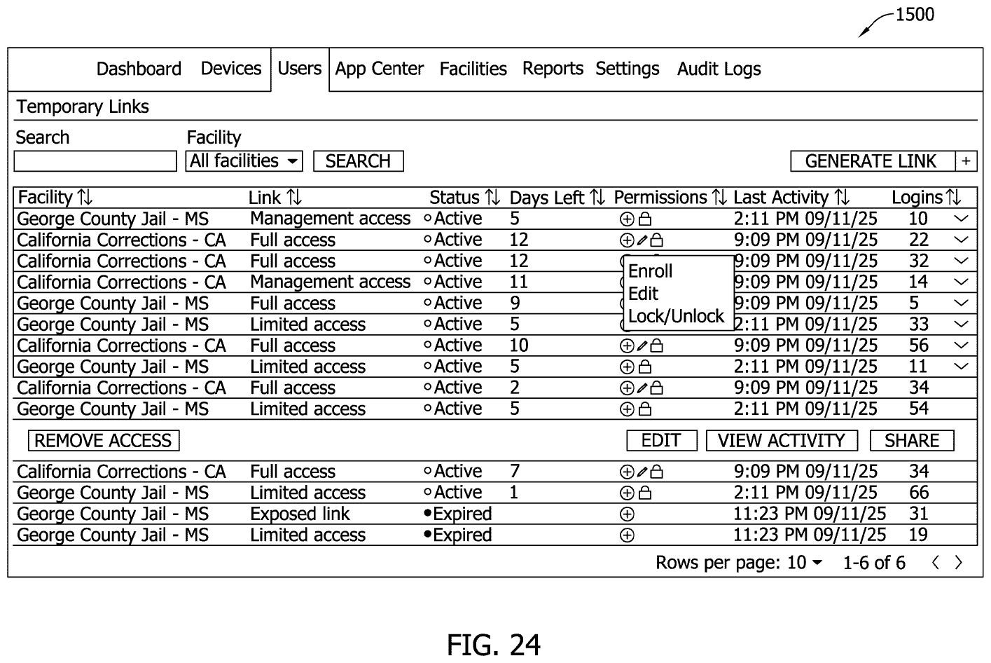

FIG. 24 illustrates an exemplary administrator interface graphical screen display 1500 showing administrator user permission assignment and monitoring in the processes 500 illustrated in FIG. 14 for configurable kiosk systems 450 such as those shown in FIG. 13. Given the security requirements of correctional facilities, it is important that administrator access to charging bay device information be managed and controlled. One way to do so is to assign temporary access links to correctional facilities at the local level of the kiosk systems 450. Such assignment of temporary links, which temporarily allows local administrators to surely interact with and manage enrolled charging bay devices may be made by kiosk services administrators that are remote from the correctional facilities. In other words, a two-tiered administrator access scheme is contemplated, wherein kiosk services administrators having permission in a first tier (e.g., at the kiosk services level) may delegate rights and permissions to enroll, edit, change lock state, and access information about the charging bays to other administrators in the second tier such as correctional facility administrators overseeing charging bay operation and/or managing charging bay devices and tablet computer devices locally in each correctional facility.

Administrators in either tier may beneficially be restricted in their ability to manage the charging bays in certain aspects, and detailed record keeping is realized in the system to account for actions taken by permitted administrators. Meanwhile, persons who lack access to the temporary links and/or those who lack permission to take selected actions are prohibited from system access or restricted in actions that they can take to ensure secure operation of the system and avoid security vulnerabilities relative to conventional systems that have less restricted access or lack options to restrict users from taking certain actions. Permissions data may be stored in system databases and may be applied as administrative users login to the system, with different users in different facilities seeing different adaptations of screen displays depending on permissions granted or denied to them.

In the graphical screen display 1500, the Users option has been selected in the upper navigation bar and a Temporary Links screen, also sometimes referred to as a Temporary Access Management page, is caused to be displayed to a first administrator user having credentials to access the system and to select the Users option in the navigation bar. For administrators having no permitted access to the Temporary Access Management page, the Users option will be grayed out and otherwise inactive or may be removed from the screen 1500 entirely. As such, the Users screen and its options and information may be made available only to trusted administrators, typically at the kiosk services level.

The screen 1500 includes a Search box wherein the administrator user may search for a facility by name, a Facility drop-down menu wherein a user can select the facility name of interest, and a Search button for the selections made. A table or grid is also shown including All Facilities by default and all of the charging bay devices in all of the facilities with the links that have been created for administrator access. The table or grid includes a sortable Facility column, a sortable Link column, a sortable Status column, a sortable Days Left option, a sortable Permissions column, a sortable Last Activity column, and a sortable Logins column. The rows of the table are sortable by alphabetical order where text is concerned, ascending or descending order where numbers or dates are concerned, and by symbol in the example Permissions chart which includes permissions of enrollment (circled plus sign), editing (pencil symbol) and locking (padlock symbol).

As shown in FIG. 24, the permissions may be individually assigned and granted on a per facility basis with different facilities being granted different permissions (or different combinations of permissions as the case may be). Each row also includes a down arrow menu selector which when selected causes a sub-grid row of options to be displayed which in the example shown includes a REMOVE ACCESS button, an EDIT button, A VIEW ACTIVITY button, and a SHARE button for appropriate selection by the user. The REMOVE, EDIT and SHARE buttons are displayed only for active links.

As shown in the exemplary grid, different types of permission links may be assigned in each facility, including Management Access, Full Access and a Limited access permitting or restricting certain actions to be taken by administrators at the correctional facility level. The status column includes temporary link status of Active and Expired, with the Days Left column shown the number of days until an Active status becomes Expired. The screen also includes a GENERATE LINK option as shown with a plus sign which may be selected to create a temporary link. The number of rows in the grid is selectable by the administrator user. By default the number of rows is set to fifteen, although alternative numbers of rows such as five, ten, twenty five and fifty may be selected using the drop down menu provided.

In contemplated embodiments, links may may be displayed in the grid for the screen 1500 that have been deactivated via removal or decommissions of related charging bays

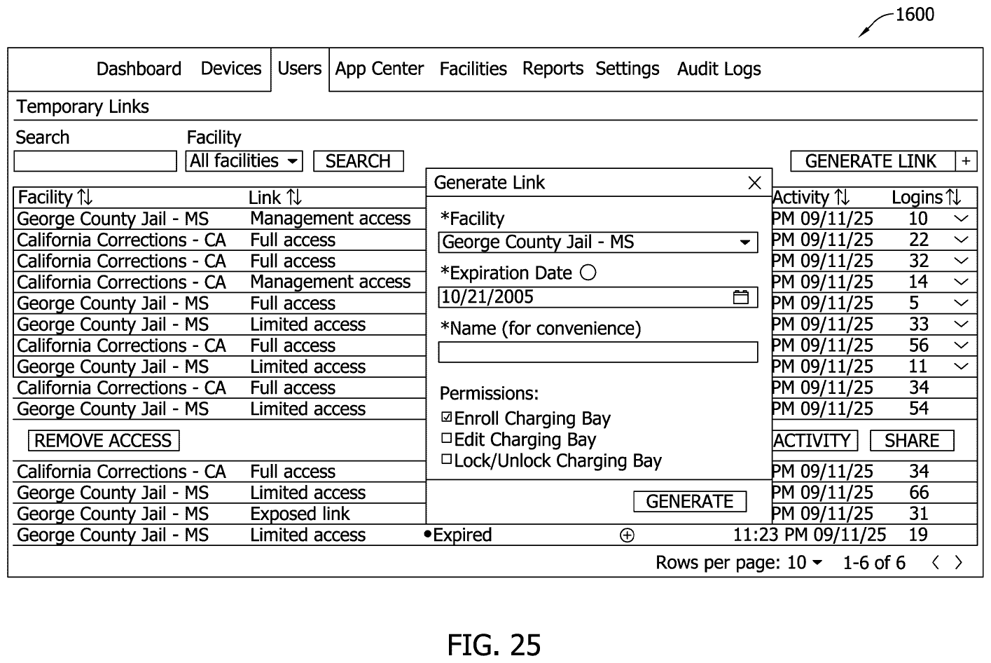

FIG. 25 illustrates an exemplary administrator interface graphical screen display 1600 similar to FIG. 25 but showing a popup Generate Link window after the Generate Link option has been selected in the screen 1500 by an administrator user having permission to generate links.

The popup window includes a down facility selection box for facilities where charging bays are located, an Expiration Date box with an information (circled i) symbol for the user needing help or explanation, a fillable Name box, and permission check boxes of Enroll Charging Bay, Edit Charging Bay, and Lock/Unlock Charging bay options for the linked facility. In the example shown, the Expiration Date field may be fillable or with month, date, year or may be selected on a calendar via the calendar icon provided. Once the information is entered and selections are made in the popup window, the user may select the GENERATE button to create the link, which will then be displayed in the Temporary link table or able to be searched in the table. In contemplated embodiments, the created link will expire at noon on the expiration day and its status will be changed to Expired in the main grid. Automatic expiration of created links maintains system security. Expired links may be recreated or regenerated as desired. Indefinite access is beneficially avoided by the expiring links, and current users having access may be more effectively overseen.

When the GENERATE button is selected, another window may pop up including for the generated link, the facility, a link address, a password and a COPY button. When the COPY button is selected, the link and password are copied. In contemplated embodiments, the link may include a random token of 64 symbols, with each token for each link being unique from all other links generated (including expired links), and the link generated being based on the environment (e.g., different links for qa and prod). As one non-limiting example, the link may be https://mdm.homewav.com/4f8b7a9d2e6c4e5f9a1b7c2d8f3a0b6e56rb7a4ttht45e5f9a1b7c2d8f8uyc3e. Such a link is effective to deter hacking attempts or unauthorized entry to the system and provides a degree of cybersecurity for the correctional facility to ensure compliance with the unique security needs of the facility.

Also in contemplated embodiments, the password may be a randomly generated password string of 32 symbols, wherein one password is created for all logins made through the generated link. As a non-limiting example, the password may be Ul%0Y9@xH%@Hk!YTR7%0Y9@xU2@Hk!YT. The password too is designed to deter hacking attempts or unauthorized entry to the system and provides a degree of cybersecurity for the correctional facility to ensure compliance with the unique security needs of the facility.

Once the link and password are generated and copied, the administrator may select the EDIT or SHARE button in the sub-grid shown in FIG. 24. Sharing of the link makes it available for system login by local correctional facility using the link and password provided. If the REMOVE button is selected in the sub-grid shown in FIG. 24, the link will be deactivated and its status will be changed to Expired in the main grid. All activity relating to generating links, editing of links, sharing of links, and removal of links may be recorded and accessed through the Audit Log option on the main navigation by a user having permission to view it. Such activity may further be archived and reported on the system as a means to detect or deter any attempt to exploit or improperly use the link generation features. In contemplated embodiments, multiple administrator users would have permission to review the Audit log for any suspicious activity or to review overall user engagement with the system.

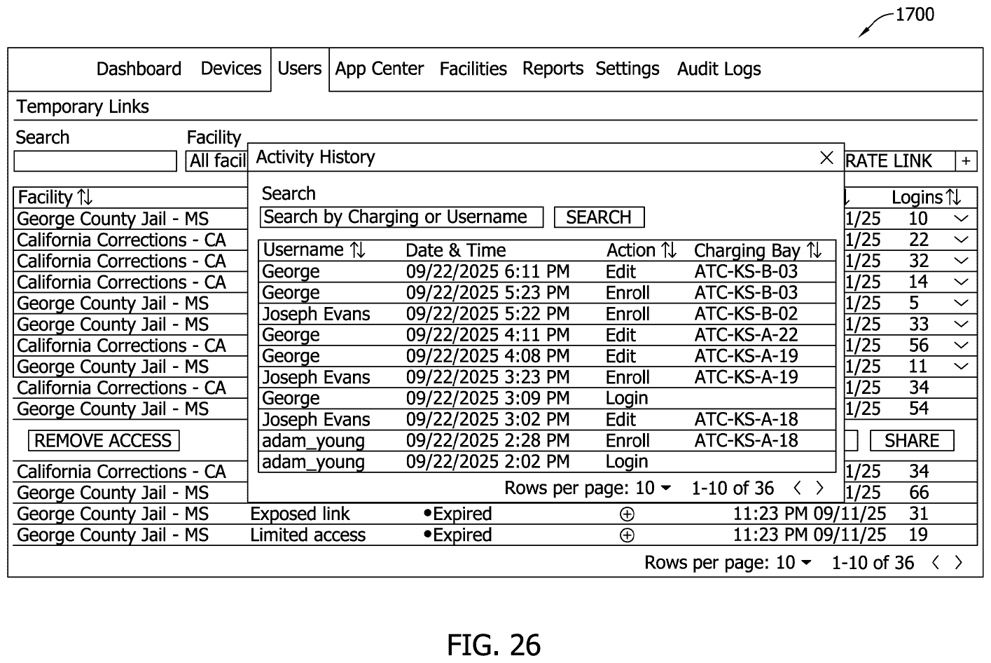

FIG. 26 illustrates an exemplary administrator interface graphical screen display 1700 similar to FIG. 25 but showing a popup Activity History window after the Show Activity button has been selected via the drop menu for a selected one of the table rows on the Temporary Link screen. The Activity History window includes a fillable charging bay or username search box and a Search button for reviewing subsets of activity information of interest to the user. An activity table is also provided which includes a sortable username column, a sortable date and time column, a sortable action column, and a sortable charging bay column. In the example shown the Actions column includes actions of Enroll, Edit and login which may relate to different permitted users identified by username. The activity therefore serves to show actions taken with respect to identified charging bays, the individuals who took action, the nature of the action taken, and the date and time of each action.

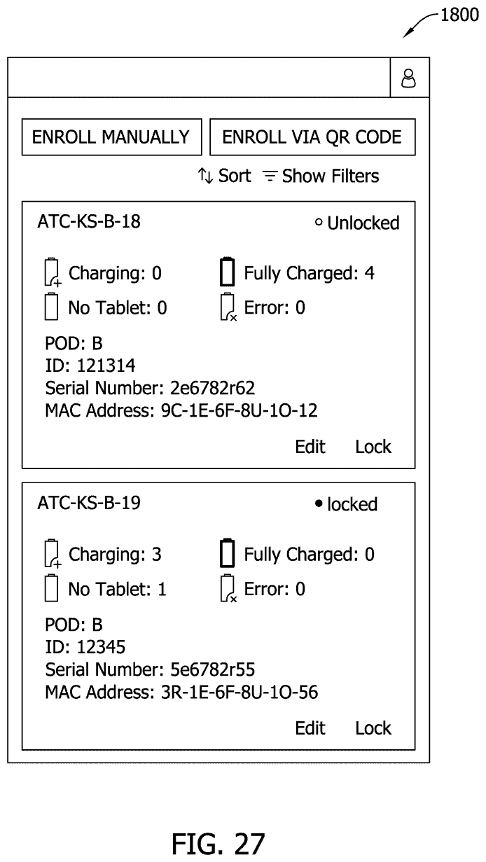

FIG. 27 illustrates an exemplary Admin Panel interface graphical screen display 1700 in the processes 500 illustrated in FIG. 14 for configurable kiosk systems 450 such as those shown in FIG. 13. The Admin Panel interface graphical screen display 1700 may be provided to a permitted user via a mobile device such as a smartphone or tablet device carried by the technician to the site in the facility where charging bay devices are to be located. Screens having similar options may also be displayed on a laptop or notebook computer or on a desktop computer via the ENROLL button on the screen display 600 shown in FIG. 15.

In contemplated embodiments, the screen display 1700 can be accessed by an authorized technician with permission to introduce charging bays in facilities after logging in to the system via a generated link and password available on the technician's smartphone or tablet computer device. The technician may be given the generated link and password as described above to login to the system when installing, removing, or replacing charging bay devices on site at the respective facilities having mobile device management systems. When the technician opens the link, a sign-in page is displayed including a password field and a sign-in button. If the technician enters the applicable password to validate the sign-in, a name page follows for the technician to enter the technician's name and then select a Continue button. The technician is then logged in, and if there is no activity in a 24 hour period, the technician is automatically logged out.

While logged in the technician can only see or only select the Charging Bay information, and in the Charging Bay page the technician may not see the Facility filter option. When the technician selects the Enroll button in the Charger Bay tab, the Admin Panel screen 1800 of FIG. 27 is displayed as a page or as a window. In contemplated embodiments, the kiosk services administrators may also view the Admin Panel and interact with the same to enroll charging bay devices. Likewise, a correctional facility administrator could enroll a charging bay device via the Admin Panel or the other screens described herein if permission to do so was granted.

The Admin Panel screen 1800 includes in the example shown an ENROLL MANUALLY button and an EROLL VIA QR CODE button. A number of charging bay devices are listed with an alphanumeric identifiers, a Locked or Unlocked States, a Charging status for the charging slots in the charging bay device, a Fully Charged indicator for the tablet computer devices in the charging slots, a No Tablet indicator for slots that do not include a tablet computer device, an Error indicator for a faulty locking mechanism, a location or POD identifier, an ID number for purposes of the kiosk system, a device serial number and a MAC address. Options are also included to edit the information shown or change the lock state of the device with Lock or Unlock options. Also shown is a Sort icon and a Show Filters icon to obtain different listings of charging bay devices according to user preferences and selections made.

When the user selects the ENROLL MANUALLY button or the EROLL VIA QR CODE button, a pop-up window is displayed allowing the user to supply the information manually or import it automatically via a Quick Response (QR) code provided on the charging bay device. The QR code is one example of a machine readable bar-code element that may be utilized with a known reader device, which may be a smartphone or other device as desired, to instantly access data for charging bay devices and import it into the applicable enrollment fields required for the system operation. The QR code may be provided on a label affixed to each charging bay devices for access to the enrollment data and information. Information may also be printed on a label affixed to each charging bay device which can be read by a human and re-entered manually during the enrollment process. Enrollment data and information may also be stored in look-up tables which can be referenced for enrollment purposes, or the enrollment data and information can otherwise be made available and retrieved in any other known manner.

When the enrollment information is completed, the user may select an Enroll button. As a safeguard, the system checks to confirm that the MAC address and ID correspond to a charging bay device that it has detected before adding to the enrolled charging bay devices that are displayed on the screens such as those described above. If there is no confirmed device with the MAC address and ID provided, the user is notified and asked to resupply the information. Once the device is enrolled, the device can be locked by the technician or any permitted administrator through the user interface to prevent tablet computer devices from being placed into the charging bay device or to prevent a removal of tablet computer devices from the charging bay device. The technician (or any other administrator having permission) can also change the lock state for testing purposes to ensure that the lock mechanism is working properly.

While exemplary user interfaces and graphical screen displays have been described, adaptations of the interfaces and graphical screen displays are possible, as well as additional and different interfaces and graphical screen displays otherwise offering similar functionality and benefits. The flexibility of the user interfaces described, coupled with the flexibility of the module kiosk systems to be configured and reconfigured with different numbers of improved charging bay devices to meet changing needs of correctional facilities and the number of tablet computer devices to be accommodated, beneficially realizes a relatively low cost solution to longstanding but unfilled needs in the marketplace.

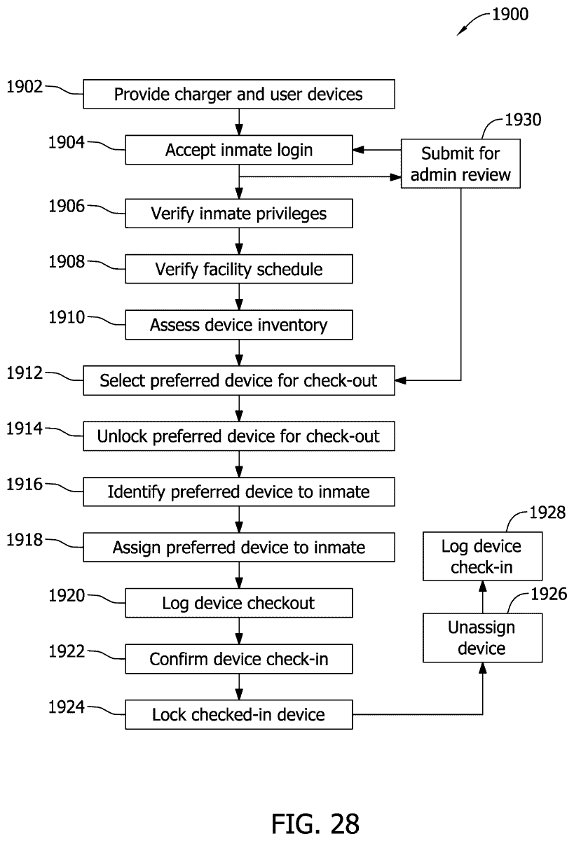

FIGS. 28-36 illustrate further methodology and further charging pocket features that provide still further benefits in securely managing portable electronic devices and accommodating preferences of different facilities in a universal design while addressing additional use cases that may be problematic in conventional portable computing device charging and access systems while also providing additional hardware protection features for charging bay devices and user computing devices.

FIG. 28 is a method flowchart of exemplary user device check-out and check-in processes 1900 implemented in configurable kiosk systems and charging bays such as those described above. The processes 1900 may be implemented in one or more of the computing devices, controllers, or control devices described above.

At step 1902, charging pockets are supplied in the form of main kiosk devices or charging bay devices to scale the number of portable user computing devices (e.g., inmate computing devices such as those described above). Any number n of charging pockets may be supplied in any number of kiosk devices provided with charging pockets or in any number of charging bay devices. The charging pockets define a charging and access system for the user computing devices, with each charging pocket defining a charging slot accepting one of the user computing devices in the inventory as described above.

At step 1904, user login is accepted. In contemplated embodiments the user is an inmate logging into the system for identification purposes as described above to confirm an authorization to use the system. If the user is determined to be unauthorized, the user may be so informed and the user will either not be able to access a user device or not be able to use a device that has been accessed. In other words, the devices will remain locked if already locked to prevent access to one of the devices, or in the case where the devices are unlocked the system can notify the user that no authorization exists to access a user computing device. If a user accesses a user computing device anyway, the user will not be able to log in to the user computing device and use it.

At step 1906, user privileges (e.g., inmate privileges as described above) are assessed for the logged in user who was authorized at step 1904. The user privilege is separate from the authorized user requirement and provides a secondary access restriction for one of the user devices to the user based on recent behavioral considerations of the user in a controlled environment (e.g., a correctional facility). Such user privileges incentivize good behavior and disincentivises bad behavior in the controlled environment, and the user privilege status may be activated, suspended or adjusted by correctional facility administrators to provide varying degrees of restriction to user computing devices or to the functionality of the user computing system to access kiosk services. If user privileges (e.g., inmate privileges) are suspended, the user may be so informed and the user will either not be able to access a user computer device or not be able to use a device that has been accessed. If the user privilege is active (i.e., not suspended) the user is advanced to step 1908 where the system determines facility scheduling access.

At step 1908, each facility may schedule preapproved times for user access on an individual or group basis. Therefore, the system confirms whether tablet checkout is allowed at the current time based on facility-defined schedules which may be set or determined in a similar manner to that described above. Such preapproved and prescheduled access times constitute a separate access restriction from the authorized user requirement and the active inmate privilege requirements from steps 1904 and 1906. If the logged in user is within a scheduled window of time for approved access, the system proceeds to assess available user device inventory at step 1910. If the logged in user is not within a scheduled window of time for approved access, the user may be so informed and the user will either not be able to access a user device or not be able to use a device that has been accessed.

At step 1910 the available inventory of user computing devices are assessed to ensure that a sufficiently charged user computing device is available for use and/or that a user computing device having a current software or firmware installation is available for use. Other considerations are possible for deciding how to assess the available user computing device inventory, but the assessment effectively applies a priority access preference amongst the available user computing devices. In the priority access preference, fully charged user computing devices will be made available before partially charged devices, and user computing devices having more up to date software and firmware will be made available before user devices having less up to date software and firmware. Also, user computing devices having less than a predetermined amount of charge or user computing devices having an unacceptably out of date software and firmware may be deemed inaccessible by the system. In other words, user computing devices having current software/firmware version below the required software/firmware version cannot be checked out. This is useful if a security concern has been identified and a software/firmware fix has been pushed but the user computing device has yet to receive the update. The priority access preference aims to provide the best available choice of the user computing devices for the user at the time of login.

At step 1912, a preferred user user computing device is selected based on the user device inventory assessment of step 1910. At step 1914 the preferred device is unlocked (if not already unlocked) for checkout by the logged-in user after removal from the charging pocket. The system may identify the preferred user computing device to the user (e.g., the inmate) at step 1916 by, for example, flashing an indictor light for the charging pocket containing the preferred user computing device, as well as by displaying the device name or number that the user may reference to find the selected device, or by audio and visual instructions provided to the inmate.

At step 1918, the system assigns the preferred user device to the logged in user. As such, the preferred user computing device, once assigned, is only operable with respect to the assigned user logging into the preferred user device. No other user may log in to the preferred user computing device, and therefore no other user (e.g., no other inmate) may log in to and operate the preferred user computing device after it has been assigned. Assignment of the device to the logged in user constitutes yet another type of access restriction to kiosk services which prevents a first inmate from retrieving the device and a second inmate from using the retrieved device in manner that circumvents security safeguards. Assignment of the device to the logged in user also facilitates user computing device tracking and reporting, and assigned user oversight in the operation of the device and to detect events of interest pertaining to improper use of the device to maintain compliance with security objectives.

At step 1920, data logs are kept of the check-out process and the outcomes of the prior steps for system archival and reporting purposes. Detailed records are kept and made available to ensure that security compliance is maintained with respect to user computing device access, as well as to assess system reliability and to troubleshoot issues that may be presented or experienced. The data log may include image capture for a camera equipped kiosk or charging bay device, or otherwise may include an image capture from an external camera. The image capture forms an identification record of the inmate that is checking-out the user computing device as another security enhancing measure which can be reviewed and compared against other system data to thwart attempts for unauthorized access to a user computing device.

At step 1922, the preferred user computing device is checked back in to the charging system by inserting the preferred user computing device into any one of the unoccupied charging pockets or charging slots. The inmate need not return the preferred user computing device to the same slot where it was checked out from. The system identifies the preferred user computing device as it returned, and the system confirms that it corresponds to one of the checked-out devices and that it is being correctly returned. Once the confirmation is made, the system may optionally lock the checked-in device at step 1924 and unassign the preferred user computing device from the assigned user at step 1926. When the checked-in device is confirmed and unassigned, it may be charged and software/firmware may be updated if needed. The checked-in device may then be considered again in the device inventory assessment of step 1910 for subsequent users who login to request a user computing device.

At step 1928, data logs are kept of the check-in process and the outcomes of the prior check-in steps for system archival and reporting purposes. Detailed records are kept and made available to ensure that security compliance is maintained, as well as to assess system reliability and to troubleshoot issues that may be presented or experienced. The data log at step 1928 may include image capture for a camera equipped kiosk or charging bay device, or otherwise image capture from an external camera. The image capture forms an identification record of the inmate that is checking-in the device as another security enhancing measure which can be reviewed and compared against other system data to thwart attempts for unauthorized access to a user computing device.

As shown at step 1930, the inmate request from step 1904 may optionally be submitted to an administrator at the facility for review and approval. Once approved by the administrator, the system can automatically select a preferred device at step 1912. If the administrator denies the request, the system may inform the user and the system reverts to step 1904 and awaits another user login. In some embodiments, once approval is obtained from step 1930, the inmate may log in again to “claim” the device through steps 1906, 1908, 1910 and 1912. The approval may be obtained through a notice or alert which may be generated and delivered to administrators in any form via any medium desired in an active or passive alert (e.g., email, SMS text notification, voice message, push notification, etc.) or via interactive graphical screen displays such as those described above.

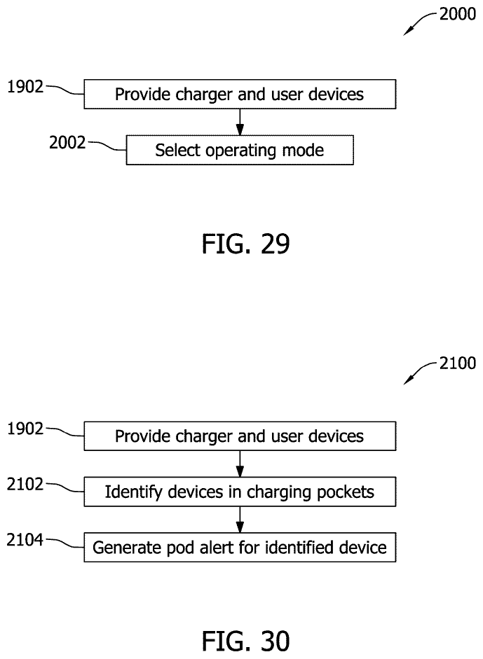

FIG. 29 is a method flowchart of exemplary processes 2000 for operating configurable kiosk systems and charging bays in different security modes. Such security modes may be independently selected at the POD level in a facility, and different kiosk systems and charging bays may operate with different degrees of security suitable for the PODs in which they are located.

The processes 2000 includes step 1902 where charging pockets are supplied or provided as described above. The processes 2000 may be implemented in one or more of the computing devices, controllers or control devices described above.

The charging system is operable in multiple modes which may be selected at step 2002 via a graphical screen display or via another input selector or user interface provided in the system or in the devices included in the system. In contemplated embodiments, the modes may include a basic mode, an intermediate mode, and an advanced mode offering increasing degrees of security compliance and complexity to meet the varying needs of different locations and applications in a facility.

The basic mode in contemplated embodiments may include manual locking or unlocking of user devices in the charging systems, charging indicators for user devices in the charging pockets, and no additional access restrictions or security-minded intelligence in the operation of the charging system. The basic mode is sometimes referred to a No-Smarts mode wherein more advanced logic features are present but not enabled or not turned on. Simpler operation in the basic mode may be desirable in, for example, booking areas or medical areas of a facility than in other locations.

The intermediate mode in contemplated embodiments may include manual and automatic locking, as well as remote locking or unlocking capability, charging indicators for user devices in the charging pockets, and manual and automatic charging bay device enrollment as described above to facilitate reporting via graphical screen displays and the like described above. The intermediate mode enables some but not all of the logic features to provide an intermediate level of security in the operation of the kiosk and charging bay systems described herein.

The advanced mode in contemplated embodiments may include the features of the intermediate mode plus inmate check-in and check-out particulars of the type described above and below via an optional kiosk interface (e.g., touchscreen or telephone handset) or via another input interface and control device existing in the system. In addition to the access system for the user computing devices, the user computing devices themselves may accept and process inmate login for authorization of the user, user privilege assessments and facility scheduling assessment as an alternative or redundant form or access restriction to ensure that access to kiosk services can be made only by permitted users. User assignment of computing devices and device tracking and monitoring are also part of the advanced mode. In the advanced mode, manual, automatic and remote locking and unlocking may be made in groups of charging pockets simultaneously in some of the embodiments described above, or may be made individually on a pocket-by-pocket basis by the system controls. The advanced mode enables most if not all of the logic features to provide a high level of security in the operation of the kiosk and charging bay systems described herein.

The kiosk systems and charging bays and may be switched back and forth between the basic, intermediate and advanced modes as needed or as desired. Such switching between the operating modes is particularly beneficial when moving the kiosk system and/or charging bays from one location to another that have different security needs in a facility, or for different facilities having different security requirements. The kiosk system and charging bay devices are therefore versatile and flexible to meet a variety of different needs and applications with a common and relatively low cost manufacture.

By virtue of the different operating modes, varying degrees of security are conveniently and selectively enabled or disabled in the kiosk system and charging bay devices, allowing them to be more or less universally used to meet the different needs of different environments in facilities. For example, and considering a correctional facility, some areas of the facility will require more or less security than another, and the charging system may be flexibly operated in a mode suitable for where it is located. Different types of kiosks and charging bays specifically geared toward areas requiring more or less security are avoided, and supply chains and inventory requirements for the kiosk systems and charging bays may be advantageously simplified. Notices or alerts concerning a change in selected operating mode for any of the monitored charging bay devices may be generated and delivered to administrators in any form via any medium desired in an active or passive alert (e.g., email, SMS text notification, voice message, push notification, etc.) or via interactive graphical screen displays such as those described above.

FIG. 30 is a method flowchart of exemplary user device identification and notification processes 2100 for operating configurable kiosk systems and charging bays such as those described above. The processes 2100 may be implemented in one or more of the computing devices, controllers or control devices described above.

At step 2102 the system identifies the user devices in the charging pockets. As such, the system is aware of specific devices in each of the charging pockets and can distinguish the user computing devices in each pocket from one another. The charging pockets are equipped to identify the user devices are they are inserted, so the same pocket can identify different ones of the user device inventory which may be used with the pocket. This means that user computing devices need not be checked out and returned to the same slot for the system to track access to the user computing devices. The user computing devices instead can be checked out from one charging slot and be returned to another. As such, the system is more user friendly and intuitive from the user (e.g., inmate) perspective and less burdensome for correctional facility administrators.

The ability to identify different user computing devices by the charging pockets means that the system can generate alerts or notifications as shown at step 2104. In the example shown, an alert is generated that an identified user computing device checked out from one pod location in a facility is returned to another pod location in the facility. For example, the system can detect when a user computing device assigned to one POD is placed into a charger belonging to another POD (e.g., a B-POD tablet placed into a C-POD charger) and generate an alert accordingly. Because the system can determine which user device is in each specific charging slot at any time, it can also know when the B-POD tablet is removed from the C-POD charger and returned to the B-POD charger. User computing device inventory tracking over a number of kiosk systems and charging bays is therefore improved. Notices or alerts at step 2104 may be generated and delivered to administrators in any form via any medium desired in an active or passive alert (e.g., email, SMS text notification, voice message, push notification, etc.) or via interactive graphical screen displays such as those described above.

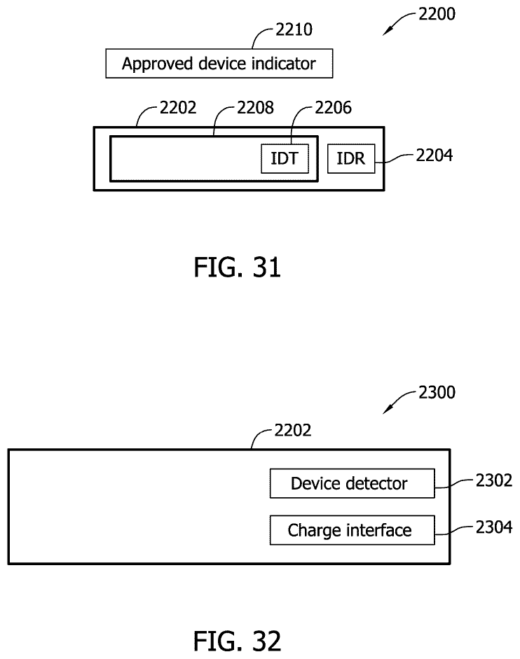

FIG. 31 schematically illustrates charging pocket and user device identification features 2200 which may be implemented in configurable kiosk systems and charging bays. In the example shown, the charging pocket 2202 includes an identification reader (IDR) 2204 which cooperates with an identification tag (ITD) 2206 coupled to a user device 2208 to identify the user device 2208 as it inserted into the charging slot defined by the pocket 2202.

In a contemplated embodiment, the reader 2204 and tag 2206 may be configured as Near Field Communication (NFC) devices. When the user computing device 2208 is inserted into the charging slot of the charging pocket 2202, the reader 2204 obtains identification information from the tag 2206 that uniquely identifies the user computing device to the system. For example, the tag 2206 may include encoded device information such as Device MAC address, Device Serial Number, and Device ID. By virtue of the readers 2204 in each pocket 2202, the system identifies each of the tablet devices 2208 and builds a database of which tablet device is in which pocket. The database can be updated as the tablets are moved from one pocket to another in use of the system. By referencing the database for the location of specific tablets in each of the charging slots provided, the system can unlock a specific tablet or a batch of tablets according to information such as the power levels of selected tablets.

To ensure proper communication between the tag 2206 and the reader 2204, a distance between them should be about 2 cm or less when the user computing device 2208 is fully inserted into and received in the charger pocket 2202. In contemplated embodiments, the pocket 2202 is fabricated from metal and provided with a plastic mold to hold the reader in a predetermined orientation in the pocket 2202 to ensure communication with the tag 2206 when the user computing device 2208 is inserted. In various embodiments, the reader 2204 may be located behind the rear edge of the user device 2208 and the tag 2206 may be located on the facing end of the user device 2208 such as in the illustrated embodiment, or the reader 2204 may be located above or below the user device 2208 with the tag 2206 being located on the facing surface of the device 2208.

In another contemplated embodiment, user computing device identification can be obtained via, for example, a 5-Pin USB Data Line which transmits the same identifiers (MAC address, serial number, device ID) via a physical wired connection instead of over-the-air like the NFC tags and readers described above. Once the wired connection is establishing in the pocket 2202 with a user computing device 2008, the identification data and information can be communicated in the data line connection.

In still another contemplated embodiment device identification can be realized via MDM data and local network communication to identify tablet devices during check-in and check-out.

As also shown in FIG. 31, an approved device indicator 2210 is located adjacent the charging pocket 2202 and may be activated to show the user which ones of the user computing devices has been approved for access and use and which may be retrieved in the check-out process. The indicator 2210 in a contemplated embodiment may be a light emitting diode (LED) which may illuminate in a selected color, intensity or flashing pattern to garner attention of a user to retrieve the device. Given a number of pockets with such indicators, the user may quickly and intuitively locate the user device 2208 which may be retrieved from the corresponding charging pocket. Other types of indicators are possible, and the user may receive audio and/or visual instructions and assistance to aid the user in locating the identified device in the pocket that the system intends for the user to access and retrieve.

FIG. 32 schematically illustrates user computing device detection and interface features 2300 for charging pockets implemented in configurable kiosk systems and charging bays. In the example shown, the charging pocket 2202 includes a device detector element 2302 and a charge interface 2304. The detector element senses the presence or absence of the user computing device 2208 and operates the charge interface 2304 accordingly. Specifically, the charger interface 2304 may be energized when the user computing device 2208 is present and may be de-energized when the user computing device 2208 is absent. The charger interface 2304 in contemplated embodiments may establish a physical wire connection to a charging port of the user computing device 2208, although wireless charging interfaces are possible in other embodiments.

In a contemplated embodiment, the device detector element 2302 is implemented as a trigger wire or trip wire in the pocket. Insertion of a tablet into the charging pocket influences the trigger wire and activates charger logic which ensures that charging is disabled in the pocket when there is no tablet present. In the event that the tablet detection fails, the pocket remains powered off. This beneficially prevents potential electrical arcing or shorting caused by foreign object insertion to the charging pockets, reduces phantom power consumption, improves user safety, and extends the lifespan of the system and the tablet devices.

In contemplated embodiments, the trigger wire or trip wire is implemented in a pogo-pin charging connection made between the charging pocket 2202 and the user device 2208. For example, there may be three points on the charging pogo-pin and there may be three wires in a charging cable. Two of the three are used for charging, and the third is used to detect whether the tablet is placed into the charging pocket as a form of a trigger switch that completes a circuit only when the user device 2208 is in contact with it. When triggered, it detects that the tablet has been inserted, and the charging current can also be added for cross-verification of the tablet presence. By virtue of the trigger, the system can distinguish between charging pockets that include a tablet and charging pockets that are empty (i.e., do not include a tablet), both of which can be useful for charging circuit control as well as for reporting purposes on graphical user display screens such as those above.

The system can also send charging information on a per-pocket basis, enabling detection of issues with individual pockets or the charger overall. Logging is available to help diagnose lock mechanism failures at the pocket or charger level, with readable GUI notifications for both facility and HomeWAV administrators. Notices or alerts concerning charging performance, lock mechanism performance, and other detected issues may be generated and delivered to administrators in any form via any medium desired in an active or passive alert (e.g., email, SMS text notification, voice message, push notification, etc.) or via interactive graphical screen displays such as those described above.

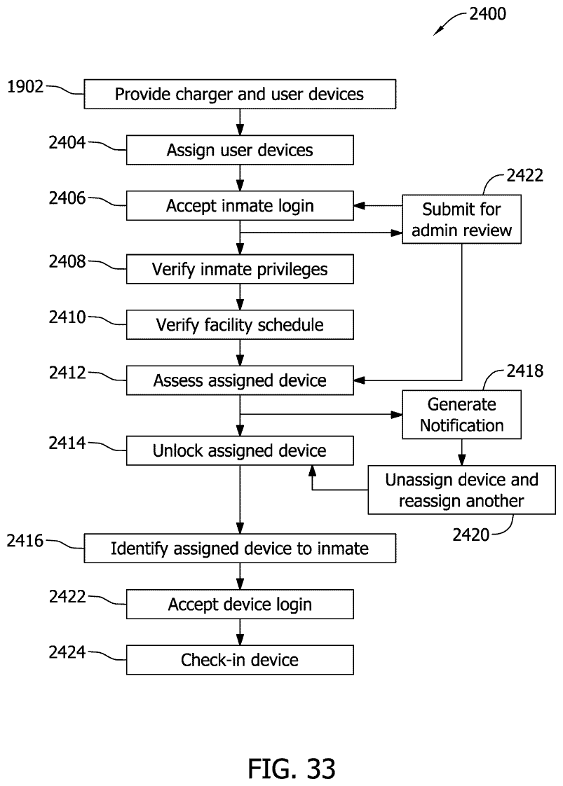

FIG. 33 is a method flowchart of exemplary assigned user device checkout processes 2400 implemented in configurable kiosk systems and charging bays such as those described above. The processes 2400 may be implemented in one or more of the controllers or control devices described above. The processes 2400 accommodate models wherein user computing devices are more or less permanently assigned to individual users for checkout and check-in. Such permanently assigned devices to specific users are not useable by others, and as such the system needs specific awareness of which user computing devices are assigned to which users and where the assigned devices are in the charger system to ascertain their status in the checkout process.

The processes 2400 includes step 1902 where charging pockets are supplied or provided as described above. At step 2404 the user computing devices are respectively assigned to authorized users (e.g., inmates) before a request for access is made through the system. As such, the user computer devices in the processes 2400 are sometimes referred to as pre-assigned devices in the system. As such, the pre-assigned user computing devices are only operable by the assigned user, and the system accordingly needs to make the pre-assigned device available to the pre-assigned users and avoid providing a pre-assigned device to another user. Once assigned, the user computing devices remain assigned to the individual authorized user such that the user may repeatedly check-in and checkout the assigned device in an exclusive manner that certain facilities may prefer. When inmates are released or change PODs, however, the assigned devices are unassigned and made available to other users via reassignment to persons who remain located in the PODs.

At step 2406 a user login is accepted as described above. At step 2408 user privileges are assessed as described above. At step 2410 the facility schedule is consulted to approve or deny access to a user device as described above. At step 2412 the specifically assigned device for the authorized user, which may be determined by the user login credentials, is assessed. Specifically, the battery charge status and the software/firmware status is checked for the assigned device to ensure that the device is sufficiently charged and sufficiently up to date for use by the assigned user. If the assigned device passes the assessment the assigned device may be unlocked at step 2414 if not already unlocked. At step 2146, the system may identify the assigned device for the inmate as described above. Since the device is already pre-assigned to the user making the request, the pre-assigned device may be removed from the charging system for use by the assigned user after login as shown as step 2422. When the assigner user is finished with the user computing device, the assigned user computing device may be returned to one of the charging pockets and checked back in as shown at step 2424. The system recognizes the assigned user computing device at check-in and charges the device for future use by the assigned user and performs any updates.

At step 2418, if the pre-assigned device does not pass the assessment (e.g., it is not sufficiently charged) a notification to the user may be generated and the system may optionally and temporarily reassign another user device which does pass the assessment criteria for use by the logged in user. The process then reverts to step 2414 to optionally unlock the reassigned device and step 2416 the system can indicate its location to the user for retrieval. The reassignment may be temporary and effective only until the originally pre-assigned device again passes assessment criteria for use. When the reassigned device is checked in again, the system may recognize it and undo the reassignment. In some embodiments, facility administrators may be notified by the system in advance for approval to reassign a device before any reassignment is made. Notices or alerts may be generated and delivered to administrators in any form via any medium desired in an active or passive alert (e.g., email, SMS text notification, voice message, push notification, etc.) or via interactive graphical screen displays such as those described above.

As shown at step 2422, the inmate request from step 1904 may optionally be submitted to an administrator at the facility for review and approval. Once approved by the administrator, the system can automatically assess the pre-assigned device at step 2412 or the user may log back in to claim the device as described above. Approval from an administrator may be solicited in any form via any medium desired in an active or passive alert (e.g., email, SMS text notification, voice message, push notification, etc.) or via interactive graphical screen displays such as those described above.

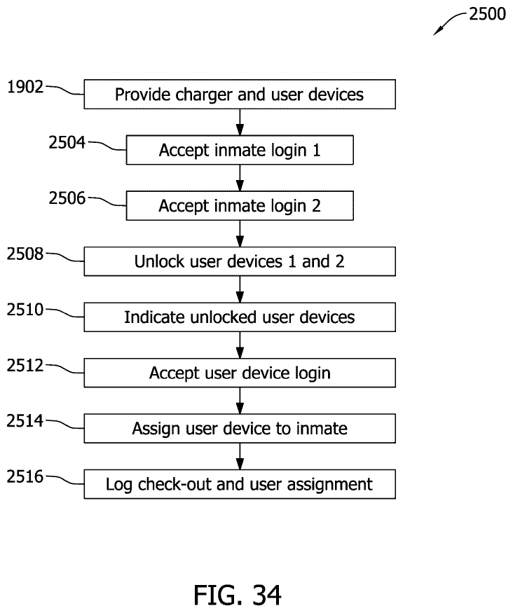

FIG. 34 is a method flowchart of user device assignment processes 2500 which may be implemented in configurable kiosk systems and charging bays. The processes 2500 address instances wherein different users request devices at approximately the same time or close in time to one another. In other words, the processes 2500 resolve issues presented by concurrent requests that can be confusing from the user (e.g., inmate) perspective.

The processes 2500 includes step 1902 where charging pockets are supplied or provided as described above. At step 2504 an inmate user login is accepted as a first request for a device, and at step 2506, a second inmate user login is accepted as a second request for a device. At step 2508 two user computing devices are unlocked (if not already unlocked) which correspond to each user request, and at step 2510 the system indicates the devices for retrieval by each respective user. If the devices are indicated to the users at close to the same time, ambiguity may be presented which device is to be retrieved by which user. Such ambiguity, in turn may create user confusion leading them to inadvertently retrieve the wrong tablet. This raises the possibility for the system to confuse the two users of each computing device, and can be a means for users to exploit security safeguards by intentionally requesting devices at or near the same time or to refrain from quickly retrieving devices from the charging slots until another device is made available so that the user may attempt to switch devices.

The system may recognize such a potentially confusing circumstance to the user, or a vulnerability to users attempting to thwart the system, because the system knows that both user computing devices are presently in their charging pockets while both are simultaneously being indicated for retrieval by approved users. To address this, the system will simply wait for the first user to retrieve a respective device, and upon login to the retrieved user computing device, that computing device is assigned to the logged in user while the other device may be assigned to the other approved user as shown at step 2514 either before or after the second user logs in to the second user computing device. Therefore, even if the user inadvertently selects the wrong user device the system is self-correcting and accurately tracks the assigned user who actually possesses each user computing device for security oversight.

At step 2516, the system logs instances of concurrent requests and related user assignments to the devices and keeps a record of which user logged into which device and the user assignments made for each device. Notices and alerts of concurrent requests and outcomes may also be generated in any form via any medium desired in an active or passive alert (e.g., email, SMS text notification, voice message, push notification, etc.) or via interactive graphical screen displays such as those described above.

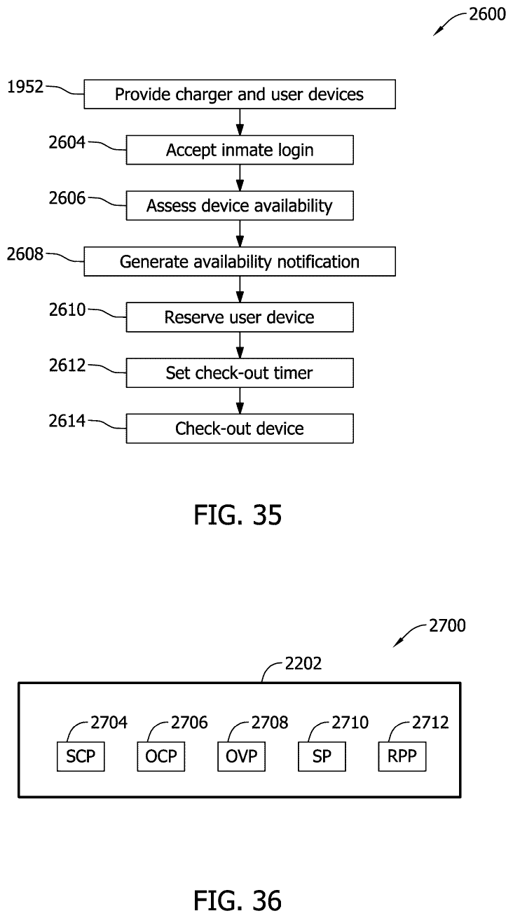

FIG. 35 is a method flowchart of queued user computing device assignment processes 2600 which may be implemented in configurable kiosk systems and charging bays. The queued processes 2600 beneficially provide device availability information and facilitate decision making from the user perspective in view of current demands for access to the tablet computer devices.

The processes 2600 includes step 1902 where charging pockets are supplied or provided as described above. At step 2604 an inmate user login is accepted and at step 2606 the system assesses user computing device availability. At step 2608 an availability notice is generated for review by the user (e.g., inmate) making the request. The notification may be made via a touch screen, a telephone handset, a speaker device or another notification element, and the notice may include the number of user computing devices which are currently available for checkout and request confirmation from the user whether or not to proceed with checkout for one of the user computing devices. One of the available user computing devices is reserved at step 2610 and a timer is set at step 2612.

Within the time limit set, the reserved user computing device is deemed unavailable to other users and if the user completes check-out in the set time limit the reserved device is assigned to the user at check-out, but if the user does not complete checkout at step 2614 before the timer expires, the reserved device is again deemed available as an unreserved and unassigned device. The user must start the process over with a new login request and another availability notification will be generated. Likewise, if no user computing device is available at the time of a request, the user can be notified and informed and may submit another request at a later time. In some cases, the notification may include a time that another device may be made available since the system knows the checkout times of other computing devices and when to expect them to be returned. For instance, if a facility sets a maximum tablet usage time of 1 hour the system can expect tablet devices that have been checked out about one hour ago to be returned shortly, and may also be able to deduce or predict battery charge levels for returning devices that have sufficient battery charge to be checked back out.

FIG. 36 schematically illustrates electrical protection features 2800 for charging pockets that may be implemented in configurable kiosk systems and charging bays. As shown in FIG. 36, the pocket is configured with electrical circuit protection such as short circuit protection (SCP) 2704, overcurrent protection (OCP) 2706, overvoltage protection (OVP) 2708, surge protection (SP) 2710, and reverse polarity protection (RPP) 2710. Such protective devices address various different electrical conditions that could otherwise damage the charging bays or the user devices while in the charging bays, as well as address other issues such as foreign objects being inserted in the charging pockets and inadvertent mistakes in the assembly or installation of the modular charging bays which could otherwise negatively impact the operation of the system.

The SCP 2704, OCP 2706, OVP 2708, SP 2710 may be implemented, for example, via respective components on a control board of a controller device which supplies electrical power to charging circuitry in each pocket, or may be integrated in a power supply module or power supply board supplying power to a control device. A variety of known circuit protection components are known and may be incorporated as the SCP 2704, OCP 2706, OVP 2708 and SP 2710. Individually and collectively, they protect the charging pockets and tablet devices from electrical conditions that can otherwise damage the pockets and tablet devices. Certain devices are known which may provide combinations of SCP, OCP, OVP and SP and which may be utilized. If any of the devices operate to address SC, OC, OV or surge conditions, notices and alerts may be generated in any form via any medium desired in an active or passive alert (e.g., email, SMS text notification, voice message, push notification, etc.) or via interactive graphical screen displays such as those described above.

The RPP 2710 may be provided in a connector component or components which prevent adverse consequences when hot and neutral wires are inadvertently swapped in an electrical connection being made in the system. In contemplated embodiments, the RPP is integrated in a control board power supply connection to prevent the positive and negative pole connections of power supply circuitry from being reversed. A variety of RPP components are known and may be incorporated. In some cases, the electronics in the charging bay devices may detect and take action for reverse polarity protection to prevent a power supply circuit board or connection control board from being burned out. Notices and alerts concerning detected reverse polarity connection events may be generated in any form via any medium desired in an active or passive alert (e.g., email, SMS text notification, voice message, push notification, etc.) or via interactive graphical screen displays such as those described above.

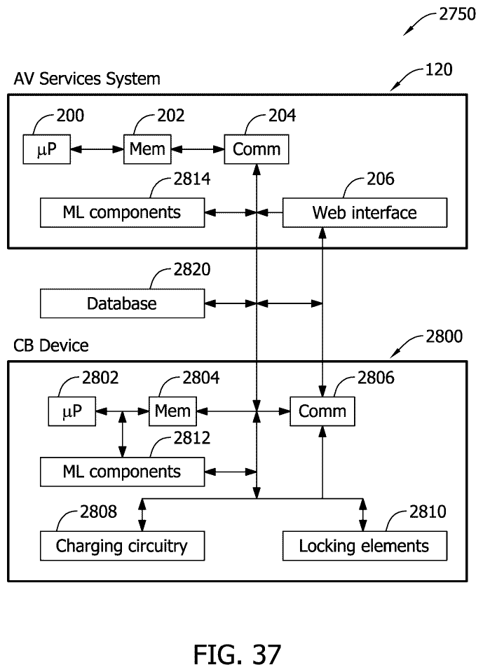

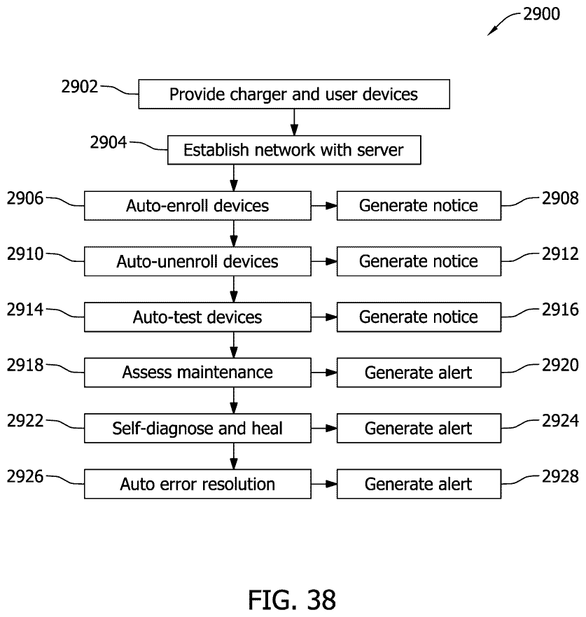

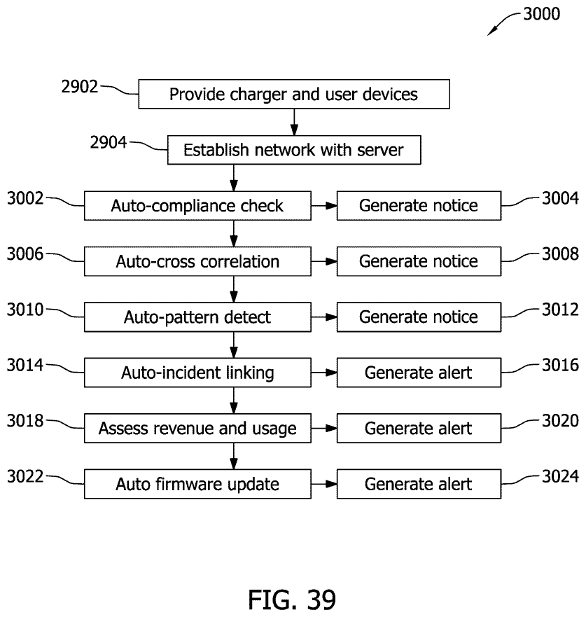

As further illustrated in the system block diagram of FIG. 37 and the method flowcharts of FIGS. 38 and 39, kiosk systems which may be configurable with charging bay devices, as well as portable computing device charging systems and user computing device access management systems which include or incorporate the above described charging bays, charging pockets, method processes, and graphical screen displays such as those described above afford considerable intelligence gathering capability in the operating status of the systems and devices in the system which may be further harnessed to realize advanced functionality with further benefits.

In particular, comprehensive data and information is sensed or otherwise detected in the system 2750 concerning an operation of charging bay devices 2800, and also user computing devices (e.g., inmate computing devices) such as those separately described above in relation to FIG. 3 and which are secured and charged in the charging bay devices 1800. Sensed operating data and usage data facilitates effective oversight, management and compliance with security demand and requirements for controlled environment (e.g., correctional facility) applications. Collected over time, such data and intelligence generated and collected in the system 2750, in turn, realizes intelligent automation and advanced analytic capabilities that heretofore have been unrealized in conventional kiosk systems for portable computing device and charging and access management systems for tablet computing devices in a controlled environment such as a correctional facility.

As shown in the example system 2750 of FIG. 37, a charging bay device 1800 is placed in communication with a server computing device which may be configured as the AV Services System 120 described above. The charger bay device 2800, like the server computing device, may include a processor 2802, a memory 2804, and a communication element 2806 sending and receiving data information to and from the server computing device. The charging bay device 2808 includes charger circuitry 2808 and locking elements 2810 and related sensors and interfaces which may communicate status information and error information to the server computing device concerning operation of the charger circuitry 2808 and locking elements 2810.

Additional sensors and machine readable elements of the type described above may likewise be included in the charging bay device 1800 and may communicate, for example, the presence and absence of a user computing devices in the charging pockets or charging slots, charger bay device and user computing device identification data, charging bay device and user computing device enrollment data and other information to realize the functionality described herein. Likewise, the charger bay device 1800 may communicate and report software/firmware version and other data and information of interest for the system, and the charger bay device 1800 may receive remote lock and unlock commands and facilitate remote testing and diagnostics as desired. Any of the exemplary charging bay devices described above may be provided as the charging bay 1800 for purposes of the system 2750, and in contemplated embodiments multiple charging bay devices 1800 are monitored simultaneously with the server computing device.

Like the systems described above, the system 2750 is scalable to include any number n of charging bays devices 1800 in the same or different facilities for desired monitoring by the system 2800. Generally speaking, the more charging bay devices 1800 that are monitored by the system 2750 the more data is collected and the more powerful the desired automation and analytics may become. The data and information sensed and collected in the operation of the system 2750 is stored and archived in a system database 2820 and may be accessed and retrieved by the server computing system and the charging bay device (as well as by user computing devices) to perform the desired automation data processing and analytic data processing.

In contemplated embodiments, sensed and detected data and information in the system may be processed or analyzed with Machine Learning (ML) components 2812 in the charging bay device 1800 and/or ML components 2814 of the server computing device. The machine learning components 2812 and 2814 may execute Machine Learning (ML) Algorithms to provide enhanced reporting capabilities for charging bay devices added, charging bay devices removed, and operating status of the charging bay devices over time. Predictive capabilities may also be afforded through ML algorithms, and automated problem solving in the real-time operation of the system 2750 may also be realized in the execution of ML algorithms.

In some embodiments, ML components may also be provided in the user computing devices (e.g., the administrator user devices described above) to perform ML algorithms on the data collected by the system 2750, both separately from and together with data collected in the usage of the user computing devices (e.g., inmate devices such as those described above). Likewise, ML components in further contemplated embodiments may be provided in control boards, controller devices or computing devices which may be separately provided from the charging bay device 1800 and the server computing device. For example, ML components may be provided in one or more kiosk controllers which are in communication with the charging bay devices 1800 and which further communicate with the server computing device. Still further, additional computing devices or processor-based devices may be provided with ML components to run ML algorithms on data stored and collected in the database 2820 or in another storage component or memory device in the system 2750 or which is accessible by the system 2750.

In the system 2750, one or more processors in the devices described, via computer-executable instructions stored on non-transitory computer-readable media or medium, preforms data processing to intelligently “learn” and manage system operation and device operation in view of historical data and information which may provide a baseline upon to predictively address issues that have not yet actually presented themselves in the real world yet, to discover cause and effect relationships in the system operation that would otherwise be difficult to discern, and to deduce problematic instances that otherwise may be obscured to human facility administrators from the data and information streams provided.

Accordingly, in contemplated embodiments, machine learning techniques and artificial intelligence algorithms may be employed which beneficially operate on historical data and information by such ML components 2812, 2814 to improve operation of the system 2750 in important aspects to produce a more meaningful level of system oversight. As such, and over time, the system 2750 may become progressively better in its predictive capabilities to desirably avoid certain types of issues and in its diagnostic capabilities to detect certain issues and/or in its ability to automatically respond to certain types of detected issues. In some contemplated embodiments, ML components may analyze, organize, and/or process data without being explicitly programmed to do so via applicable machine learning methods and machine learning algorithms while still producing machine learning outputs such as those described below.

As shown in the exemplary auto-detection, auto-configuration and auto-troubleshooting processes 2900 of FIG. 38 implemented in the system 2750 shown in FIG. 37, charging bay devices 1800 and user computing devices are provided at step 2902. The charging bay devices 1800 and user computing devices may be configured to communicate as shown at step 3904 with a server computer device via a local network or via the Internet in contemplated embodiments. Further, the charging bay devices 1800 and user computing devices may be configured to communicate exclusively with the server computing device which is maintained in a secure manner to meet security compliance requirements of controlled environments such as correctional facility environments.

When charging bay devices 1800 and user computing devices (e.g., inmate devices) are self-identifying to the system via any of the techniques described above including machine readable identification elements or via transmission of self-identifying data to the server computing device, administrative burdens of launching and configuration of the system may be further reduced via automated device enrollment processes as shown at step 2906. More specifically, newly introduced charging bay devices 1800 may auto-enroll or auto-register in the system when connected to the network according to smart enrollment processes. That is, the charging bay devices 1800 may be automatically recognized when introduced and connected to other system devices and system components, and after being automatically recognized, the recognized charging bay devices 1800 may be automatically added to graphical screen displays such as those described herein or incorporated by reference for reporting purposes for tablet computer devices associated with auto-enrolled charging bay devices. Modular assemblies such as the charging bay pockets which may be utilized in charging bay devices 1800 may likewise be automatically recognized and verified and validated for purposed of step 2902.

As aspects of auto-enrollment at step 2906, the system 2750 may intelligently and automatically verify the authenticity of charging bay devices 1800 added via checking of device manufacturer info, device model info, device serial no. info, MAC address info, etc. In doing so, the system 2750 may reference an external database or databases of authorized charging bay devices and/or user computing devices to verify the devices as they are introduced. Notices and alerts may be automatically generated at step 2908 for auto-enrolled charging bay devices, auto enrollment of user computing devices, and/or auto-enrolled charging bay pockets or pocket assemblies at step 2906. Notices and alerts may be automatically generated at step 2908 regarding devices that could not be confirmed or validated to complete an auto-enrollment process, Such notices and alerts may be generated in any form via any medium desired in an active or passive alert (e.g., email, SMS text notification, voice message, push notification, etc.) or via interactive graphical screen displays such as those described above.

Because the charging pockets can specifically identify user computing devices in each charging slot, the user computing devices can be independently auto-enrolled with a similar verification of validation of user computing device identification data and information to ensure that unauthorized devices are not added to the system 2750. Auto-enrollment processes are run initially when the system 2750 is first installed and configured, and auto-enrollment processes are run again as changes are made to retrofit the system with additional charging bay devices, modular assemblies for charging bay devices, or user computing devices.

Auto-unenrollment processes and related notices and alerts may likewise be provided at steps 2910 and 2912 to similarly process a removal of charging bay devices 1800 or the removal of modular charging bay pockets and modular assemblies such as those described above for the charging bay devices 1800, and the system may automatically update administrator reports for graphical screen displays of the type described above. All automated enrollment and unenrollment operations performed on the system may be logged by the system for detailed reporting and assessment of devices added and removed in the various kiosk system and charging systems in the various different facilities being monitored.

Additionally, the system 2750 may automatically confirm the proper operation of new and auto-enrolled charging bay devices 1800 as shown at step 2914 via, for example, device testing algorithms using remote lock and unlock commands to assess proper operation of locking elements or locking mechanisms as well as to assess operation of charging circuitry and other components of interest. Notices and alerts may be automatically generated at step 2916 to flag device fault conditions and/or error conditions for auto-enrolled charging bay devices, or other automatically detected data and information for the benefit of local and remote system administrators to manage and oversee system security for the controlled environment as new charging bay devices and replacement modular assemblies are added to the system. Such notices and alerts may be generated in any form via any medium desired in an active or passive alert (e.g., email, SMS text notification, voice message, push notification, etc.) or via interactive graphical screen displays such as those described above.

Additionally, in view of the intelligence afforded by the system 2750, AI-driven predictive analytics may be applied on the data and information collected on the system to assess device maintenance needs over time as shown at step 2918. Natural language summaries and actionable alerts may be provided as shown at step 2920 through a centralized dashboard screen display integrated with external management platforms for providing device maintenance and system upkeep, including repair or replacement of modular devices and modular assemblies such as those described above. Local correctional facility administrators accordingly need not undertake maintenance inspections, troubleshoot issues or arrange for technicians to repair or replace devices or components to restore full system operation. If sufficient data exists for the performance of charging bay devices 1800 and modular assembly performance, predictive maintenance scheduling is possible for predicted failures before the failures occur, and related suboptimal optimal operation of the system or reduced capacity of the system due to device failures or component failures may be avoided. Predictive Maintenance Triggers may also be realized via detected audit patterns. For example, if certain administrator actions historically lead to failure conditions, the system may proactively schedule checks after those actions in order to proactively address and if possible to avoid the types of failures that have historically been experienced. Notice and reminders may be sent to responsible persons to proactively take desired actions to avoid foreseeable failure conditions.

All activity and operations of steps 2918 and 2920 may be logged by the system for detailed reporting and assessment of system reliability, which may also beneficially provide insight for improvements in the manufacture of charging bay devices or modular components to address detected reliability issues in actual usage of the system. Insights may also be realized for new charging bay device features that may improve system reliability in desired aspects.

As shown at step 2922, self-diagnostic and healing capability is also possible in the system 2750 by automatically and iteratively running health check algorithms on a periodic basis and in some cases automatically fixing minor issues without requiring any type of administrator action or intervention. For purposes of step 2922, automated error resolution is possible to resolve common issues via predefined scripts which are triggered automatically in response to certain types of detected error conditions. Remote Auto-Recovery is possible as well wherein, if a charging bay device 1800 goes offline, the system attempts remote fixes (e.g., restart services, reconnect network) before alerting administrators. Notices and alerts for predicted maintenance needs, actual maintenance needs, auto-maintenance fixes, auto-error resolutions, and auto-recovery instances may be generated at step 2924 in any form via any medium desired in an active or passive alert (e.g., email, SMS text notification, voice message, push notification, etc.) or via interactive graphical screen displays such as those described above. All such activity may further be logged by the system for detailed reporting and assessment of system operation.

By virtue of the comprehensive data and information collected by the system, operational event history may be advantageously integrated with administrator access and audit logs and applied AI-driven event correlation and predictive analytics to identify patterns, generate compliance-ready reports, and provide natural language summaries of combined data streams.

For instance, and as shown in the analytic processes 3000 of FIG. 39 for the system 2750 shown in FIG. 37, the charging bay devices and user computing devices are provided at step 2902 and the network is established at step 2904. As shown at step 3002, the system may perform automated compliance checks by running periodic compliance auditing algorithms and sending reports as shown at step 3004 in an automated manner without manual action or effort required by local or remote administrators. In contemplated embodiments, the compliance checks are made from the security perspective to ensure that the system remains secure and that correctional facility security objectives have not been circumvented. Such compliance checks may include auditing of identified devices to ensure that they are authorized devices, auditing of device locations to ensure that the devices are in the proper locations, and cross-referencing lock and unlock data with device usage data and making other data comparisons to confirm that devices have been secured and access restrictions have been maintained. Alerts and notices generated at step 3004 may include confirmations (e.g., audit passed) with supporting data or include flagged issues for investigation by correctional facility administrators with supporting data so that suspicious events may be promptly investigated or addressed. Audit logs for interests other than security are also contemplated, and all audit logs and compliant check events and results are logged and stored on the system for further review and study as desired.

As shown at step 3006, the system may also perform Cross-Log Correlation for Root Cause Analysis when a monitored device error occurs. For example, the system may automatically run or check audit logs to see if an administrator action (e.g., firmware update or permission change) preceded a device error issue in the past. As such, when a similar error is detected that follows a similar administrator action, the system can flag the error condition with explanation for what caused the error at step 3008. Such reports including notices and alerts at step 3008 can serve as administrator training tools in some instances to help administrators understand the consequences of taking certain actions that may otherwise not be foreseeable or understood by administrators at the time the actions are being taken, and in view of this human administrators may learn to refrain from taking certain actions or otherwise to proactively address related issues when taking certain actions to avoid error conditions. Particularly when the root cause of certain errors is human action or human error, such Cross-Log Correlation for Root Cause Analysis can be particularly helpful. Such Cross-Log Correlation for Root Cause Analysis is also beneficial from the perspective of charging bay device and modular assembly fabrication or from the perspective of kiosk services administrators to optimize the system in view of the root cause analysis that would otherwise be difficult to discern for the typical human operator monitoring a rather complex system of inter-related components and a myriad of potential error conditions and different causations for error conditions. All activity related to steps 3006 and 3008 is logged and recorded on the system for further review and study.

As shown at step 3010, Intelligent Behavioral Pattern Detection may be realized via AI analysis to identify patterns like repeated login failures followed by device configuration changes that could relate to attempts to circumvent security safeguards. At step 3012, the system flags potential security risks relating to such patterns. All activity related to steps 3010 and 3012 is logged and recorded on the system for further review and study.

As shown at step 3014, the system may perform Automated Incident Linking wherein when an anomaly is detected, the system links related logs, admin actions, and operational events into a single view as shown at step 3016 for faster resolution by a human administrator in a user friendly graphical screen display or dashboard such as those described above. Administrators need not manually gather the information needed to understand detected anomalies in the operation of the system. All activity related to steps 3014 and 3016 is logged and recorded on the system for further review and study. As another example of operational event history processing with the system, Anomaly Alerts may be generated including Combined Multiple Data Streams such as, and for example, “Unusual activity detected: Admin B accessed system outside normal hours and 5 bays reported errors within 10 minutes.”

In still further aspects, and as shown at step 3018 the system may incorporate revenue and usage-based analytics by collecting operational data from charging bays and associated devices, applying AI-driven correlation to identify utilization patterns, optimize resource allocation, and generate predictive forecasts, wherein the system provides natural language summaries and actionable insights through a centralized dashboard integrated with external management platforms as shown at step 3020. Usage-Based Alerts may be generated concerning charging bays which are deemed to be underutilized or overused relative to expected usage suggestions. Charging bay redistributions may be suggested to address underutilized or overutilized devices in or more correctional facilities being monitored. For example, a charging bay suggestion may include a recommendation to relocate one or more charging bays from one POD to another POD in a correctional facility to address the detected underutilization or overutilization of charging bay devices. Additionally, Idle Bay Detection is possible to automatically identify charging bays that have been unused for extended periods of time. A suggestion or recommendation to repurpose or relocate idle bays to high-demand zones based on historical usage patterns may be generated by the system. Usage Trend Summaries may also be generated such as weekly AI-generated reports summarizing usage patterns and suggesting operational improvements to improve system usage. Information from steps 3018 and 3020 may be beneficial for local correctional facility administrators and remote kiosk system administrators to better understand present system usage and suggestions and recommendations for more optional use of the system. All operations and activity relating to steps 3018 and 3020 is logged on the system for further study and review.

As shown at step 3022, Auto-Firmware Updates may be scheduled for charging bay devices 1800 without administrators taking any action to review firmware versions or to schedule updates. Especially for large numbers of charging bay devices 1800, firmware and software updates may be automatically downloaded and updates may be installed during off-peak hours. Local correctional facility administrators need not manage firmware updates themselves for the charging bay devices 1800, and network bandwidth is preserved during peak hours for users having authorized access to the user computing devices. Also to avoid network bandwidth issues, the updates for the charging bay devices (or modular assemblies associated with the charging bay devices) may be separately scheduled from the updates for the user computing devices which are present in larger numbers than the numbers of charging bay devices. Reports of updates may be reported as shown at step 3024, and all system operations and activity for steps 3022 and 3024 is logged and stored on the system for further review and study.

The above-described embodiments of the disclosure may be implemented using computer programming or engineering techniques including computer software, firmware, hardware or any combination or subset thereof, wherein the technical effects described above are achieved. Any such resulting program, having computer-readable code means, may be embodied or provided within one or more computer-readable media, thereby making a computer program product, (i.e., an article of manufacture), according to the embodiments described above. The computer-readable media may be, for example, but is not limited to, a fixed (hard) drive, diskette, optical disk, magnetic tape, semiconductor memory such as read-only memory (ROM), and/or any transmitting/receiving medium such as the Internet or other communication network or link. The article of manufacture containing the computer code may be made and/or used by executing the code directly from one medium, by copying the code from one medium to another medium, or by transmitting the code over a network.

Such computer programs (also known as programs, software, software applications, “apps”, or code) include machine instructions for a programmable processor, and can be implemented in a high-level procedural and/or object-oriented programming language, and/or in assembly/machine language. As used herein, the terms “machine-readable medium” “computer-readable medium” refers to any computer program product, apparatus and/or device (e.g., magnetic discs, optical disks, memory, Programmable Logic Devices (PLDs)) used to provide machine instructions and/or data to a programmable processor, including a machine-readable medium that receives machine instructions as a machine-readable signal. The “machine-readable medium” and “computer-readable medium,” however, do not include transitory signals. The term “machine-readable signal” refers to any signal used to provide machine instructions and/or data to a programmable processor.

As used herein, a processor may include any programmable system including systems using micro-controllers, reduced instruction set circuits (RISC), application specific integrated circuits (ASICs), logic circuits, and any other circuit or processor capable of executing the functions described herein. The above examples are example only and are thus not intended to limit in any way the definition and/or meaning of the term “processor.”

The applications described above are flexible and designed to run in various different environments without compromising any major functionality. In some embodiments, the system includes multiple components distributed among a plurality of computing devices. One or more components are in the form of computer-executable instructions embodied in a computer-readable medium. The systems and processes are not limited to the specific embodiments described herein. In addition, components of each system and each process can be practiced independently and separately from other components and processes described. Each component and process can also be used in combination with other assembly packages and processes.

One or more computer-readable storage media may include computer-executable instructions embodied thereon for interfacing with the kiosk systems, charging bay devices, and tablet computer devices described. The kiosk systems, charging bay devices, and the tablet computer devices may each include a memory device and a processor in communication with the memory device, and when executed by the processor in each respective device the computer-executable instructions may cause the processor to perform one or more algorithmic steps of a method such as the methods described and illustrated in the examples of FIGS. 5, 14, 28-30, 33-35 and 38-39.

Having described devices and applicable operating algorithms functionally per the description above, those in the art may accordingly implement the algorithms via programming of the controllers, servers or other processor-based computing devices. Such programming or implementation of the concepts described is believed to be within the purview of those in the art and will not be described further.

The benefits and advantages of the inventive kiosk systems, assemblies, algorithms and user interfaces described are now believed to have been amply illustrated in relation to the exemplary embodiments disclosed. Barriers to adoption of tablet computer devices in correctional facilities are obviated, and inmates may more readily enjoy the enhanced user experience of tablet computer devices without burdening facility administrators or compromising security safeguards. Technological solutions to significant technological problems are provided via the inventive kiosk devices, systems and methods described including hardware and software configurability and intelligent management of an inventory of a number of tablet computer devices and in a single system realized by a combination of prefabricated charger bay devices and prefabricated modular charger bay component assemblies and at least one controller for effecting the functionality described herein.

An embodiment a configurable kiosk charging system for a plurality of portable computing devices has been disclosed. The configurable kiosk charging system includes at least one modular charging bay device having a cabinet housing defining a front face and a plurality of access openings extending thorough the front face. A charging pocket and charging circuitry are accessible through each respective one of the access openings, wherein each charging pocket is configured to entirely receive and automatically charge one of the plurality of portable computing devices. A locking mechanism is in the cabinet housing and is configured to simultaneously allow a removal of the plurality of portable computing devices from the respective charging pockets when in an unlocked state and to simultaneously prevent a removal of the plurality of portable computing devices from the respective charging pockets when in a locked state. A pair of sensors are operable in combination to detect a successful change of the locking mechanism between the locked state and the unlocked state and to detect an unsuccessful change of the locking mechanism between the locked state and the unlocked state.

Optionally, the at least one modular charging bay device may include a control board and a motor responsive to the control board, wherein the motor and control board automatically cause the locking mechanism to change between the lock state and the unlocked state and between the unlocked state and the lock state according to a predetermined scheduled day and time. The system may further include at least one administrator computing device separately provided from the at least one modular charging bay device, the at least one computer device operable to present at least one graphical screen display including predetermined schedule options. The at least one administrator computing may further be operable to present at least one graphical screen display including an option to an administrator to cause an unscheduled change in state of the locking mechanism. The locking mechanism may include a manual override feature accessible locally at the at least one modular charging bay device, the manual override feature being accessible from the front face and being operable to cause a change in state of the locking mechanism, and the manual override feature may be spring biased toward a locked state of the locking mechanism. The manual override feature may include a key and barrel assembly.

As further options, the locking mechanism may include a single actuator link and a plurality of locking tabs extending from the single actuator link, the locking tabs respectively blocking a portion of each access opening when in the locked position to prevent removal of the respective portable electronic device and clearing the access openings when in the unlocked position to allow a removal of the portable electronic device. The single actuator link may be spring biased to cause the locking tabs to assume the locked position. The single actuator link may also be interfaced with the motor, the motor causing the single actuator link to change position relative to the front panel, and the changed position of the single actuator link causing the plurality of locking tabs to block or clear the access openings. An eccentric wheel may interface the motor and the actuator link. The motor may be operable by a power over ethernet power supply for operating the locking mechanism. The single actuator link may be vertically movable between the locked position and the unlocked position, and at least one of the pair of sensors is a limit switch. The locking tabs may extend horizontally across a portion of the respective access openings. The locking tabs may be reinforced to resist tampering.

The portable electronic devices may optionally be tablet computer devices respectively housed in a protective case, the protective case including an integral stand, and the locking mechanism extending across a portion of the integral stand in the locked state. The at least one modular charging bay device may further include at least one lock indicator for the modular charging bay device and at least one charging indicator for the plurality of portable computing devices.

At least the front panel may also be removable from the cabinet housing and from an internal modular chassis assembly. The modular chassis assembly may include angled charging pockets, and each of the angled charging pockets may have a wedge shape. The modular chassis assembly may include drainage openings. The system may include a wall mounted bracket, and the modular chassis assembly may be suspended from the wall mounted bracket.

The access openings may define clearance portions for a user's hand when inserting or retrieving one of the plurality of mobile computing devices. The access openings may also include tapered side edges. The access openings and charging slots are configured to receive the plurality of portable computing devices in a one-way orientation for successful insertion. The one-way orientation may be an upside-down orientation of the portable computing device.

The system may optionally include at least one remote device receiving lock detection data from the pair of sensors, charging data for the plurality of portable computing devices in the at least one modular charging bay device, and device data for the modular charging bay device. The system may further include at least one administrator computer device accessing data collected by the at least one remote device, the administrator user device operable to present at least one graphical screen display including lock status, charging status, or device status for the at least one modular charging bay device. The at least one graphical screen display may include a lock status of Successful, In Progress, or, Failed for the at least one modular charging bay device; a device status of Unlocked, Locked, or Offline for the at least one modular charging bay device; and a charging status of Charging, Not Charging or Fully Charged for the charging pockets in the at least one modular charging bay device.

The administrator computer device may also be operable to present at least one graphical screen display including software or firmware information for the at least one modular charging bay device; at least one graphical screen display including a lock history for the modular charging bay device; and at least one graphical screen display including notification information for the modular charging bay device.

An embodiment of a mobile device management system for a plurality of portable computing devices in a plurality of different facilities has also been disclosed. The mobile device management system includes a plurality of configurable kiosk charging systems in each of the plurality of different facilities, each of the plurality of configurable kiosk charging systems including one or more modular charging bay devices. Each of the one or more modular charging bay devices includes: a cabinet housing defining a front face and a plurality of access openings extending thorough the front face; a charging pocket and charging circuitry accessible through each respective one of the access openings, wherein each charging pocket is configured to entirely receive and automatically charge one of the plurality of portable computing devices; and a locking mechanism in the cabinet housing and being configured to allow a removal of the plurality of portable computing devices from the respective charging pockets when in an unlocked state and to prevent a removal of the plurality of portable computing devices from the respective charging pockets when in a locked state; and a pair of sensors operable in combination to detect a successful change of the locking mechanism between the locked state and the unlocked state and to detect an unsuccessful change of the locking mechanism between the locked state and the unlocked state. At least one remote device is also included which receives lock data from the pair of sensors in the one or more modular charging bay devices, charging data for the plurality of portable computing devices in the one or more modular charging bay devices, and device data for the one or more modular charging bay devices. At least one administrator computer device is separately provided from the plurality of configurable kiosk charging systems, and the administrator computer device is operable to present at least one graphical screen display including lock status, charging status or device status for each of the one or more modular charging bay devices in the plurality of configurable kiosk charging systems.

Optionally, the at least one graphical screen display includes a lock status of Successful, In progress, or, Failed for each of the one or more modular charging bay devices in the plurality of configurable kiosk charging systems. The at least one graphical screen display may also include a device status of Unlocked, Locked, or Offline for each of the one or more modular charging bay devices in the plurality of configurable kiosk charging systems. The at least one graphical screen display may include a charging status of Charging, Not Charging or Fully Charged for each of the pockets in each of the one or more modular charging bay devices in the plurality of configurable kiosk charging systems.

The administrator computer device may also be operable to present at least one graphical screen display including software or firmware information for the one or more modular charging bay devices in the plurality of configurable kiosk charging systems; at least one graphical screen display including a lock history for the one or more modular charging bay devices; and at least one graphical screen display including notification information for one or more modular charging bay devices.

The locking mechanism in each of the more or more modular charging bay devices is optionally configured to simultaneously allow or prevent an insertion or removal of the plurality of portable computing devices through the access openings. The locking mechanism in each of the more or more modular charging bay devices may be automatically operated to change the state of the locking mechanism on a predetermined schedule. The locking mechanism in each of the more or more modular charging bay devices may be manually operable via a manual override feature accessible on the front face of the cabinet housing. The locking mechanism in each of the more or more modular charging bay devices may be remotely operable from the administrator computer device in an unscheduled manner. The locking mechanism in each of the more or more modular charging bay devices is biased toward the locked state. The locking mechanism may include an actuator link which is movable relative to the access openings, and the actuator link may be integrally formed with a plurality of locking tabs which extend partly across the access openings in the locked state.

At least the front panel may be removable from the cabinet housing and from an internal modular chassis assembly in each of the one or more modular charging bay devices. The modular chassis assembly in each of the one or more modular charging bay devices may include angled charging pockets, and each of the angled charging pockets may having a wedge shape. The modular chassis assembly in each of the one or more modular charging bay devices may include drainage openings. The system may include a wall mounted bracket, and the modular chassis assembly may be suspended from the wall mounted bracket.

The access openings in each of the one or more modular charging bay devices may define clearance portions for a user's hand when inserting or retrieving one of the plurality of mobile computing devices. The access openings in each of the one or more modular charging bay devices may include tapered side edges. The access openings and charging pockets in each of the one or more modular charging bay devices may be configured to receive the plurality of portable computing devices in a one-way orientation for successful insertion. The one-way orientation may be an upside-down orientation.

The portable electronic devices may be tablet computer devices respectively housed in a protective case, the protective case including an integral stand, and the locking mechanism in each of the one or more modular charging bay devices extending across a portion of the integral stand in the locked state. The locking mechanism in each of the one or more modular charging bay devices may include a motor in communication with a control board. The locking mechanism in each of the one or more modular charging bay devices may also include an eccentric wheel. The locking mechanism in each of the one or more modular charging bay may also include a spring, the spring opposing a movement of the mechanism to the unlocked state. Each of the one or more modular charging bay devices may also include a lock indicator and charging indicators for each of the charging pockets.

A mobile device management system for a plurality of portable computing devices in a plurality of different facilities has been disclosed. The mobile device management system includes a plurality of charging bay devices in the plurality of different facilities. Each of the plurality of charging bay devices includes: a cabinet housing defining a front face and a plurality of access openings extending thorough the front face; a charging pocket and charging circuitry accessible through each respective one of the access openings, wherein each charging pocket is configured to entirely receive and automatically charge one of the plurality of portable computing devices; a locking mechanism in the cabinet housing and being configured to allow a removal of the plurality of portable computing devices from the respective charging pockets when in an unlocked state and to prevent a removal of the plurality of portable computing devices from the respective charging pockets when in a locked state; and a pair of sensors operable in combination to detect a successful change of the locking mechanism between the locked state and the unlocked state and to detect an unsuccessful change of the locking mechanism between the locked state and the unlocked state. The system also includes at least one remote device receiving lock data from the pair of sensors in the plurality of charging bay devices, charging data for the plurality of portable computing devices in the plurality of charging bay devices in each of the respectively different facilities, and device data for the plurality of charging bay devices; and at least one administrator computer device separately provided from the plurality of charging bay devices, the administrator computer device operable to present at least one graphical screen display including lock status, charging status or device status for each of the plurality of charging bay devices in the different facilities.

Optionally, the at least one graphical screen display may include a lock status of Successful, In progress, or Failed for each of the one or more modular charging bay devices in the plurality of charging bay devices. The at least one graphical screen display may include a device status of Unlocked, Locked, or Offline for each of the plurality of plurality of charging bay devices. The at least one graphical screen display may also include a charging status of Charging, Not Charging or Fully Charged for each of the pockets in each of the plurality of charging bay devices The administrator computer device may also be operable to present at least one graphical screen display including software or firmware information for the plurality of charging bay devices. The administrator computer device further may further be operable to present at least one graphical screen display including a lock history for the plurality of charging bay devices, and at least one graphical screen display including notification information for the plurality of charging bay devices.

As further options, the locking mechanism in each of the more or more modular charging bay devices is further configured to simultaneously allow or prevent an insertion or removal of the plurality of portable computing devices through the access openings. The locking mechanism in each of plurality of charging bay devices may be automatically operated to change the state of the locking mechanism on a predetermined schedule. The locking mechanism in each of plurality of charging bay devices may be manually operable via a manual override feature accessible on the front face of the cabinet housing. The locking mechanism in each of the plurality of charging bay devices may be remotely operable from the administrator computer device in an unscheduled manner. The locking mechanism in each of the plurality of charging bay devices may be biased toward the locked state. The locking mechanism in each of the more or more modular charging bay devices may include an actuator link which is movable relative to the access openings, and the actuator link integrally formed with a plurality of locking tabs which extend partly across the access openings in the locked state.

Optionally, at least the front panel may be removable from the cabinet housing and from an internal modular chassis assembly in each of the one or more modular charging bay devices. The modular chassis assembly in each of the plurality of charging bay devices may include angled charging pockets, each of the angled charging pockets having a wedge shape. The modular chassis assembly in each of the one or more modular charging bay devices may include drainage openings. The system may include a wall mounted bracket, with the modular chassis assembly suspended from the wall mounted bracket.

The access openings in each of the one or more modular charging bay devices may define clearance portions for a user's hand when inserting or retrieving one of the plurality of mobile computing devices. The access openings in each of the plurality of charging bay devices may include tapered side edges. The access openings and charging pockets in each of the plurality of charging bay devices may be configured to receive the plurality of portable computing devices in a one-way orientation for successful insertion. The one-way orientation may be an upside-down orientation.

The portable electronic devices may be tablet computer devices respectively housed in a protective case, the protective case including an integral stand, and the locking mechanism in each of the one or more plurality of charging bay devices extending across a portion of the integral stand in the locked state. The locking mechanism in each of the plurality of charging bay devices may include a motor in communication with a control board. The locking mechanism in each of the plurality of charging bay devices may also include an eccentric wheel. The locking mechanism in each of the plurality of charging bay devices may also include a spring, the spring opposing a movement of the mechanism to the unlocked state. Each of the plurality of charging bay devices may also include a lock indicator and charging indicators for each of the charging pockets.

Optionally, the administrator computer device is further operable to present at least one graphical screen display including an option to generate a secure link for permitted user access to information for selected ones of the plurality of charging bay devices. The permitted user access may include ability to enroll charging bay devices. The at least one graphical screen display may include an option to manually enroll a charging bay device or to automatically enroll a charging bay device. The option to automatically enroll a charging bay device may also include an option to automatically enroll a charging bay device via QR code. The permitted user access may also include an ability to edit charging bay device information, and an ability to change a lock state of at least one charging bay device. The permitted user may be a technician responsible for installing, adding or removing a charging bay, a local facility administrator, wherein the local facility is a correctional facility. The generated secure link may be a temporary secure link that is active for a selected amount of time and thereafter automatically expires.

An embodiment of a mobile device management system for a plurality of portable computing devices in at least one correctional facility has also been disclosed. The mobile device management system includes: a plurality of charging bay devices arranged in the at least one correctional facility. Each of the charging bay devices includes: a cabinet housing defining a front face and a plurality of access openings extending thorough the front face; a charging pocket and charging circuitry accessible through each respective one of the access openings, wherein each charging pocket is configured to entirely receive and automatically charge one of the plurality of portable computing devices; a locking mechanism in the cabinet housing and being configured to allow a removal of the plurality of portable computing devices from the respective charging pockets when in an unlocked state and to prevent a removal of the plurality of portable computing devices from the respective charging pockets when in a locked state; and a pair of sensors operable in combination to detect a successful change of the locking mechanism between the locked state and the unlocked state and to detect an unsuccessful change of the locking mechanism between the locked state and the unlocked state. The system further includes at least one remote device receiving enrollment data, user permission data, lock data from the pair of sensors in the charging bay devices, and charging data for the plurality of portable computing devices in the charging bay devices; and at least one administrator computer device separately provided from the plurality of charging bay devices, the administrator computer device operable to present at least one graphical screen display including enrolled charging bay information, lock status, and charging status for each of the plurality of charging bay devices in the at least one correctional facility, wherein the at least one graphical screen display includes a lock status of Successful, In progress, or Failed for each of the one or more modular charging bay devices in the plurality of charging bay devices.

The at least one graphical screen display may include: a device status of Unlocked, Locked, or Offline for each of the plurality of plurality of charging bay devices; a charging status of Charging, Not Charging or Fully Charged for each of the pockets in each of the plurality of charging bay devices; an option to cause a selected charging bay to lock or unlock; and/or an option to generate a secure link for permitted user access to information for selected ones of the plurality of charging bay devices. The generated secure link may be a temporary secure link that is active for a selected amount of time and thereafter automatically expires. The permitted user access may include an ability to enroll charging bay devices, an option to manually enroll a charging bay device or to automatically enroll a charging bay device, an option to automatically enroll a charging bay device via QR code, an ability to edit charging bay device information, an ability to change a lock state of at least one charging bay device. The permitted user may be a technician responsible for installing, adding or removing a charging bay. The permitted user may be a local correctional facility administrator.

A method of managing portable computing devices in at least one correctional facility has also been disclosed. The method includes providing a plurality of charging bay devices arranged in the at least one correctional facility for receiving respective ones of the portable computing devices. Each of the charging bay devices include: a cabinet housing defining a front face and a plurality of access openings extending thorough the front face; a charging pocket and charging circuitry accessible through each respective one of the access openings, wherein each charging pocket is configured to entirely receive and automatically charge one of the plurality of portable computing devices; a locking mechanism in the cabinet housing and being configured to allow a removal of the plurality of portable computing devices from the respective charging pockets when in an unlocked state and to prevent a removal of the plurality of portable computing devices from the respective charging pockets when in a locked state; and a pair of sensors operable in combination to detect a successful change of the locking mechanism between the locked state and the unlocked state and to detect an unsuccessful change of the locking mechanism between the locked state and the unlocked state. The method also includes: providing at least one remote device receiving enrollment data, user permission data, lock data from the pair of sensors in the charging bay devices, and charging data for the plurality of portable computing devices in the charging bay devices; providing at least one administrator computer device separately provided from the plurality of charging bay devices, the administrator computer device operable to present at least one graphical screen display including enrolled charging bay information, lock status, and charging status for each of the plurality of charging bay devices in the at least one correctional facility; and displaying, via the at least one graphical screen display, a lock status of Successful, In progress, or Failed for each of the charging bay devices; and causing selected ones of the charging bay devices to lock or unlock via a permitted user selection made on the at least one graphical screen display.

Optionally, the method also includes, from a location remote from the correctional facility, granting permissions to selected persons inside the correctional facility to supply enrolled charging bay information, edit charging bay information, or to cause selected ones of the charging bay devices to lock or unlock. The method may also include generating a temporarily link for access to the system by permitted persons.

An embodiment of a computer-implemented method of managing mobile computing devices has also been disclosed. The method is implemented in a system including a database having authorized user data and information and authorized user privilege information, at least one controller, and at least one charging bay device. The charging bay device includes a closed housing including a plurality of charging slot apertures, a charging slot and charging circuitry accessible through each respective one of the charging slot apertures, wherein each charging slot is configured to at least partly receive and automatically charge one of the plurality of portable computing devices, and a locking mechanism in the cabinet housing and being configured to allow a removal of one or more of the plurality of portable computing devices from the respective charging slots when in an unlocked state and to prevent a removal of the plurality of portable computing devices from the respective charging slots when in a locked state, the locking mechanism being automatically and manually positionable between the locked and unlocked states. The method includes: accepting, by the at least one controller, a user login to verify an authorized user status according to the authorized user data and information in the database; assessing a user privilege status after the authorized user status is verified and according to the authorized user data and information in the database, wherein the user privilege status is a changeable behavioral based status of active privilege status to access one of the portable computing device or suspended privilege status to access one of the portable electronic computing devices; and only when the user privilege status is active, allowing one of the portable computing devices to be retrieved and used by the verified authorized user.

Optionally allowing one of the portable computing devices to be retrieved may include unlocking at least one the charging slots for retrieval of one of the portable computing devices. The method may also include accepting with the at least one controller a remote locking or unlocking command for at least one of the charging slots. The method may further include: verifying with the at least one controller whether a time of the accepted user login falls within a predetermined facility schedule access time window; and only when the time of the accepted user login falls within a predetermined facility schedule access time window, allowing one of the portable computing devices to be retrieved and used by the verified authorized user.

As further options, the method may include: assessing, with the at least one controller, an available portable computing device inventory in the at least one charging bay device according to predetermined criteria; selecting a preferred one of the portable computing devices according to the predetermined criteria; and allowing the selected preferred one of the portable computing devices to be retrieved and used by the verified authorized user. The predetermined criteria may include assessment of battery charge level for the available portable computing devices and an assessment of software or firmware version for the available portable computing devices. The method may further include assigning the selected preferred portable computing device to the verified authorized user prior to use of the preferred one of the portable computing devices by the authorized user; identifying, by the at least one controller, the selected preferred one of the portable computing devices when returned to the at least one charging bay device; and unassigning the selected preferred one of the portable computing devices from the authorized user. The method may also include operating an approved portable computing device indicator for the user to locate the selected preferred one of the portable computing devices in the at least one charging bay. The approved portable computing device indicator may be a light emitting diode (LED) and may include a flashing light.

As further options, the at least one charging bay device may be equipped with a near field communication element in each charging slot, the near field communication in each slot cooperating with a near field communication coupled to a portable computing device to uniquely identify the portable computing device in each slot, and the method may include: creating a database of identified portable computing device is each charging slot with the near field communication elements; and generating a notice regarding an identified portable computing device which has been located in at least one of the charging slots.

The at least one charging bay device may optionally be equipped with a portable computing device detector in each charging slot, and the method may include enabling or disabling an output of the charging circuitry by the at least one controller when the portable computing device detector does not detect a portable computing device in the respective charging slots. The method may further include establishing a physical wire connection between the charging circuitry and the portable computing device in each charging slot.

The method may further optionally include: pre-assigning one of the portable computing devices to a logged in user; assessing, by the at least one controller, the pre-assigned one of the portable computing devices according to predetermined criteria; and if the pre-assigned one of the portable computing devices passes the assessment, allowing the pre-assigned one of the portable computing devices to be retrieved and used by the logged in user. The method may also optionally include: if the pre-assigned one of the portable computing devices does not pass the assessment, reassigning another one of the portable computing devices to the logged in user and allowing the reassigned portable computing device to be retrieved and used by the logged in user; and generating a notice of the reassigned portable computing device.

As still further options, the method may include: once the verified authorized user logs into the retrieved portable computing device, assigning the portable computing device to the authorized user for system oversight of usage of the portable computing device by the verified authorized user; and logging the assignment of the portable computing device.

The method may also optionally include: generating a portable computing device availability notice to the verified authorized user; reserving one of the portable computing device for checkout by the verified authorized user; setting a timer for the verified authorized user to complete a checkout of the reserved portable computing device; and if the verified authorized user does not complete checkout of the reserved portable computer device before the timer expires, return the reserved device to an available inventory for a subsequent accepted user login.

The authorized user may be an incarcerated inmate in a correctional facility, and wherein the user privilege status is an inmate privilege status determined by the correctional facility to address security concerns for the correctional facility.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A computer-implemented method of managing mobile computing devices,
the method implemented in a system including:
a database including authorized user data and information and authorized user privilege information;
at least one controller; and
at least one charging bay device comprising:
a closed housing including a plurality of charging slot apertures;
a charging slot and charging circuitry accessible through each respective one of the charging slot apertures, wherein each charging slot is configured to at least partly receive and automatically charge one of the plurality of portable computing devices; and
a locking mechanism in the cabinet housing and being configured to allow a removal of one or more of the plurality of portable computing devices from the respective charging slots when in an unlocked state and to prevent a removal of the plurality of portable computing devices from the respective charging slots when in a locked state, the locking mechanism being automatically and manually positionable between the locked and unlocked states; and
wherein the method comprises:
accepting, by the at least one controller, a user login to verify an authorized user status according to the authorized user data and information in the database;
assessing a user privilege status after the authorized user status is verified and according to the authorized user data and information in the database, wherein the user privilege status is a changeable behavioral based status of active privilege status to access one of the portable computing device or suspended privilege status to access one of the portable electronic computing devices; and
only when the user privilege status is active, allowing one of the portable computing devices to be retrieved and used by the verified authorized user.

2. The method of claim 1, wherein allowing one of the portable computing devices to be retrieved comprises unlocking at least one the charging slots for retrieval of one of the portable computing devices.

3. The method of claim 1, further comprising, accepting with the at least one controller a remote locking or unlocking command for at least one of the charging slots.

4. The method of claim 3, further comprising:
verifying with the at least one controller whether a time of the accepted user login falls within a predetermined facility schedule access time window; and
only when the time of the accepted user login falls within a predetermined facility schedule access time window, allowing one of the portable computing devices to be retrieved and used by the verified authorized user.

5. The method of claim 1, further comprising:
assessing, with the at least one controller, an available portable computing device inventory in the at least one charging bay device according to predetermined criteria;
selecting a preferred one of the portable computing devices according to the predetermined criteria; and
allowing the selected preferred one of the portable computing devices to be retrieved and used by the verified authorized user.

6. The method of claim 5, wherein the predetermined criteria includes assessment of battery charge level for the available portable computing devices and an assessment of software or firmware version for the available portable computing devices.

7. The method of claim 5, further comprising assigning the selected preferred portable computing device to the verified authorized user prior to use of the preferred one of the portable computing devices by the authorized user.

8. The method of claim 7, further comprising:
identifying, by the at least one controller, the selected preferred one of the portable computing devices when returned to the at least one charging bay device; and
unassigning the selected preferred one of the portable computing devices from the authorized user.

9. The method of claim 5, further comprising operating an approved portable computing device indicator for the user to locate the selected preferred one of the portable computing devices in the at least one charging bay device.

10. The method of claim 9, wherein the approved portable computing device indicator is a light emitting diode (LED).

11. The method of claim 10, wherein the portable computing device indicator includes a flashing light.

12. The method of claim 1, wherein the at least one charging bay device is equipped with a near field communication element in each charging slot, the near field communication in each slot cooperating with a near field communication coupled to a portable computing device to uniquely identify the portable computing device in each slot,
wherein the method further comprises:
creating a database of identified portable computing device is each charging slot with the near field communication elements; and
generating a notice regarding an identified portable computing device which has been located in at least one of the charging slots.

13. The method of claim 1, wherein the at least one charging bay device is equipped with a portable computing device detector in each charging slot, and wherein the method further comprises enabling or disabling an output of the charging circuitry by the at least one controller when the portable computing device detector does not detect a portable computing device in the respective charging slots.

14. The method of claim 13, further comprising establishing a physical wire connection between the charging circuitry and the portable computing device in each charging slot.

15. The method of claim 1, further comprising:
pre-assigning one of the portable computing devices to a logged in user;
assessing, by the at least one controller, the pre-assigned one of the portable computing devices according to predetermined criteria; and
if the pre-assigned one of the portable computing devices passes the assessment, allowing the pre-assigned one of the portable computing devices to be retrieved and used by the logged in user.

16. The system of claim 15, wherein the method further comprises, if the pre-assigned one of the portable computing devices does not pass the assessment, reassigning another one of the portable computing devices to the logged in user and allowing the reassigned portable computing device to be retrieved and used by the logged in user.

17. The method of claim 16, further comprising generating a notice of the reassigned portable computing device.

18. The method of claim 1, further comprising, once the verified authorized user logs into the retrieved portable computing device, assigning the portable computing device to the authorized user for system oversight of usage of the portable computing device by the verified authorized user; and
logging the assignment of the portable computing device.

19. The method of claim 1, further comprising:
generating a portable computing device availability notice to the verified authorized user;
reserving one of the portable computing device for checkout by the verified authorized user;
setting a timer for the verified authorized user to complete a checkout of the reserved portable computing device; and
if the verified authorized user does not complete checkout of the reserved portable computer device before the timer expires, return the reserved device to an available inventory for a subsequent accepted user login.

20. The method of claim 1, wherein the authorized user is an incarcerated inmate in a correctional facility, and wherein the user privilege status is an inmate privilege status determined by the correctional facility to address security concerns for the correctional facility.
